(19) United States
(12) Patent Application Publication
(10) Pub. No.: US 2025/0040116 A1
(43) Pub. Date: Jan. 30, 2025

(54) MEMORY DEVICE

(71) Applicant: Semiconductor Energy Laboratory Co., Ltd., Atsugi-shi (JP)

(72) Inventors: Shunpei YAMAZAKI, Setagaya (JP); Takanori MATSUZAKI, Atsugi (JP); Yuto YAKUBO, Atsugi (JP); Yuki OKAMOTO, Ebina (JP); Hideki UOCHI, Atsugi (JP)

(21) Appl. No.: 18/780,752

(22) Filed: Jul. 23, 2024

(30) Foreign Application Priority Data
Jul. 28, 2023 (JP) 2023-123290

(51) Int. Cl. H10B 12/00

(52) U.S. Cl. CPC H10B 12/00

(57) ABSTRACT

A novel memory device is provided. A plurality of memory cells each including two vertical transistors are connected in series. One of the two transistors functions as a transistor for writing data, and the other functions as a transistor for reading the data that has been written to the memory cell. Data written to the memory cell is retained in a gate of the reading transistor. A transistor with low off-state current is used as the writing transistor.

### BACKGROUND OF THE INVENTION

### 1. Field of the Invention

One embodiment of the present invention relates to a memory device.

Note that one embodiment of the present invention is not limited to the above technical field. Examples of the technical field of one embodiment of the present invention disclosed in this specification and the like include a semiconductor device, a display device, a light-emitting device, a power storage device, a memory device, an electronic device, a lighting device, an input device, an input/output device, a driving method thereof, and a manufacturing method thereof.

### 2. Description of the Related Art

In recent years, with an increase in the amount of data manipulated, a semiconductor device having a larger storage capacity has been required. To increase storage capacity per unit area, stacking memory cells is effective (see Patent Documents 1 and 2). Stacking memory cells can increase storage capacity per unit area in accordance with the number of stacked memory cells. Patent Documents 3 and 4 disclose memory devices that use an oxide semiconductor.

In Patent Documents 1 and 2, a plurality of memory elements (also referred to as memory cells) are stacked and these memory elements are connected in series, so that a three-dimensional memory cell array (also referred to as a memory string) is formed.

### REFERENCE

### Patent Documents

[Patent Document 1] United States Patent Application Publication No. 2011/0065270
[Patent Document 2] United States Patent Application Publication No. 2016/0149004
[Patent Document 3] Japanese Published Patent Application No. 2018-207038
[Patent Document 4] Japanese Published Patent Application No. 2019-008862

### SUMMARY OF THE INVENTION

In Patent Document 1, a semiconductor pattern provided in a columnar form is in contact with an insulator including a charge storage layer. In addition, in Patent Document 2, a semiconductor pattern provided in a columnar form is in contact with an insulator functioning as a tunnel dielectric. In both Patent Documents 1 and 2, writing of data to the memory cells is performed by extraction and injection of charge through the insulator. In this case, trap centers might be formed at the interface where the semiconductor and the insulator are in contact with each other. The trap centers can shift the threshold voltage (also referred to as “Vth”) of the transistor by trapping electrons, in some cases. This can adversely affect the reliability of the memory device.

One object of one embodiment of the present invention is to provide a highly reliable memory device. Another object of one embodiment of the present invention is to provide a memory device with a large storage capacity. Another object of one embodiment of the present invention is to provide a memory device that occupies a small area. Another object of one embodiment of the present invention is to provide a memory device with a high memory density. Another object of one embodiment of the present invention is to provide a memory device with low manufacturing costs. Another object of one embodiment of the present invention is to provide a novel memory device. Another object of one embodiment of the present invention is to provide a semiconductor device with high reliability. Another object of one embodiment of the present invention is to provide a semiconductor device with low manufacturing costs. Another object of one embodiment of the present invention is to provide a novel semiconductor device.

Note that the description of these objects does not preclude the existence of other objects. Objects other than these can be derived from the description of the specification, the drawings, the claims, and the like. Note that objects of one embodiment of the present invention do not necessarily achieve all the objects listed above and the other objects. One embodiment of the present invention is to achieve at least one of the objects listed above and the other objects.

One embodiment of the present invention is a memory device including n memory cells (n is an integer greater than or equal to 3), a first wiring, n second wirings, n third wirings, and n fourth wirings. Each of the n memory cells includes a first transistor and a second transistor. Each of the first transistor and the second transistor includes a first conductive layer, a first insulating layer over the first conductive layer, a fourth conductive layer over the first insulating layer, a second insulating layer over the fourth conductive layer, a second conductive layer over the second insulating layer, a semiconductor layer including a region along a side surface of the fourth conductive layer, and a third conductive layer including a region along the side surface of the fourth conductive layer with the semiconductor layer therebetween. The second conductive layer of the first transistor[i] (i is an integer greater than or equal to 2 and less than or equal to n−1) in the i-th memory cell is electrically connected to the first wiring. The first conductive layer of the first transistor[i] is electrically connected to the third conductive layer of the second transistor[i] in the i-th memory cell. The third conductive layer of the first transistor[i] is electrically connected to the i-th second wiring. The fourth conductive layer of the first transistor[i] is electrically connected to the i-th third wiring. The fourth conductive layer of the second transistor[i] is electrically connected to the i-th fourth wiring. The first conductive layer of the second transistor[i] is electrically connected to the second conductive layer of the second transistor[i−1] in the i−1-th memory cell. The second conductive layer of the second transistor[i] is electrically connected to the first conductive layer of the second transistor[i+1] in the i+1-th memory cell.

The first transistor[i] and the second transistor[i] preferably include a region where the first transistor[i] and the second transistor[i] overlap with each other in a plan view. The first conductive layer of the first transistor[i] is configured to serve as the third conductive layer of the second transistor[i]. By providing a capacitor element electrically connected to the third conductive layer of the second transistor[i] to each of the n memory cells, data written to the memory cells can be more stably retained.

One embodiment of the present invention can provide a highly reliable memory device. Another embodiment of the present invention can provide a memory device having a large storage capacity. Another embodiment of the present invention can provide a memory device that occupies a small area. Another embodiment of the present invention can provide a memory device with a high memory density. Another embodiment of the present invention can provide a memory device with low manufacturing costs. Another embodiment of the present invention can provide a novel memory device. Another embodiment of the present invention can provide a highly reliable semiconductor device. Another embodiment of the present invention can provide a semiconductor device with low manufacturing costs. Another embodiment of the present invention can provide a novel semiconductor device.

Note that the description of these effects does not preclude the existence of other effects. Effects other than these can be derived from the description of the specification, the drawings, the claims, and the like. One embodiment of the present invention does not necessarily achieve all of these effects and the other effects. One embodiment of the present invention has at least one of the above effects and the other effects.

### BRIEF DESCRIPTION OF THE DRAWINGS

In the accompanying drawings:

FIGS. 1A to 1C are diagrams each illustrating a circuit structure example of a semiconductor device;

FIG. 2 is a schematic perspective view of a semiconductor device;

FIG. 3 is a diagram of a semiconductor device seen from the X direction;

FIG. 4A is a plan view illustrating an example of a semiconductor device, and FIGS. 4B to 4E are cross-sectional views illustrating an example of the semiconductor device;

FIG. 5 is a cross-sectional view illustrating an example of a semiconductor device;

FIG. 6A is a diagram illustrating a circuit structure example of a semiconductor device, FIG. 6B is a plan view illustrating an example of the semiconductor device, FIG. 6C is a schematic perspective view illustrating an example of the semiconductor device, FIG. 6D is a diagram of the semiconductor device seen from the Y direction, and FIG. 6E is a diagram of the semiconductor device seen from the X direction;

FIGS. 7A and 7B are cross-sectional views illustrating an example of a semiconductor device;

FIG. 8 is a cross-sectional view illustrating an example of a semiconductor device;

FIG. 9A is a diagram illustrating a circuit structure example of a semiconductor device, FIG. 9B is a plan view illustrating an example of the semiconductor device, FIG. 9C is a schematic perspective view illustrating an example of the semiconductor device, FIG. 9D is a diagram of the semiconductor device seen from the Y direction, and FIG. 9E is a diagram of the semiconductor device seen from the X direction;

FIGS. 10A and 10B are plan views illustrating examples of a semiconductor device;

FIG. 11A is a diagram illustrating a circuit structure example of a semiconductor device, FIG. 11B is a plan view illustrating an example of the semiconductor device, FIG. 11C is a schematic perspective view illustrating an example of the semiconductor device, FIG. 11D is a diagram of the semiconductor device seen from the Y direction, and FIG. 11E is a diagram of the semiconductor device seen from the X direction;

FIG. 12A is a plan view illustrating an example of a semiconductor device, FIG. 12B is a cross-sectional view illustrating an example of the semiconductor device, and FIG. 12C is a diagram illustrating a circuit structure example of the semiconductor device;

FIGS. 13A to 13D are diagrams illustrating circuit structure examples of a semiconductor device;

FIG. 14 is a timing chart showing an operation example of a semiconductor device;

FIG. 15 is a circuit diagram showing an operation example of a semiconductor device;

FIG. 16 is a circuit diagram showing an operation example of a semiconductor device;

FIG. 17 is a circuit diagram showing an operation example of a semiconductor device;

FIG. 18 is a circuit diagram showing an operation example of a semiconductor device;

FIG. 19 is a circuit diagram showing an operation example of a semiconductor device;

FIG. 20 is a circuit diagram showing an operation example of a semiconductor device;

FIG. 21 is a circuit diagram showing an operation example of a semiconductor device;

FIGS. 22A to 22D are cross-sectional views illustrating a method for forming a metal oxide of one embodiment of the present invention;

FIGS. 23A to 23D are cross-sectional views illustrating a method for forming a metal oxide of one embodiment of the present invention;

FIGS. 24A and 24B are diagrams illustrating an example of a semiconductor device;

FIG. 25 is a cross-sectional view illustrating an example of a semiconductor device;

FIGS. 26A and 26B are diagrams each illustrating a hierarchy of various kinds of memory devices;

FIGS. 27A and 27B are diagrams illustrating examples of electronic components;

FIGS. 28A to 28C are diagrams illustrating examples of a large computer, FIG. 28D is a diagram illustrating an example of a device for space, and FIG. 28E is a diagram illustrating an example of a storage system that can be used for a data center.

### DETAILED DESCRIPTION OF THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of embodiments below.

In this specification and the like, a semiconductor device refers to a device that utilizes semiconductor characteristics, and means a circuit including a semiconductor element (e.g., a transistor, a diode, or a photodiode), a device including the circuit, and the like. The semiconductor device also means devices that can function by utilizing semiconductor characteristics. For example, an integrated circuit, a chip including an integrated circuit, and an electronic component including a chip in a package are examples of the semiconductor device. In some cases, a memory device, a display device, a light-emitting device, a lighting device, an electronic device, and the like themselves are semiconductor devices and also include a semiconductor device.

In the drawings and the like related to this specification, the size, the layer thickness, or the region is exaggerated for clarity in some cases. Therefore, embodiments of the present invention are not limited to the size, aspect ratio, or the like shown in the drawings. The drawings are schematic views showing ideal examples, and embodiments of the present invention are not limited to shapes, values, or the like shown in the drawings.

Note that in the structures of the invention described in the embodiments, the same portions or portions having similar functions are denoted by the same reference numerals in different drawings and the description of such portions is not repeated in some cases. The same hatching pattern is used for portions having similar functions, and the portions are not denoted by specific reference numerals in some cases. Moreover, some components may be omitted in a perspective view, a plan view, or the like for easy understanding of the diagrams.

Ordinal numbers such as “first”, “second”, and “third” in this specification and the like are used in order to avoid confusion among components. Thus, the terms do not limit the number of components. The terms do not limit the order of components, either. For example, a “first” component in one embodiment in this specification and the like can be referred to as a “second” component in other embodiments, claims, or the like. As another example, a “first” component in one embodiment in this specification and the like can be omitted in other embodiments, claims, or the like.

In this specification and the like, terms for describing arrangement, such as “over”, “under”, “above”, and “below”, are sometimes used for convenience to describe the positional relation between components with reference to drawings. The positional relation between components is changed as appropriate in accordance with the direction from which each component is described. Thus, the positional relation is not limited to that described with a term used in this specification and the like and can be explained with another term as appropriate depending on the situation. For example, the expression “an insulator over (on) a top surface of a conductor” can be replaced with the expression “an insulator on a bottom surface of a conductor” when the direction of a diagram showing these components is rotated by 180°.

The term such as “over” or “under” does not necessarily mean that a component is placed directly on or under and directly in contact with another component. For example, the expression “an electrode B over an insulating layer A” does not necessarily mean that the electrode B is on and in direct contact with the insulating layer A, and can mean the case where another component is provided between the insulating layer A and the electrode B.

The term “overlap”, for example, in this specification and the like does not limit a state such as the stacking order of components. For example, the expression “electrode B overlapping with insulating layer A” does not necessarily mean the state where the electrode B is formed over the insulating layer A, and includes the case where the electrode B is formed under the insulating layer A and the case where the electrode B is formed on the right (or left) side of the insulating layer A.

The terms “adjacent” and “close” in this specification and the like do not necessarily mean that a component is directly in contact with another component. For example, the expression “electrode B adjacent to insulating layer A” does not necessarily mean that the electrode B is formed in direct contact with the insulating layer A and can mean the case where another component is provided between the insulating layer A and the electrode B.

In this specification and the like, the terms “film” and “layer” can be interchanged with each other depending on circumstances. For example, the term “conductive layer” can be changed into the term “conductive film” in some cases. The term “insulating film” can be changed into the term “insulating layer” in some cases, for example. Moreover, such terms can be replaced with a word not including the term “film” or “layer” depending on the case or circumstances. For example, the term “conductive layer” or “conductive film” can be changed into the term “conductor” in some cases. Alternatively, the term “conductor” can be changed into the term “conductive layer” or “conductive film” in some cases. For example, the term “insulating layer” or “insulating film” can be changed into the term “insulator” in some cases. For example, the term “insulator” can be changed into the term “insulating layer” or “insulating film” in some cases.

Note that a voltage refers to a difference between potentials of two points, and a potential refers to electrostatic energy (electric potential energy) of a unit charge at a given point in an electrostatic field. Note that in general, a difference between a potential of one point and a reference potential (e.g., a ground potential) is simply called a potential or a voltage, and a potential and a voltage are used as synonymous words in many cases. Thus, in this specification and the like, a potential may be rephrased as a voltage and a voltage may be rephrased as a potential unless otherwise specified.

In this specification and the like, the terms “electrode”, “wiring”, “terminal”, and the like do not limit the functions of components. For example, an “electrode” is used as part of a “wiring” in some cases, and vice versa. Furthermore, the term “electrode” or “wiring” can also mean a combination of a plurality of “electrodes” or “wirings” provided in an integrated manner, for example. For another example, a “terminal” can be used as part of a “wiring” or an “electrode”, and vice versa. Furthermore, the term “terminal” includes the case where a plurality of “electrodes”, “wirings”, “terminals”, and the like are formed in an integrated manner. Therefore, for example, an “electrode” can be part of a “wiring” or a “terminal”, and a “terminal” can be part of a “wiring” or an “electrode”. Moreover, the terms “electrode”, “wiring”, and “terminal” are sometimes replaced with the term “region” and “conductive layer”, for example.

In this specification and the like, the terms “wiring”, “signal line”, “power source line”, and the like can be interchanged with each other depending on the case or in accordance with circumstances. For example, the term “wiring” can be changed into the term “signal line” in some cases. For another example, the term “wiring” can be changed into the term such as “power supply line” in some cases. Inversely, the term “signal line”, “power source line”, and the like can be changed into the term “wiring” in some cases. The term “power supply line” or the like can be changed into the term “signal line” or the like in some cases. Inversely, the term “signal line” or the like can be changed into the term “power source line” or the like in some cases. The term “potential” that is applied to a wiring can be changed into the term “signal” or the like depending on the case or in accordance with circumstances. Inversely, the term “signal” or the like can be changed into the term “potential” in some cases.

In this specification, a “source” refers to a source region or a source electrode. A source region refers to a region in a semiconductor layer, where the resistivity is lower than or equal to a given value. A source electrode refers to a conductive layer including part connected to a source region.

In this specification, a “drain” refers to a drain region or a drain electrode. A drain region refers to a region in a semiconductor layer, where the resistivity is lower than or equal to a given value. A drain electrode refers to a conductive layer including part connected to a drain region.

In this specification, when it is explicitly described that “X and Y are connected”, the case where X and Y are electrically connected, the case where X and Y are functionally connected, and the case where X and Y are directly connected are included therein. Here, each of X and Y is an object (e.g., a device, an element, a circuit, a wiring, an electrode, a terminal, a conductive film, or a layer). Accordingly, without being limited to a predetermined connection relation (e.g., a connection relation shown in drawings and texts), another connection relation is regarded as being included in the drawings and the texts.

An example of the case where X and Y are electrically connected to each other is a case where one or more elements that enable electrical connection between X and Y (e.g., a switch, a transistor, an inductor, and a resistor) are connected between X and Y in some cases.

For example, in the case where X and Y are functionally connected, one or more circuits that allow a functional connection between X and Y (e.g., a logic circuit such as an inverter, a NAND circuit, or a NOR circuit; a signal converter circuit such as a D/A converter circuit, an A/D converter circuit, or a gamma correction circuit; a potential level converter circuit such as a power supply circuit (e.g., a step-up circuit or a step-down circuit) or a level shifter circuit for changing the potential level of a signal; a voltage source; a current source; a switching circuit; an amplifier circuit such as a circuit that can increase signal amplitude, the amount of current, or the like, an operational amplifier, a differential amplifier circuit, a source follower circuit, or a buffer circuit; a signal generation circuit; a memory circuit; or a control circuit) can be connected between X and Y in some cases. For example, even when another circuit is sandwiched between X and Y, X and Y are functionally connected when a signal output from X is transmitted to Y.

In this specification, “parallel” indicates a state where the angle formed between two straight lines is greater than or equal to −10° and less than or equal to 10°. Thus, the case where the angle is greater than or equal to −5° and less than or equal to 5° is also included. The terms “approximately parallel” and “substantially parallel” indicate that the angle formed between two straight lines is greater than or equal to −15° and less than or equal to 15°. The term “perpendicular” indicates that the angle formed between two straight lines is greater than or equal to 800 and less than or equal to 100°. Thus, the case where the angle is greater than or equal to 850 and less than or equal to 950 is also included. The terms “approximately perpendicular” and “substantially perpendicular” indicate that the angle formed between two straight lines is greater than or equal to 600 and less than or equal to 120°.

A voltage refers to a potential difference between a given potential and a reference potential (e.g., a ground potential or a source potential) in many cases. Therefore, the terms “voltage” and “potential” can be replaced with each other in many cases. In this specification and the like, “voltage” and “potential” can be replaced with each other unless otherwise specified.

In this specification and the like, an “on state” of a transistor refers to a state in which a source and a drain of the transistor are electrically short-circuited (also referred to as a “conduction state”). Furthermore, an “off state” of the transistor refers to a state in which the source and the drain of the transistor are electrically disconnected (also referred to as a “non-conduction state”).

In this specification and the like, “on-state current” sometimes means a current that flows between a source and a drain when a transistor is in an on state. In addition, “off-state current” sometimes means a current that flows between a source and a drain when a transistor is in an off state.

Unless otherwise specified, transistors described in this specification and the like are enhancement (normally-off) n-channel field-effect transistors. Thus, the threshold voltage is higher than 0 V. Furthermore, unless otherwise specified, “a potential H is supplied to a gate of a transistor” is synonymous with “a transistor is brought into an on state” in some cases. Furthermore, unless otherwise specified, “a potential L is supplied to a gate of a transistor” is synonymous with “a transistor is brought into an off state” in some cases.

In this specification and the like, the potential H is a potential that brings an n-channel field-effect transistor (also referred to as an “n-type transistor”) into an on state and also a potential that brings a p-channel field-effect transistor (also referred to as a “p-type transistor”) into an off state. The potential L is a potential that brings an n-type transistor into an off state and a p-type transistor into an on state. Thus, the potential H is higher than the potential L.

In the drawings and the like, for easy understanding of the potentials of a wiring and an electrode, “H” representing a potential H or “L” representing a potential L is sometimes written near the wiring, the electrode, and the like. In addition, enclosed “H” or “L” is sometimes written near a wiring, an electrode, and the like whose potentials are changed. Moreover, a symbol “x” is sometimes written on a transistor in an off state. Furthermore, arrows indicating the direction of current flowing are shown in some cases.

In this specification and the like, the terms “identical”, “the same”, “equal”, “uniform”, and the like (including synonyms thereof) used in describing calculation values and actual measurement values allow for a margin of error of ±10% unless otherwise specified.

In the drawings for this specification and the like, arrows indicating the X direction, the Y direction, and the Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. More specifically, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

In general, a “capacitor” has a structure in which two electrodes face each other with an insulator (dielectric) provided therebetween. This specification and the like include a case where a “capacitor element” is the above-described “capacitor”. That is, in this specification and the like, the “capacitor element” includes one having a structure in which two electrodes face each other with an insulator provided therebetween, one having a structure in which two wirings face each other with an insulator provided therebetween, or one having a structure in which two wirings face each other with an insulator provided therebetween.

In this specification and the like, when a plurality of components denoted by the same reference numerals need to be distinguished from each other, identification signs such as “A”, “b”, “_1”, “[n]”, and “[m,n]” are sometimes added to the reference numerals.

Note that the ordinal numbers such as “first” and “second” in this specification and the like are used in order to avoid confusion among components and do not denote the priority or the order such as the order of steps or the stacking order. A term without an ordinal number in this specification might be provided with an ordinal number in a claim in order to avoid confusion among components. A term with an ordinal number in this specification might be provided with a different ordinal number in a claim. Moreover, a term with an ordinal number in this specification might not be provided with any ordinal number in a claim and the like.

Note that in this specification, one of a source and a drain of a transistor is referred to as a “first terminal” in some cases. The other of the source and the drain of the transistor is referred to as a “second terminal” in some cases.

### Embodiment 1

Memory cells 10 and a memory string 100 including the memory cells 10 that are of one embodiment of the present invention will be described.

### <Structure Example of Memory String>

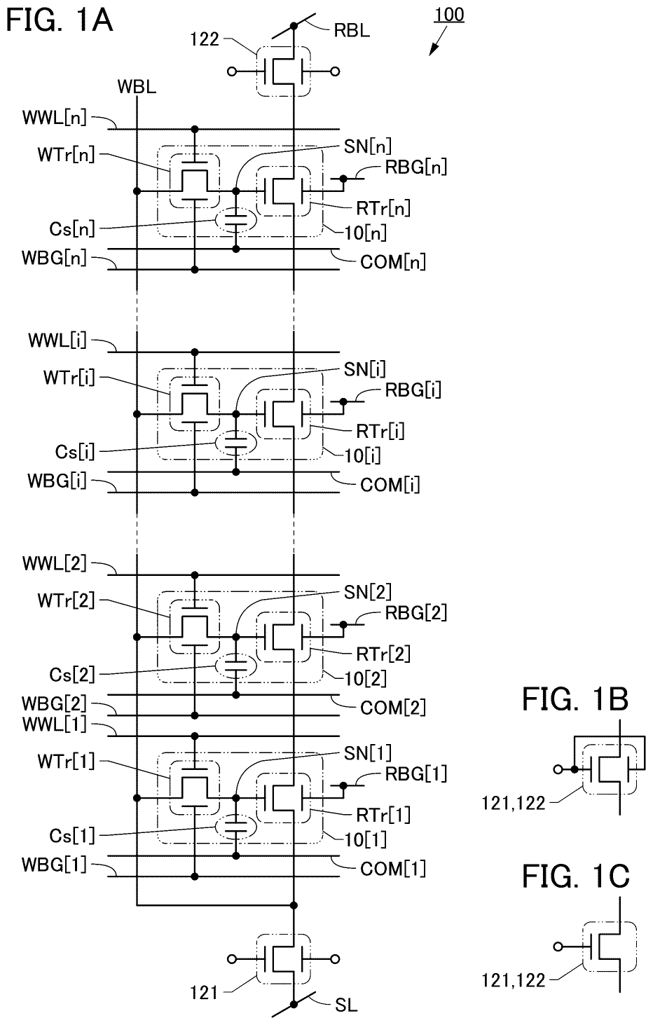

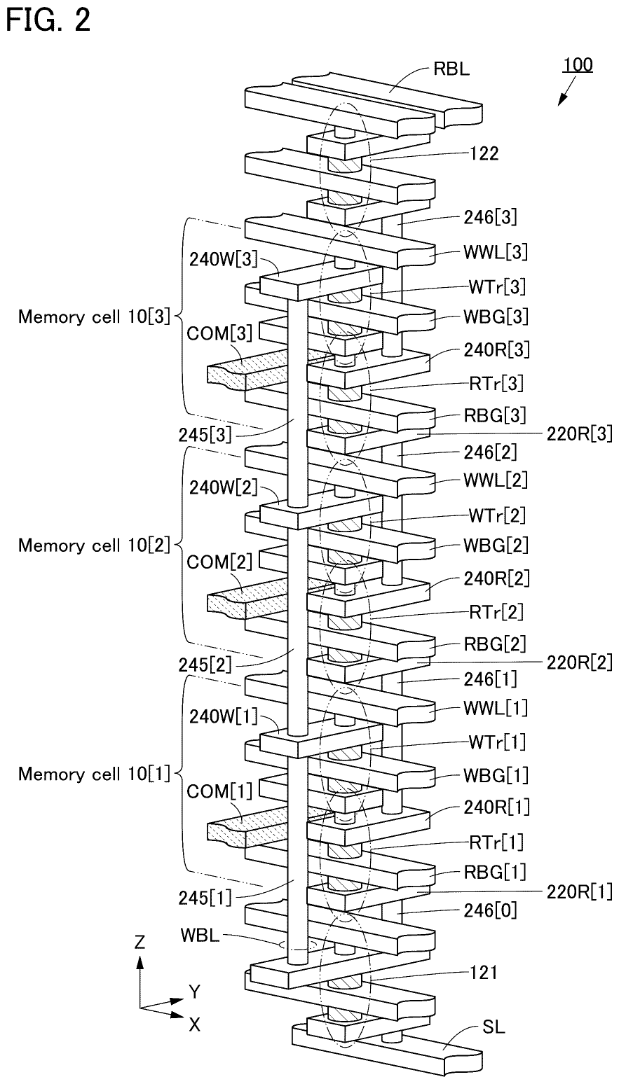

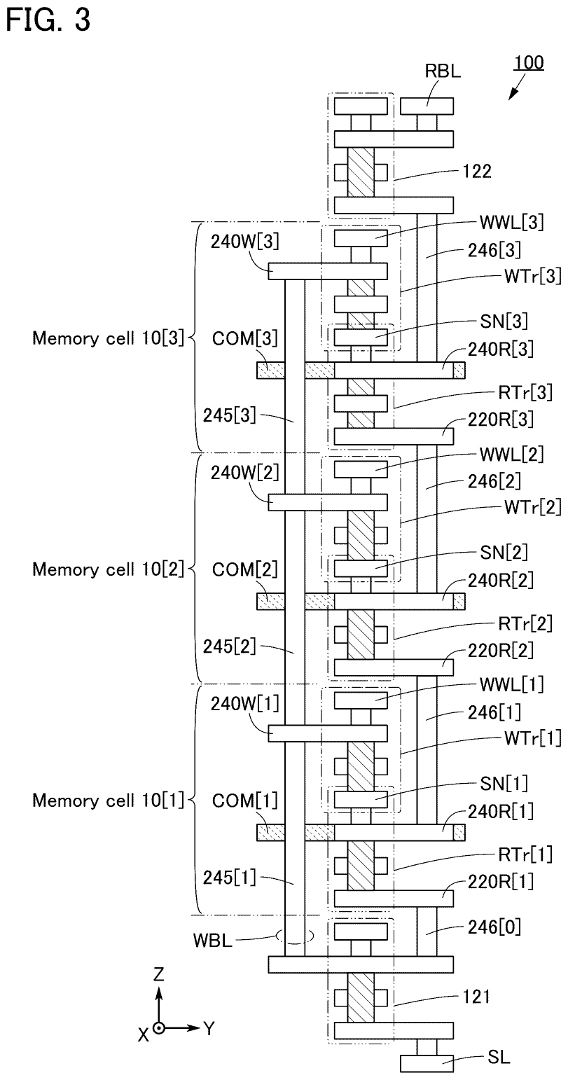

FIG. 1A illustrates a circuit structure example of the memory string 100 including n memory cells 10 (n is an integer greater than or equal to 2). FIG. 2 illustrates a schematic perspective view of the memory string 100 in the case where n is 3. The memory string 100 extends in the Z direction. The Z direction is, for example, a direction perpendicular to a substrate (not illustrated). FIG. 3 is a schematic view of the memory string 100 illustrated in FIG. 2 seen from the X direction.

The memory string 100 includes n memory cells 10 (n is an integer greater than or equal to 3), n wirings WWL, n wirings COM, n wirings WBG, n wirings RBG, a wiring RBL, a wiring WBL, a wiring SL, a transistor 121, and a transistor 122.

The n memory cells 10 are provided between the transistor 121 and the transistor 122. In this specification, the first (also referred to as the “first-stage”) memory cell 10 is denoted as the memory cell 10[1], the memory cell 10 in the second stage is denoted as the memory cell 10[2], and the memory cell 10 in the n-th stage is denoted as the memory cell 10[n]. In addition, the memory cell 10 in the i-th stage (i is an integer greater than or equal to 2 and less than or equal to n−1) is denoted as the memory cell 10[i]. Note that the same applies to the other components.

The memory cell 10 includes a transistor WTr, a transistor RTr, and a capacitor element Cs. In FIG. 1, the transistor WTr in the memory cell 10[1] is denoted as the transistor WTr[1], the transistor RTr in the memory cell 10[1] is denoted as the transistor RTr[1], and the capacitor element Cs in the memory cell 10[1] is denoted as the capacitor element Cs[1].

The wiring COM, the wiring RBG, and the wiring WWL that are connected to the memory cell 10[1] are denoted as the wiring COM[1], the wiring RBG[1], and the wiring WWL[1], respectively.

The transistor WTr in the memory cell 10[i] is denoted as the transistor WTr[i], the transistor RTr in the memory cell 10[i] is denoted as the transistor RTr[i], and the capacitor element Cs in the memory cell 10[i] is denoted as the capacitor element Cs[i]. The wiring WBL, the wiring COM, the wiring RBG, and the wiring WWL that are connected to the memory cell 10[i] are denoted as the wiring WBL[i], the wiring COM[i], the wiring RBG[i], and the wiring WWL[i], respectively.

Similarly, the transistor WTr in the memory cell 10[n] is denoted as the transistor WTr[n], the transistor RTr in the memory cell 10[n] is denoted as the transistor RTr[n], and the capacitor element Cs in the memory cell 10[n] is denoted as the capacitor element Cs[n]. The wiring COM, the wiring RBG, and the wiring WWL that are connected to the memory cell 10[n] are denoted as the wiring COM[n], the wiring RBG[n], and the wiring WWL[n], respectively.

A transistor including a gate and a back gate is used as each of the transistor WTr and the transistor RTr. The gate and the back gate are provided so that a channel formation region of a semiconductor layer is sandwiched therebetween. The gate and the back gate are each formed using a conductive layer or a semiconductor layer with low resistivity. The back gate can function in a manner similar to that of the gate. In the case where the gate is used for control of the on state and the off state of the transistor, the potential of the back gate may be the same as the potential of the gate or may be a ground potential (GND) or a given potential. In the case where the transistor is turned on, supplying the potential H to both the gate and the back gate can increase the amount of the on-state current as compared with the case of supplying the potential H to only one of them. By changing the potential of the back gate independently of the potential of the gate, the threshold voltage of the transistor can be changed. When the gate and the back gate are formed using conductive layers or the semiconductor layers with low resistivity, the transistor has a function of preventing an electric field generated outside the transistor from influencing a semiconductor in which a channel is formed (in particular, an electric field blocking function against static electricity and the like). By providing a back gate in addition to the gate, variation in characteristics between transistors can be reduced.

In the memory cell 10, a first terminal of the transistor WTr is connected to a gate of the transistor RTr and one electrode of the capacitor element Cs, and a second terminal of the transistor WTr is connected to the wiring WBL. A gate of the transistor WTr is connected to the wiring WWL, and a back gate of the transistor WTr is connected to the wiring WBG. A back gate of the transistor RTr is connected to the wiring RBG. The other electrode of the capacitor element Cs is connected to the wiring COM. A region where the first terminal of the transistor WTr, the gate of the transistor RTr, and the one electrode of the capacitor element Cs are connected functions as a retention node SN.

Note that the connection destination of a first terminal of the transistor RTr included in the memory cell 10 depends on at which stage of the transistor RTr is included in the memory cell 10. The first terminal of the transistor RTr in the memory cell 10[1] (the transistor RTr[1]) is connected to the transistor 121, and the first terminal of the transistor RTr in the memory cell 10[n] (the transistor RTr[n]) is connected to the transistor 122.

Specifically, a first terminal of the transistor 121 is connected to the wiring SL, and a second terminal of the transistor 121 is connected to the wiring WBL and the first terminal of the transistor RTr[1]. The first terminal of the transistor RTr[n] is connected to the second terminal of the transistor RTr in the memory cell 10[n−1] (the transistor RTr[n−1]), and the second terminal of the transistor RTr[n] is connected to the first terminal of the transistor 122. A second terminal of the transistor 122 is connected to the wiring RBL.

The first terminal of the transistor RTr in the memory cell 10[i] (the transistor RTr[i]) is connected to the second terminal of the transistor RTr[i−1]. The second terminal of the transistor RTr[i] is connected to the first terminal of the transistor RTr[i+1].

Note that FIG. 1A illustrates an example in which a transistor with a back gate is used as both the transistor 121 and the transistor 122. The back gate may be used independently of the gate, or the gate and the back gate of the transistor 121 may be connected to each other as illustrated in FIG. 1B. As illustrated in FIG. 1C, a transistor without a back gate may be used.

FIGS. 2 and 3 illustrate an example in which the second terminal of the transistor 121 and the first terminal of the transistor RTr[1] (a conductive layer 220R[1]) are connected to each other through a conductive layer 246[0], the second terminal of the transistor RTr[1] (a conductive layer 240R[1]) and the first terminal of the transistor RTr[2] (a conductive layer 220R[2]) are connected to each other through a conductive layer 246[1], and the second terminal of the transistor RTr[2] (a conductive layer 240R[2]) and the first terminal of the transistor RTr[3] (a conductive layer 220R[3]) are connected to each other through a conductive layer 246[2]. Since the memory string 100 illustrated in FIGS. 2 and 3 shows the case of n=3, the second terminal of the transistor RTr[3] (a conductive layer 240R[3]) is connected to the first terminal of the transistor 122 through a conductive layer 246[3].

The first terminal of the transistor 122 and the second terminal of the transistor 121 are connected through channel formation regions of the transistors RTr[1] to RTr[n]. Thus, the transistor 121, the transistor 122, and the transistors RTr[1] to RTr[n] are connected in series.

The second terminals of the transistors WTr[1] to WTr[n] are connected to each other. In the example shown in FIGS. 2 and 3, the second terminal of the transistor WTr[1] (a conductive layer 240W[1]) is connected to the second terminal of the transistor WTr[2] (a conductive layer 240W[2]) through a conductive layer 245[2], and the second terminal of the transistor WTr[2](the conductive layer 240W[2]) is connected to the second terminal of the transistor WTr[3] (a conductive layer 240W[3]) through a conductive layer 245[3]. FIGS. 2 and 3 illustrate an example in which the second terminal of the transistor WTr[1] is connected to the second terminal of the transistor 121 through a conductive layer 245[1].

Each of the plurality of conductive layers 245 functions as part of the wiring WBL. Part of the second terminal of each of the plurality of transistors WTr functions as part of the wiring WBL.

The memory string 100 functions as a NAND memory device in which a plurality of memory cells 10 are connected in series.

### <Structure Example of Transistor>

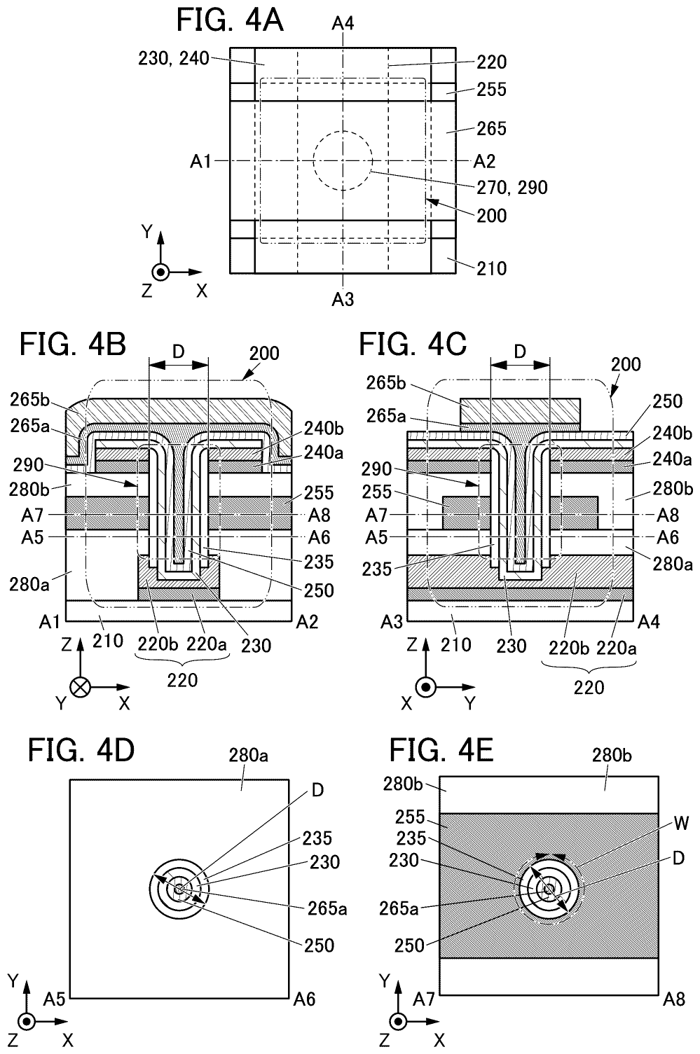

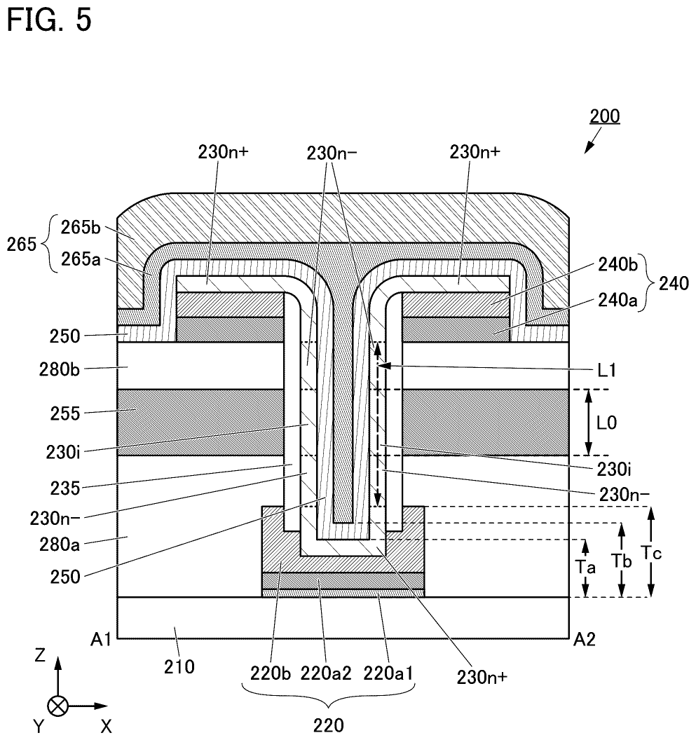

A structure example of a transistor 200 that can be used as the transistor WTr and the transistor RTr in the memory cell 10 is described with reference to FIGS. 4A to 4E and FIG. 5.

FIG. 4A is a plan view of the transistor 200. FIGS. 4B and 5 are cross-sectional views taken along the dashed-dotted line A1-A2 in FIG. 4A. FIG. 5 is an enlarged view of FIG. 4B, and illustrates more details of the structure example of each layer. FIG. 4C is a cross-sectional view taken along the dashed-dotted line A3-A4 in FIG. 4A. FIG. 4D is a cross-sectional view taken along the dashed-dotted line A5-A6 in FIGS. 4B and 4C. FIG. 4D can also be referred to as a cross-sectional view along an XY plane including an insulating layer 280a. FIG. 4E is a cross-sectional view taken along the dashed-dotted line A7-A8 in FIGS. 4B and 4C. FIG. 4E can also be referred to as a cross-sectional view along an XY plane including a conductive layer 255. Note that for simplification, some components are not illustrated in the plan view of FIG. 4A. Some components may be omitted also in the following plan views.

The semiconductor device illustrated in FIGS. 4A to 4E and FIG. 5 includes an insulating layer 210 over a substrate (not illustrated), the transistor 200 over the insulating layer 210, the insulating layer 280a over the insulating layer 210, and an insulating layer 280b over the insulating layer 280a. The insulating layers 210, 280a, and 280b function as interlayer films.

The transistor 200 includes a conductive layer 220a, a conductive layer 220b over the conductive layer 220a, the conductive layer 255 over the insulating layer 280a, a conductive layer 240a over the insulating layer 280b, a conductive layer 240b over the conductive layer 240a, an insulating layer 235, a semiconductor layer 230, an insulating layer 250 over the semiconductor layer 230, a conductive layer 265a over the insulating layer 250, and a conductive layer 265b over the conductive layer 265a.

In this specification, the conductive layer 220a and the conductive layer 220b are collectively referred to as a conductive layer 220 in some cases. Furthermore, the conductive layer 240a and the conductive layer 240b are collectively referred to as a conductive layer 240 in some cases. Furthermore, the conductive layer 265a and the conductive layer 265b are collectively referred to as a conductive layer 265 in some cases.

In the transistor 200, the semiconductor layer 230 functions as a semiconductor layer, the conductive layer 265 functions as a first gate electrode, the insulating layer 250 functions as a first gate insulating layer, the conductive layer 220 functions as one of a source electrode and a drain electrode, the conductive layer 240 functions as the other of the source electrode and the drain electrode, the conductive layer 255 functions as a second gate electrode, and the insulating layer 235 functions as a second gate insulating layer. The conductive layer 265 also functions as a gate wiring.

In the case where the conductive layer 265 is used for a gate electrode, the conductive layer 255 functions as a back gate electrode. In that case, the insulating layer 250 functions as a gate insulating layer, and the insulating layer 235 functions as a back gate insulating layer. Note that in the case where the conductive layer 265 is used for a back gate electrode, the conductive layer 255 functions as a gate electrode.

A channel formation region of the transistor 200 is electrically surrounded by the electric field of the conductive layer 255 that can function as a gate electrode, and thus can be regarded as a kind of a gate all around (GAA) structure.

The semiconductor layer 230 includes a region overlapping with the conductive layer 255 with the insulating layer 235 therebetween and a region overlapping with the conductive layer 265 with the insulating layer 250 therebetween. At least one of the regions functions as the channel formation region of the transistor 200. One of a region that is of the semiconductor layer 230 and is in contact with the conductive layer 220 and a region that is of the semiconductor layer 230 and is in contact with the conductive layer 240 functions as a source region, and the other functions as a drain region. That is, the channel formation region is sandwiched between the source region and the drain region.

As illustrated in FIGS. 4B and 4C, an opening portion 290 reaching the conductive layer 220 is provided in the insulating layer 280a, the conductive layer 255, the insulating layer 280b, the conductive layer 240a, and the conductive layer 240b.

The conductive layer 220 includes the conductive layer 220a and the conductive layer 220b over the conductive layer 220a, and a depressed portion is provided in the conductive layer 220b. In other words, the conductive layer 220 includes a depressed portion, the bottom surface of the depressed portion corresponds to the bottom surface of the depressed portion of the conductive layer 220b, and a side surface of the depressed portion corresponds to a side surface of the depressed portion of the conductive layer 220b. Specifically, the conductive layer 220b includes a first depressed portion and a second depressed portion positioned outside the first depressed portion. The first depressed portion is deeper than the second depressed portion. The second depressed portion is provided in the conductive layer 220b at the time of forming the opening portion 290, and then the first depressed portion is provided in the conductive layer 220b at the time of processing the insulating layer 235. Thus, in FIG. 4B and the like, a side surface of the first depressed portion and a surface of the insulating layer 235 on the semiconductor layer 230 side are aligned, and a side surface of the second depressed portion and a side surface of the insulating layer 280a and the like on the opening portion 290 side are aligned. Hereinafter, the first depressed portion and the second depressed portion are collectively referred to as a depressed portion in some cases.

The opening portion 290 overlaps with the depressed portion of the conductive layer 220b. Here, the bottom portion of the opening portion 290 includes the bottom surface of the depressed portion of the conductive layer 220b, and a sidewall of the opening portion 290 includes the side surface of the depressed portion of the conductive layer 220b, the side surface of the insulating layer 280a, a side surface of the conductive layer 255, a side surface of the insulating layer 280b, a side surface of the conductive layer 240a, and a side surface of the conductive layer 240b.

The opening portion 290 includes an opening portion included in the insulating layer 280a, an opening portion included in the conductive layer 255, an opening portion included in the insulating layer 280b, an opening portion included in the conductive layer 240a, and an opening portion included in the conductive layer 240b. In other words, the opening portion included in a region where the insulating layer 280a overlaps with the conductive layer 220a is part of the opening portion 290, the opening portion included in a region where the conductive layer 255 overlaps with the conductive layer 220a is another part of the opening portion 290, the opening portion included in a region where the insulating layer 280b overlaps with the conductive layer 220a is another part of the opening portion 290, the opening portion included in a region where the conductive layer 240a overlaps with the conductive layer 220a is another part of the opening portion 290, and the opening portion included in a region where the conductive layer 240b overlaps with the conductive layer 220a is another part of the opening portion 290. The shape and the size of the opening portion 290 in the plan view may differ from layer to layer. When the opening portion 290 has a circular top-view shape, the opening portions included in the layers may be, but not necessarily concentrically arranged.

At least part of the components of the transistor 200 is provided in the opening portion 290. Specifically, at least part of the insulating layer 235, the semiconductor layer 230, the insulating layer 250, and the conductive layer 265 is provided in the opening portion 290.

The insulating layer 235 includes a region positioned between the semiconductor layer 230 and the conductive layer 255. The semiconductor layer 230 includes a region in contact with the insulating layer 235 in the opening portion 290.

In FIG. 4B and the like, the insulating layer 235 includes a region in contact with the bottom surface of the second depressed portion of the conductive layer 220 and a region in contact with the side surface of the second depressed portion of the conductive layer 220. The insulating layer 235 includes a region in contact with the side surface of the insulating layer 280a, a region in contact with the side surface of the conductive layer 255, a region in contact with the side surface of the insulating layer 280b, a region in contact with the side surface of the conductive layer 240a, and a region in contact with the side surface of the conductive layer 240b in the opening portion 290. The semiconductor layer 230 includes a region in contact with the bottom surface of the first depressed portion of the conductive layer 220, a region in contact with the side surface of the first depressed portion of the conductive layer 220, a region in contact with the insulating layer 235, and a region in contact with the top surface of the conductive layer 240b. The insulating layer 250 is positioned inside the semiconductor layer 230 in the opening portion 290, and the conductive layer 265a is positioned inside the insulating layer 250 in the opening portion 290.

The insulating layer 235 is provided along at least part of the sidewall of the opening portion 290. Portions of the semiconductor layer 230 and the insulating layer 250 which are provided in the opening portion 290 reflect the shape of the opening portion 290. Specifically, the semiconductor layer 230 is provided to cover the bottom and the sidewall of the opening portion 290, and the insulating layer 250 is provided to cover the semiconductor layer 230. Then, the conductive layer 265a is provided to fill at least part of a depressed portion of the insulating layer 250 reflecting the shape of the opening portion 290.

In the transistor of one embodiment of the present invention, at least one layer included in the conductive layer 265 is provided in the opening portion 290. In the case where the conductive layer 265 has a stacked-layer structure, as miniaturization of the transistor 200 proceeds and the diameter of the opening portion 290 becomes smaller, it becomes difficult to arrange all the layers included in the conductive layer 265 in the opening portion 290. FIGS. 4B and 4C illustrate an example in which the conductive layer 265 has a two-layer structure, only the conductive layer 265a is provided in the opening portion 290, and the conductive layer 265b over the conductive layer 265a is provided in a position overlapping with the opening portion 290. Note that in some cases, both the conductive layer 265a and the conductive layer 265b are positioned in the opening portion 290 depending on the diameter of the opening portion 290, the thickness of the conductive layer 265a, and the like.

When the conductive layer 220b includes the depressed portion in a position overlapping with the opening portion 290, unlike the case where the depressed portion is not provided, the levels of the bottom surfaces of the insulating layer 250 and the conductive layer 265a in the opening portion 290 can be lower than the level of the top surface of the conductive layer 220b which is in contact with the insulating layer 280a, with the top surface of the insulating layer 210 used as a reference. Here, the levels of the surfaces can be determined using the formation surface of the transistor as a reference. Here, the top surface of the insulating layer 210 is used as the reference. The surface used as the reference is not limited to the formation surface of the transistor. For example, the top surface of the substrate where the transistor or the semiconductor device is provided may be used as the reference.

As illustrated in FIG. 5, a shortest distance Tc from the top surface of the insulating layer 210 to the top surface of the conductive layer 220b which is in contact with the insulating layer 280a is preferably longer than a shortest distance Ta from the top surface of the insulating layer 210 to the bottom surface of the insulating layer 250. Accordingly, the contact area between the side surface of the conductive layer 220b and the semiconductor layer 230 can be increased, so that the contact resistance therebetween can be reduced. Thus, a decrease in on-state current of the transistor 200 due to the contact resistance between the conductive layer 220b and the semiconductor layer 230 can be inhibited. Note that the shortest distance Ta can be determined on the basis of the bottom surface of the insulating layer 250 in the opening portion 290.

As illustrated in FIG. 5, the shortest distance Tc is preferably longer than or equal to a shortest distance Tb from the top surface of the insulating layer 210 to the bottom surface of the conductive layer 265a, further preferably longer than the shortest distance Tb. Thus, an electric field from the conductive layer 265a is applied to the entire region of the semiconductor layer 230 sandwiched between its source region and drain region. That is, an electric field from the conductive layer 265a is applied to the entire channel formation region of the semiconductor layer 230, so that the amount of the on-state current of the transistor 200 can be increased. Thus, the transistor 200 can have favorable electric characteristics. Furthermore, the gate electric field is easily applied to a region of the semiconductor layer 230 which is in contact with the conductive layer 220b, so that the amount of the on-state current of the transistor 200 can be further increased. The electrical characteristics of the transistor 200 can be improved when either the conductive layer 220 or the conductive layer 240 is used as the drain electrode. Note that the shortest distance Tb can be determined on the basis of the bottom surface of the conductive layer 265a in the opening portion 290.

The semiconductor layer 230 is in contact with the bottom and side surfaces of the depressed portion of the conductive layer 220b and the top surface of the conductive layer 240b. When the conductive layer 220b has a depressed portion, the area where the semiconductor layer 230 is in contact with the conductive layer 220b can be increased. Thus, the contact resistance between the semiconductor layer 230 and the conductive layer 220b can be reduced.

In the case where an oxide semiconductor which is one kind of a metal oxide is used for the semiconductor layer 230, a conductive material containing oxygen is preferably used for the conductive layer 220b. Accordingly, the contact resistance between the conductive layer 220b and the semiconductor layer 230 that is an oxide semiconductor can be reduced.

A conductive material containing oxygen has low contact resistance with the oxide semiconductor; thus, in the case where the conductive layer 220 and the conductive layer 240 each have a stacked-layer structure, it is preferable for each of the stacked-layer structures to include a conductive material containing oxygen in a layer with the largest area contacted with the semiconductor layer 230 which is an oxide semiconductor. Therefore, a conductive material containing oxygen is preferably used for the conductive layer 220b and the conductive layer 240b, for example.

Alternatively, in the case where the conductive layer 220 and the conductive layer 240 each have a stacked-layer structure, it is preferable for each of the stacked-layer structures to include a conductive material containing oxygen in a layer closet to the channel formation region, whereby the amount of on-state current of the transistor using an oxide semiconductor for the semiconductor layer 230 can be increased. Therefore, for example, a conductive material containing oxygen is preferably used for the conductive layer 220b and the conductive layer 240a.

As a conductive material containing oxygen, a metal oxide having conductivity (also referred to as an “oxide conductor”) is preferably used.

FIG. 4B illustrates a structure where an end portion of the conductive layer 240a, an end portion of the conductive layer 240b, and an end portion of the semiconductor layer 230 are aligned with each other outside the opening portion 290. The conductive layer 240a, the conductive layer 240b, and the semiconductor layer 230 can be formed using the same mask in the same step. Thus, the number of masks required for manufacturing the semiconductor device can be reduced. For example, in the X direction or the Y direction, any one of the end portion of the semiconductor layer 230, the end portion of the conductive layer 240a, and the end portion of the conductive layer 240b may be positioned inward or outward from the others.

The conductive layer 240 includes the opening portion 290 in a region overlapping with the conductive layer 220. The conductive layer 240 is preferably not positioned inside the opening portion 290 included in the insulating layer 280b or the like. That is, the conductive layer 240 preferably does not include a region in contact with the side surface of the insulating layer 280b in the opening portion 290. With such a structure, the opening portion 290 can be formed in the conductive layer 240, the insulating layer 280b, the conductive layer 255, and the insulating layer 280a at once. When the side surfaces of the conductive layer 240, the insulating layer 280b, the conductive layer 255, and the insulating layer 280a are aligned in the opening portion 290, the thickness distribution of the insulating layer 235, the semiconductor layer 230, and the like provided inside the opening portion 290 can be made uniform. In addition, the insulating layer 235, the semiconductor layer 230, and the like can be inhibited from being divided by a step between the conductive layer 240 and the insulating layer 280b, for example.

Although FIGS. 4B and 4C illustrate the structure where the side surface of the conductive layer 240 in the opening portion 290 and the side surface of the insulating layer 280b in the opening portion 290 are on the same plane (also referred to as being aligned or substantially aligned with other), the present invention is not limited thereto. For example, the side surface of the conductive layer 240 in the opening portion 290 and the side surface of the insulating layer 280b in the opening portion 290 may be discontinuous. The inclination of the side surface of the conductive layer 240 in the opening portion 290 and the inclination of the side surface of the insulating layer 280b in the opening portion 290 may be different from each other. At this time, for example, the taper angle of the side surface of the conductive layer 240 in the opening portion 290 is preferably smaller than that of the side surface of the insulating layer 280b in the opening portion 290. With such a structure, the coverage of the side surface of the conductive layer 240 with the semiconductor layer 230 in the opening portion 290 is improved, so that defects such as voids can be reduced. In the case where the insulating layer 280a and the insulating layer 280b each have a stacked-layer structure, the inclinations of the side surfaces of the layers in the opening portion 290 may be different from each other. Similarly, in the case where the conductive layer 240 has a stacked-layer structure, the inclinations of the side surfaces of the layers in the opening portion 290 may be different from each other.

An oxide semiconductor is preferably used for the semiconductor layer 230 where a channel is formed. In this specification, a transistor in which an oxide semiconductor is used for a semiconductor layer where a channel is formed is also referred to as an “OS transistor”. An oxide semiconductor has a band gap of 2 eV or more and thus has an extremely low off-state current. Thus, when the OS transistor is used as the transistor WTr, the data written to the retention node SN can be retained for a long period.

In addition, the OS transistor operates stably even in a high-temperature environment and has small fluctuation in characteristics. For example, the off-state current hardly increases even in a high-temperature environment. Specifically, the off-state current hardly increases even at an environment temperature higher than or equal to room temperature and lower than or equal to 200° C. In addition, the on-state current of the OS transistor is less likely to decrease even in a high-temperature environment. The OS transistor has high withstand voltage between its source and drain. Thus, a memory circuit or a memory element using an OS transistor (also referred to as an “OS memory”) can operate stably and have high reliability even in a high-temperature environment.

Furthermore, the OS memory allows a variation in electrical characteristics due to irradiation with radiation such as cosmic rays to be small. That is, the OS memory is less likely to cause a soft error by the radiation and has high reliability.

When the OS transistor is used as both the transistor WTr and the transistor RTr, a highly reliable memory element can be achieved.

Meanwhile, when oxygen vacancies (Vo) and impurities are in a channel formation region of an oxide semiconductor in an OS transistor, electrical characteristics of the OS transistor easily vary and the reliability thereof might worsen. In some cases, hydrogen in the vicinity of an oxygen vacancy forms a defect that is an oxygen vacancy into which hydrogen enters (hereinafter sometimes referred to as VoH), which generates an electron serving as a carrier. Thus, when the channel formation region of the oxide semiconductor includes oxygen vacancies, the OS transistor tends to have normally-on characteristics. Therefore, the oxygen vacancies and the impurities are preferably reduced as much as possible in the channel formation region of the oxide semiconductor. In other words, the oxide semiconductor preferably includes an i-type (intrinsic) or substantially i-type channel formation region with a low carrier concentration.

Meanwhile, preferably, the source region and the drain region of the OS transistor include more oxygen vacancies, include more VoH, or have a higher concentration of an impurity such as hydrogen, nitrogen, or a metal element than the channel formation region, and thus are low-resistance regions with high carrier concentrations. In other words, the source region and the drain region of the OS transistor are preferably n-type regions having higher carrier concentrations and lower resistances than the channel formation region.

As described above, the semiconductor layer 230 is provided inside the opening portion 290. The transistor 200 has a structure in which a current flows in the vertical direction since one of a source electrode and a drain electrode (here, the conductive layer 220) is positioned below and the other of the source electrode and the drain electrode (here, the conductive layer 240) is positioned above. That is, a channel is formed along the side surface of the opening portion 290.

That is, the source electrode and the drain electrode are provided in the Z direction in the transistor 200. The source region and the drain region of the transistor 200 are provided at different levels. In other words, the source region and the drain region of the transistor 200 are provided in different positions in the Z direction. Such a transistor is also referred to as a “vertical-channel transistor”, a “vertical transistor”, or a “vertical field-effect transistor (VFET)”.

The area occupied by a vertical transistor can be smaller than the area occupied by a conventional transistor whose channel formation region, source region, and drain region are provided separately on the XY plane (e.g., a planar transistor). Thus, the use of a vertical-channel transistor can reduce the area occupied by the memory cell 10. This can reduce the area occupied by the memory device including the memory cells 10. This can also increase the memory density of the memory device including the memory cells 10. Moreover, the storage capacity per unit area of the semiconductor device using the memory cells 10 can be increased. Furthermore, the use of a vertical-channel transistor in a semiconductor device achieves an area reduction and high integration of the semiconductor device.

The positional relation of layers in the opening portion 290 is described with reference to FIGS. 4D and 4E. The insulating layer 235 is in contact with an outer surface of the semiconductor layer 230. The conductive layer 255 surrounds the entire outer periphery of the semiconductor layer 230 with the insulating layer 235 therebetween. The insulating layer 250 is in contact with an outer surface of the conductive layer 265a. The semiconductor layer 230 surrounds the entire outer periphery of the conductive layer 265a with the insulating layer 250 therebetween. Thus, the channel formation region of the transistor 200 can be formed on the entire outer surface of the semiconductor layer 230 in the opening portion 290 (the entire region in contact with the insulating layer 235). Note that FIG. 4E can be regarded as a cross-sectional view along the XY plane including the channel formation region of the semiconductor layer 230.

The channel length of the transistor 200 can be regarded as a distance between the source region and the drain region. That is, it can be said that the channel length of the transistor 200 is determined by the thicknesses of the insulating layer 280a, the conductive layer 255, the insulating layer 280b, and the like that are over the conductive layer 220. That is, it can be said that the channel formation region of the semiconductor layer 230 includes a region overlapping with the side surface of the insulating layer 280a, a region overlapping with the side surface of the conductive layer 255, and a region overlapping with the side surface of the insulating layer 280b.

Since the transistor 200 includes the conductive layer 255 functioning as a back gate, the threshold voltage of the transistor 200 can be controlled by a potential supplied to the conductive layer 255. At this time, a portion of the semiconductor layer 230 that overlaps with the conductive layer 255 with the insulating layer 235 therebetween is most likely to be affected by the conductive layer 255. Thus, in FIG. 5, the semiconductor layer 230 is divided into three regions: a region 230n+, a region 230n−, and a region 230i. The region 230i corresponds to a portion of the semiconductor layer 230 that overlaps with the conductive layer 255 with the insulating layer 235 therebetween.

The region 230n+ is formed in and near a region of the semiconductor layer 230 that is in contact with the conductive layer 240b or the conductive layer 220b, and can be referred to as a source region or a drain region. The source and drain regions are n-type regions (low-resistance regions) having a higher carrier concentration than the channel formation region.

The region 230i is a region of the semiconductor layer 230 that overlaps with the conductive layer 255 with the insulating layer 235 therebetween and overlaps with the conductive layer 265a with the insulating layer 250 therebetween. The region 230i functions as the channel formation region. The channel formation region is preferably controlled to be an intrinsic (i-type) or substantially i-type by a potential supplied to the conductive layer 255.

The region 230n− preferably has a higher resistance than the region 230n+ and a lower resistance than the region 230i. However, when a high-resistance region is included between the region 230i and the region 230n+, the amount of the on-state current of the transistor 200 might be decreased. When the region 230n− has a relatively low resistance, the amount of the on-state current of the transistor 200 can be increased in some cases. Note that the region 230n− also functions as a channel formation region in some cases.

As described above, when the channel length of the transistor 200 is regarded as the distance between the source region and the drain region, the channel length of the transistor 200 can be a length L1. Meanwhile, since the region 230n− has a lower resistance than the region 230i, the channel formation region of the transistor 200 can be regarded as the region 230i that is controlled to be a high-resistance region by the conductive layer 255. In that case, the channel length of the transistor 200 can be regarded as a length L0 of the region 230i that is shorter than the length L1. In this case, the length L0 can also be referred to as the effective channel length of the transistor 200.

When the resistance of the region 230n− is low and the effective channel length of the transistor 200 is short, the transistor 200 tends to have normally-on characteristics. Meanwhile, the transistor of one embodiment of the present invention includes a back gate. When a potential lower than or equal to a source potential or a potential lower than or equal to 0 V (preferably a negative potential) is supplied to the back gate, the threshold voltage of the transistor can be shifted in the positive direction and the transistor can have normally-off characteristics. Accordingly, the transistor of one embodiment of the present invention can achieve both high on-state current and normally-off characteristics.

In the transistor of one embodiment of the present invention, either the conductive layer 255 or the conductive layer 265 may be used as a gate or a back gate. In particular, the transistor of one embodiment of the present invention is preferably formed using the conductive layer 265 and the conductive layer 255 as a gate and a back gate, respectively. When a region of the conductive layer 265 facing the semiconductor layer 230, which is wider than a region of the conductive layer 255 facing the semiconductor layer 230, is used for a gate, a gate electric field is applied to the semiconductor layer 230 more efficiently; thus, the electrical characteristics of the transistor can be improved in some cases.

In a planar transistor, the channel length is limited by the light exposure limit of photolithography; however, in one embodiment of the present invention, the channel length can be determined by the thicknesses of the insulating layers 280a and 280b. Thus, the channel length of the transistor 200 can be less than or equal to the light exposure limit of photolithography allowing a quite minute structure (e.g., greater than or equal to 1 nm and less than or equal to 60 nm, greater than or equal to 1 nm and less than or equal to 50 nm, greater than or equal to 1 nm and less than or equal to 40 nm, greater than or equal to 1 nm and less than or equal to 30 nm, greater than or equal to 1 nm and less than or equal to 20 nm, or greater than or equal to 1 nm and less than or equal to 10 nm). Accordingly, the transistor 200 can have a higher on-state current and higher frequency characteristics. The vertical transistor facilitates a reduction in channel length, and thus an increase in the amount of on-state current (a reduction in on-state resistance) can be easily achieved. With the use of a vertical-channel transistor, a semiconductor device with high operation speed can be provided.

As illustrated in FIG. 4D, the insulating layer 235, the semiconductor layer 230, the insulating layer 250, and the conductive layer 265a are provided concentrically. Therefore, a side surface of the conductive layer 265a provided at the center faces a side surface of the semiconductor layer 230 with the insulating layer 250 therebetween. That is, in the top view, all the perimeter of the semiconductor layer 230 serves as the channel formation region. In this case, for example, the channel width of the transistor 200 is determined by the length of the outer periphery of the semiconductor layer 230. In other words, the channel width of the transistor 200 is determined by the width of the opening portion 290 (the diameter in the case where the opening portion 290 is circular in the top view). The width D of the opening portion 290 is shown in FIGS. 4B to 4E, and a channel width W of the transistor 200 is shown in FIG. 4E. By increasing the width D of the opening portion 290, the channel width per unit area can be increased and the amount of the on-state current can be increased.

Note that the width D of the opening portion 290 changes in the depth direction in some cases. Here, the shortest distance between two side surfaces of the conductive layer 255 which face each other with the opening portion 290 therebetween in a cross-sectional view that is perpendicular to the Z direction (e.g., FIG. 4B or 4C) is particularly used as the width D. In other words, the minimum width of the opening portion 290 in the conductive layer 255 seen from the Z direction is used as the width D of the opening portion 290. The width of the opening portion 290 at the highest position, the width of the opening portion 290 at the lowest position, the width of the opening portion 290 at the intermediate position, or the average value of these three widths may be used as the width D of the opening in the conductive layer 255. Although an example in which the width D is determined using the width of the opening portion 290 of the conductive layer 255 is described here, there is no particular limitation on the method for determining the width D. For example, the shortest distance of the width of the opening portion 290 in any of the insulating layer 280a, the insulating layer 280b, the conductive layer 240a, and the conductive layer 240b, which are seen from the Z direction, can be used as the width D. In any of the insulating layer 280a, the insulating layer 280b, the conductive layer 240a, and the conductive layer 240b, the width of the opening portion 290 at the highest position, the width of the opening portion 290 at the lowest position, the width of the opening portion 290 at the intermediate position, or the average value of these three widths may be used as the width D.

In the case where the opening portion 290 is formed by a photolithography method, the width D of the opening portion 290 is limited by the light exposure limit of photolithography. In addition, the width D of the opening portion 290 is limited by the thicknesses of the insulating layer 235, the semiconductor layer 230, the insulating layer 250, and the conductive layer 265a provided in the opening portion 290. The width D of the opening portion 290 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. In the case where the opening portion 290 is circular in the top view, the width D of the opening portion 290 corresponds to the diameter of the opening portion 290, and the channel width W can be calculated to be “D×π”.

The channel length L of the transistor 200 is preferably shorter than at least the channel width W of the transistor 200. The channel length L of the transistor 200 is preferably greater than or equal to 0.1 times and less than or equal to 0.99 times, further preferably greater than or equal to 0.5 times and less than or equal to 0.8 times the channel width W of the transistor 200. This structure enables a transistor with favorable electrical characteristics and high reliability.

As described above, in the case where the opening portion 290 is formed to be circular in the plan view, the insulating layer 235, the semiconductor layer 230, the insulating layer 250, and the conductive layer 265a are formed concentrically. Accordingly, the distance between the conductive layer 255 and the semiconductor layer 230 and the distance between the conductive layer 265a and the semiconductor layer 230 are substantially uniform, so that a gate electric field can be substantially uniformly applied to the semiconductor layer 230.

Although an example where the opening portion 290 is circular in the plan view is described in this embodiment, the present invention is not limited thereto. The opening portion 290 in the plan view can have a circular shape, a substantially circular shape such as an elliptical shape, a polygonal shape such as a triangular shape, a quadrangular shape (including a rectangular shape, a rhombic shape, and a square), a pentagonal shape, or a star polygonal shape, or any of these polygonal shapes whose corners are rounded, for example. Note that the polygonal shape may be a concave polygonal shape (a polygonal shape at least one of the interior angles of which is greater than 180°) or a convex polygonal shape (a polygonal shape all the interior angles of which are less than or equal to 180°). As illustrated in FIG. 4A and the like, the opening portion 290 in the plan view preferably have a circular shape. When the opening portion has a circular shape in the plan view, processing accuracy in forming the opening portion can be high, whereby the opening portion can be formed to have minute sizes. Note that in this specification and the like, a circular shape is not necessarily a perfect circular shape.

### <Constituent Materials of Semiconductor Device>

Materials that can be used for a semiconductor device of one embodiment of the present invention, such as a transistor, a memory cell, a memory string, or a memory device, are described below. Note that the layers included in the semiconductor device of one embodiment of the present invention may have a single-layer structure or a stacked-layer structure. FIGS. 4B and 4C each illustrate an example in which the conductive layer 220a has a single-layer structure. FIG. 5 illustrates an example in which the conductive layer 220a has a stacked-layer structure.

### [Semiconductor Layer 230]

As described above, the semiconductor layer 230 includes a channel formation region. The semiconductor layer 230 further includes a source region and a drain region. The source and drain regions are n-type regions (low-resistance regions) having a higher carrier concentration than the channel formation region. The semiconductor layer 230 may have a stacked-layer structure of two or more layers.

There is no particular limitation on the crystallinity of the semiconductor material used for the semiconductor layer 230, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. It is preferable to use a single crystal semiconductor or a semiconductor having crystallinity, in which case deterioration of the transistor characteristics can be suppressed.

In the case where an oxide semiconductor which is one kind of a metal oxide is used for the semiconductor layer 230, the band gap of the metal oxide is preferably greater than or equal to 2.0 eV, further preferably greater than or equal to 2.5 eV. The use of such a metal oxide having a wide band gap for the semiconductor layer 230 can reduce the amount of the off-state current of the transistor. The off-state current of the OS transistor is small, so that power consumption of the semiconductor device can be sufficiently reduced. The OS transistor has high frequency characteristics, which enables the semiconductor device to operate at high speed.

For the oxide semiconductor that can be used for the semiconductor layer of the transistor of one embodiment of the present invention, the description in Embodiment 3 can be referred to. Here, detailed description thereof is omitted.

Note that for the semiconductor device of this embodiment, a transistor containing another semiconductor material in a channel formation region may be used. Examples of another semiconductor material include a single-element semiconductor and a compound semiconductor. Examples of the single-element semiconductor include silicon and germanium. Examples of the compound semiconductor include gallium arsenide and silicon germanium. Other examples of the compound semiconductor include an organic semiconductor and a nitride semiconductor. Note that the above-described oxide semiconductor is also one kind of the compound semiconductor. These semiconductor materials may contain an impurity as a dopant.

Examples of silicon that can be used as a semiconductor material of a transistor include single crystal silicon, polycrystalline silicon, microcrystalline silicon, and amorphous silicon. An example of polycrystalline silicon is low-temperature polysilicon (LTPS).

Alternatively, a semiconductor layer of a transistor may contain a layered material functioning as a semiconductor. The layered material generally refers to a group of materials having a layered crystal structure. In the layered crystal structure, layers formed by covalent bonding or ionic bonding are stacked with bonding such as the van der Waals bonding, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, the transistor can have a high on-state current.

Examples of the layered material include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

### [Insulating Layers]

An inorganic insulating film is preferably used as each of the insulating layers (the insulating layer 210, the insulating layer 235, the insulating layer 250, the insulating layer 280a, the insulating layer 280b, and the like). Examples of the inorganic insulating film include an oxide insulating film, a nitride insulating film, an oxynitride insulating film, and a nitride oxide insulating film. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, a tantalum oxide film, a cerium oxide film, a gallium zinc oxide film, and a hafnium aluminate film. Examples of the nitride insulating film include a silicon nitride film and an aluminum nitride film. Examples of the oxynitride insulating film include a silicon oxynitride film, an aluminum oxynitride film, a gallium oxynitride film, an yttrium oxynitride film, and a hafnium oxynitride film. Examples of the nitride oxide insulating film include a silicon nitride oxide film and an aluminum nitride oxide film. An organic insulating film may be used as the insulating layer included in the semiconductor device.

With miniaturization and high integration of a transistor, for example, a problem such as generation of leakage current may arise because of a thin gate insulating layer. When a high-k material is used for the insulating layer functioning as a gate insulating layer such as the insulating layer 235 and the insulating layer 250, the voltage at the time of operation of the transistor can be reduced while the physical thickness is maintained. In addition, the equivalent oxide thickness (EOT) of the gate insulating layer can be reduced. By contrast, when a material with a low dielectric constant is used for the insulating layer functioning as an interlayer film, parasitic capacitance generated between wirings can be reduced. Thus, a material can be selected depending on the function of an insulating layer. Note that a material with a low dielectric constant is a material with high dielectric strength.

Examples of a material with a high dielectric constant (a high-k material) include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a material with a low dielectric constant include inorganic insulating materials such as silicon oxide, silicon oxynitride, and silicon nitride oxide, and resins such as polyester, polyolefin, polyamide (e.g., nylon and aramid), polyimide, polycarbonate, and an acrylic resin. Other examples of an inorganic insulating material with a low dielectric constant include silicon oxide to which fluorine is added, silicon oxide to which carbon is added, and silicon oxide to which carbon and nitrogen are added. Another example is porous silicon oxide. Note that these silicon oxides may contain nitrogen.

A material that can show ferroelectricity may be used for the insulating layers 235 and 250. Examples of the material that can show ferroelectricity include metal oxides such as hafnium oxide, zirconium oxide, and HfZrO_{X} (X is a real number greater than 0). Examples of the material that can show ferroelectricity also include a material in which an element J1 (the element J1 here is one or more of zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 can be, for example, 1:1 or the neighborhood thereof. Examples of the material that can show ferroelectricity also include a material in which an element J2 (the element J2 here is one or more of hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 can be, for example, 1:1 or the neighborhood thereof. As the material that can show ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can show ferroelectricity also include a metal nitride containing an element M1, an element M2, and nitrogen. Here, the element M1 is one or more of aluminum, gallium, indium, and the like. The element M2 is one or more of boron, scandium, yttrium, lanthanum, cerium, neodymium, europium, titanium, zirconium, hafnium, vanadium, niobium, tantalum, chromium, and the like. Note that the atomic ratio of the element M1 to the element M2 can be set as appropriate. A metal oxide containing the element M1 and nitrogen shows ferroelectricity in some cases even though the metal oxide does not contain the element M2. Examples of the material that can show ferroelectricity also include the above metal nitride to which an element M3 is added. Note that the element M3 is one or more of magnesium, calcium, strontium, zinc, cadmium, and the like. Here, the atomic ratio between the element M1, the element M2, and the element M3 can be set as appropriate.

Examples of the material that can show ferroelectricity also include perovskite-type oxynitrides such as SrTaO₂N and BaTaO₂N, and GaFeO₃ with a κ-alumina-type structure.

Although metal oxides and metal nitrides are described above as examples, one embodiment of the present invention is not limited thereto. For example, a metal oxynitride in which nitrogen is added to any of the above metal oxides, a metal nitride oxide in which oxygen is added to any of the above metal nitrides, or the like may be used.

As the material that can show ferroelectricity, a mixture or compound containing a plurality of materials selected from the above-listed materials can be used, for example. Alternatively, the insulating layer can have a stacked-layer structure of a plurality of materials selected from the above-listed materials. Since the above-listed materials and the like may change their crystal structures (characteristics) according to a variety of processes and the like as well as deposition conditions, a material that exhibits ferroelectricity is referred to not only as a ferroelectric but also as a material that can show ferroelectricity in this specification and the like.

A metal oxide containing one or both of hafnium and zirconium is preferable because the metal oxide can have ferroelectricity even when being a thin film of several nanometers. A metal oxide containing one or both of hafnium and zirconium is preferable because the metal oxide can have ferroelectricity even with a minute area. Accordingly, the use of a metal oxide containing one or both of hafnium and zirconium enables miniaturization of the semiconductor device.

Note that in this specification and the like, the material that can have ferroelectricity processed into a layered shape is referred to as a ferroelectric layer, a metal oxide film, or a metal nitride film in some cases. Furthermore, a device including such a ferroelectric layer, metal oxide film, or metal nitride film is sometimes referred to as a ferroelectric device in this specification and the like.

Note that ferroelectricity is exhibited by displacement of oxygen or nitrogen of a crystal included in a ferroelectric layer due to an external electric field. Ferroelectricity is presumably exhibited depending on a crystal structure of a crystal included in a ferroelectric layer. Thus, in order that the insulating layer can exhibit ferroelectricity, the insulating layer needs to include a crystal. It is particularly preferable that the insulating layer include a crystal having an orthorhombic crystal structure, in which case ferroelectricity is exhibited. A crystal included in the insulating layer may have one or more of crystal structures selected from cubic, tetragonal, orthorhombic, monoclinic, and hexagonal crystal structures. Alternatively, the insulating layer may have an amorphous structure. In that case, the insulating layer may have a composite structure including an amorphous structure and a crystal structure.

Addition of a Group 3 element (also referred to as IIIa element) in the periodic table to an oxide containing one or both of hafnium and zirconium increases the oxygen vacancy concentration in the oxide and facilitates formation of a crystal having an orthorhombic crystal structure. This is preferable because the proportion of the crystal having an orthorhombic crystal structure is increased and the amount of remanent polarization can be increased. On the other hand, too much addition of the Group 3 element might decrease the crystallinity of the oxide and hinder the exhibition of ferroelectricity. Thus, the content percentage of the Group 3 element in the oxide containing one or both of hafnium and zirconium is preferably higher than or equal to 0.1 atomic % and lower than or equal to 10 atomic %, further preferably higher than or equal to 0.1 atomic % and lower than or equal to 5 atomic %, still further preferably higher than or equal to 0.1 atomic % and lower than or equal to 3 atomic %. Here, the content percentage of the Group 3 element refers to the proportion of the number of the Group 3 element atoms in the number of all metal element atoms contained in the layer. The Group 3 element is preferably one or more selected from scandium, lanthanum, and yttrium, further preferably one or both of lanthanum and yttrium.

A transistor including a metal oxide can have stable electrical characteristics when surrounded by an insulating layer having a function of inhibiting passage of impurities and oxygen. The insulating layer having a function of inhibiting passage of impurities and oxygen can have, for example, a single-layer structure or a stacked-layer structure of an insulating layer containing one or more of boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum. Specifically, as a material for the insulating layer having a function of inhibiting passage of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide or a metal nitride such as aluminum nitride, silicon nitride oxide, or silicon nitride can be used.

Specifically, for the insulating layer having a function of inhibiting passage of oxygen and impurities such as water and hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide can be used. Other examples of the insulating layer having a function of inhibiting passage of oxygen and impurities such as water and hydrogen include oxides containing aluminum and hafnium (hafnium aluminate). Other examples of the insulating layer having a function of inhibiting passage of oxygen and impurities such as water and hydrogen include metal nitrides such as aluminum nitride, aluminum titanium nitride, titanium nitride, silicon nitride oxide, and silicon nitride.

In addition, an insulating layer in contact with an oxide semiconductor layer, such as the insulating layers 235 and 250, or an insulating layer provided in the vicinity of the oxide semiconductor layer preferably includes a region containing oxygen (hereinafter, sometimes referred to as excess oxygen) that is released by heating. For example, when an insulating layer including a region containing excess oxygen is in contact with an oxide semiconductor layer or positioned in the vicinity of the oxide semiconductor layer, the number of oxygen vacancies in the oxide semiconductor layer can be reduced. Examples of an insulating layer in which a region containing excess oxygen is easily formed include silicon oxide, silicon oxynitride, and porous silicon oxide.

The insulating layer 210 functions as an interlayer film and preferably has a low dielectric constant. In the case where a material with a low dielectric constant is used for an interlayer film, the parasitic capacitance generated between wirings can be reduced. Silicon oxide and silicon oxynitride are thermally stable, and thus are suitable for the insulating layer 210.

The concentration of impurities such as water and hydrogen in the insulating layer 210 is preferably reduced. This can inhibit entry of impurities such as water or hydrogen into the channel formation region of the semiconductor layer 230.

As the insulating layer 210, a barrier insulating layer against hydrogen is preferably used. When the insulating layer 210 provided outside the semiconductor layer 230 has a barrier property against hydrogen, diffusion of hydrogen into the semiconductor layer 230 can be inhibited.

Examples of a material for the barrier insulating layer against hydrogen include aluminum oxide, magnesium oxide, hafnium oxide, gallium oxide, silicon nitride, and silicon nitride oxide.

Note that in this specification and the like, a barrier insulating layer refers to an insulating layer having a barrier property. In addition, the barrier property refers to a property that does not easily allow diffusion of a target substance (also referred to as a property that does not easily allow passage of a target substance, a property with low permeability of a target substance, or a function of inhibiting diffusion of a target substance). Note that hydrogen described as a target substance refers to at least one of a hydrogen atom, a hydrogen molecule, and a substance bonded to hydrogen, such as a water molecule or OH⁻, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), and a copper atom. Oxygen described as a target substance refers to, for example, at least one of an oxygen atom and an oxygen molecule.

For example, a silicon nitride film is preferably used as the insulating layer 210.

In the case where an oxide semiconductor is used for the semiconductor layer 230, each of the insulating layer 280a and the insulating layer 280b preferably includes the above-described barrier insulating layer against hydrogen. The insulating layer 280a and the insulating layer 280b are provided to surround the semiconductor layer 230. When the insulating layer 280a and the insulating layer 280b provided outside the semiconductor layer 230 have a barrier property against hydrogen, diffusion of hydrogen into the semiconductor layer 230 can be inhibited. For example, the insulating layer 280a and the insulating layer 280b each preferably include one or both of an aluminum oxide film and a silicon nitride film.

Note that silicon nitride also has a barrier property against oxygen. Thus, using silicon nitride for the insulating layer 280a and the insulating layer 280b can inhibit extraction of oxygen from the semiconductor layer 230, and accordingly can inhibit formation of an excess amount of oxygen vacancies in the semiconductor layer 230.

In the case where an oxide semiconductor is used for the semiconductor layer 230, the use of silicon nitride for the insulating layer 280a and the insulating layer 280b can prevent excess oxygen from being supplied to the semiconductor layer 230. Thus, the channel formation region of the semiconductor layer 230 can be prevented from containing excess oxygen, whereby the reliability of the transistor 200 can be improved.

The insulating layers 280a and 280b preferably include any of an oxide insulating film, an oxynitride insulating film, and an insulating layer including a region containing excess oxygen, which are described above.

For example, the insulating layer including a region containing excess oxygen can be formed by deposition by a sputtering method in an atmosphere containing oxygen. Since a molecule containing hydrogen is not used as a deposition gas in the sputtering method, the hydrogen concentration in the insulating layers 280a and 280b can be reduced. When at least one layer in each of the insulating layers 280a and 280b is deposited in this manner, oxygen can be supplied from the insulating layers 280a and 280b to the channel formation region of the semiconductor layer 230, so that oxygen vacancies and VoH therein can be reduced.

In the case where an oxide semiconductor is used for the semiconductor layer 230, the concentration of impurities such as water and hydrogen in the insulating layers 280a and 280b are preferably reduced. This can inhibit entry of impurities such as water and hydrogen into the channel formation region of the semiconductor layer 230.

Note that since the thicknesses of the insulating layers 280a and 280b over the conductive layer 220 influence the channel length of the transistor 200, the thicknesses of the insulating layers 280a and 280b are set as appropriate depending on the design value of the channel length of the transistor 200.

For example, a single-layer structure of a silicon nitride film, a silicon nitride oxide film, or an aluminum oxide film is preferably used for the insulating layers 280a and 280b. Alternatively, for example, a three-layer structure where a silicon nitride film, a silicon oxide film, and a silicon nitride film are stacked in this order is preferably used for each of the insulating layers 280a and 280b. For example, a three-layer structure where an aluminum oxide film, a silicon oxide film, and an aluminum oxide film are stacked in this order is preferably used for each of the insulating layers 280a and 280b.

In the case where an oxide semiconductor is used for the semiconductor layer 230, the insulating layer 250 preferably has a function of capturing and fixing hydrogen. In this case, the hydrogen concentration in the semiconductor layer 230 (in particular, the hydrogen concentration in the channel formation region of the transistor) can be reduced. Accordingly, VoH in the channel formation region can be reduced, so that the channel formation region can be an i-type or substantially i-type region.

Examples of a material for an insulating layer having a function of capturing or fixing hydrogen include metal oxides such as an oxide containing hafnium, an oxide containing magnesium, an oxide containing aluminum, and an oxide containing aluminum and hafnium (hafnium aluminate). Furthermore, these metal oxides may further contain zirconium, and an example of such a metal oxide is an oxide containing hafnium and zirconium. Note that in a metal oxide having an amorphous structure, some oxygen atoms have a dangling bond, which allows the metal oxide to have a high property of capturing or fixing hydrogen. Thus, these metal oxides preferably have an amorphous structure. For example, these oxides may have an amorphous structure by containing silicon. For example, an oxide containing hafnium and silicon (hafnium silicate) is preferably used. Note that the metal oxide may partly include one or both of a crystal region and a crystal grain boundary.

Note that a function of capturing or fixing a target substance can also be referred to as a property that does not easily allow diffusion of a target substance. Thus, a function of capturing or fixing a target substance can be rephrased as a barrier property.

In the case where an oxide semiconductor is used for the semiconductor layer 230 and the gate insulating layer has a stacked-layer structure, a layer in contact with the semiconductor layer 230 preferably has a function of capturing or fixing hydrogen. In this case, hydrogen contained in the semiconductor layer 230 can be captured or fixed more effectively. Thus, the hydrogen concentration in the semiconductor layer 230 can be lowered. For a layer of the insulating layer 250 which is in contact with the semiconductor layer 230, hafnium silicate or the like is preferably used, for example. The layer preferably has an amorphous structure.

When the layer has an amorphous structure, formation of a crystal grain boundary can be inhibited. Inhibiting formation of a crystal grain boundary can increase the planarity of the layer. This enables the insulating layer 250 to have uniform thickness distribution and a reduced number of extremely thin portions, so that the withstand voltage of the insulating layer 250 can be increased. Furthermore, the thickness distribution of the film provided over the insulating layer 250 can be uniform.

Furthermore, inhibiting formation of a crystal grain boundary in the layer can reduce leakage current due to the defect states in the crystal grain boundary. Thus, the insulating layer 250 can function as an insulating film with a small leakage current.

Hafnium oxide is a high-k material; thus, depending on the silicon content, hafnium silicate is also a high-k material. Thus, in the case where hafnium oxide or hafnium silicate is used for the gate insulating layer, a gate potential applied at the time of operation of the transistor can be reduced while the physical thickness of the gate insulating layer is maintained. In addition, the EOT of the gate insulating layer can be reduced.

As described above, for the insulating layer 250, an oxide containing one or both of aluminum and hafnium is preferably used, more preferably, an oxide containing one or both of aluminum and hafnium and having an amorphous structure is used, and further preferably, aluminum oxide having an amorphous structure is used.

In the case where an oxide semiconductor is used for the semiconductor layer 230, the above-described barrier insulating layer against hydrogen is preferably used as the insulating layer 250. When a barrier insulating layer against hydrogen is used as the insulating layer 250, diffusion of impurities contained in the conductive layer 265 into the semiconductor layer 230 can be inhibited. For example, silicon nitride is suitable for the insulating layer 250 because of its high barrier property against hydrogen. Furthermore, the insulating layer 250 may include a thermally stable insulating layer such as silicon oxide or silicon oxynitride.

With such a structure, a semiconductor device having favorable electrical characteristics can be provided. A highly reliable semiconductor device can be provided. A semiconductor device with a small variation in transistor electrical characteristics can be provided. A semiconductor device that has a high on-state current can be provided.

Furthermore, the insulating layer 250 may include a thermally stable insulating layer such as silicon oxide or silicon oxynitride.

The insulating layer 250 may include, between a pair of insulating layers having a function of capturing and fixing hydrogen, a thermally stable insulating layer.

The insulating layer 250 preferably includes a barrier insulating layer against oxygen. In this case, oxidation of the conductive layer 240, the conductive layer 265, and the like can be inhibited. In the case where the insulating layer 250 has a stacked-layer structure, a layer in contact with the conductive layer 240 is preferably a barrier insulating layer against oxygen. In particular, the layer in contact with the conductive layer 240 and a layer in contact with the conductive layer 265, which are included in the insulating layer 250, are preferably barrier insulating layers against oxygen.

When a barrier insulating layer against hydrogen and oxygen is used as the layer of the insulating layer 250 which is in contact with the conductive layer 265, oxidation of the conductive layer 265 can be inhibited. Furthermore, in the case where an oxide semiconductor is used for the semiconductor layer 230, diffusion of oxygen contained in the semiconductor layer 230 into the conductive layer 265 can be inhibited, and accordingly formation of oxygen vacancies in the semiconductor layer 230 can be inhibited.

Examples of a barrier insulating layer against oxygen include an oxide containing one or both of aluminum and hafnium, magnesium oxide, gallium oxide, gallium zinc oxide, silicon nitride, and silicon nitride oxide. Examples of the oxide containing one or both of aluminum and hafnium include aluminum oxide, hafnium oxide, an oxide containing aluminum and hafnium (hafnium aluminate), and an oxide containing hafnium and silicon (hafnium silicate).

The layer of the insulating layer 250 which is in contact with the conductive layer 240 is preferably less likely to transmit oxygen than at least the insulating layer 280b. When the layer has a barrier property against oxygen, oxidation of the side surface of the conductive layer 240 can be inhibited, and accordingly formation of an oxide film on the side surface can be inhibited. It is thus possible to inhibit a reduction in the amount of on-state current or field-effect mobility of the transistor 200.

Each layer included in the insulating layer 250 is preferably a thin film. For example, when each layer included in the insulating layer 250 has a thickness greater than or equal to 1 nm and less than or equal to 20 nm, preferably greater than or equal to 3 nm and less than or equal to 10 nm, the subthreshold swing value (also referred to as S value), which is one of transistor characteristics, can be reduced. Note that the S value means the amount of change in gate voltage in the subthreshold region when the drain voltage is constant and the drain current is changed by one order of magnitude.

The thickness of each layer included in the insulating layer 250 is preferably greater than or equal to 0.1 nm and less than or equal to 10 nm, further preferably greater than or equal to 0.1 nm and less than or equal to 5 nm, further preferably greater than or equal to 0.5 nm and less than or equal to 5 nm, further preferably greater than or equal to 1 nm and less than 5 nm, further preferably greater than or equal to 1 nm and less than or equal to 3 nm. Note that each layer included in the insulating layer 250 at least partly includes a region with the above-described thickness.

In the case where the oxide semiconductor is used for the semiconductor layer 230, the insulating layer 250 preferably has a three-layer structure where a first insulating layer containing a material with a low dielectric constant, a second insulating layer having a function of capturing or fixing hydrogen, and a third insulating layer having a barrier property against hydrogen and oxygen are stacked in this order from the semiconductor layer 230 side. As the material with a low dielectric constant contained in the first insulating layer, silicon oxide or silicon oxynitride is preferably used. The first insulating layer is in contact with the semiconductor layer 230. When an oxide is used for the first insulating layer, oxygen can be supplied to the semiconductor layer 230. Providing the third insulating layer can inhibit diffusion of oxygen contained in the first insulating layer into the conductive layer 265 and inhibit oxidation of the conductive layer 265. Furthermore, a reduction in the amount of oxygen supplied from the first insulating layer to the semiconductor layer 230 can be inhibited.

In the case where the oxide semiconductor is used for the semiconductor layer 230, the insulating layer 250 preferably has a four-layer structure where a fourth insulating layer having a barrier property against oxygen, a first insulating layer containing a material with a low dielectric constant, a second insulating layer having a function of capturing or fixing hydrogen, and a third insulating layer having a barrier property against hydrogen and oxygen are stacked in this order from the semiconductor layer 230 side. The first insulating layer to the third insulating layer can have a structure similar to that of the layers used in the above three-layer structure. The fourth insulating layer is in contact with the semiconductor layer 230. When the fourth insulating layer has a barrier property against oxygen, release of oxygen from the semiconductor layer 230 can be inhibited. For the fourth insulating layer, aluminum oxide is preferably used, for example. Aluminum oxide has a function of capturing or fixing hydrogen, and thus is suitably used for the fourth insulating layer in contact with the semiconductor layer 230. Specifically, it is preferable to employ a four-layer structure in which an aluminum oxide film, a silicon oxide film, a hafnium oxide film, and a silicon nitride film are stacked in this order from the semiconductor layer 230 side.

Typically, the thicknesses of the fourth, first, second, and third insulating layers are 1 nm, 2 nm, 2 nm, and 1 nm, respectively. Such a structure enables the transistor to have favorable electrical characteristics even when the transistor is miniaturized or highly integrated.

The insulating layer 250 preferably has a three-layer structure where a fourth insulating layer having a barrier property against oxygen, a first insulating layer containing a material with a low dielectric constant, and a second insulating layer having a function of capturing or fixing hydrogen are stacked in this order from the semiconductor layer 230 side. Specifically, it is preferable to employ a three-layer structure in which an aluminum oxide film, a silicon oxide film, and a hafnium oxide film are stacked in this order from the semiconductor layer 230 side.

Note that, as the insulating layer 210, the above-described insulating layer having a function of capturing or fixing hydrogen may be used. Accordingly, hydrogen in the semiconductor layer 230 diffusing into the insulating layer 210 through the conductive layers 220a and 220b can be captured or fixed. Thus, the hydrogen concentration in the semiconductor layer 230 can be lowered. For example, the insulating layer 210 may have a two-layer structure of a silicon nitride film and a hafnium silicate film over the silicon nitride film.

The insulating layer 235 can also be referred to as a sidewall, a sidewall insulating layer, or a sidewall protective layer, for example.

In the case where an oxide semiconductor is used for the semiconductor layer 230, the insulating layer 235 preferably includes an insulating layer including a region which contains oxygen released by heating. Thus, oxygen can be supplied from the insulating layer 235 to the semiconductor layer 230. For example, silicon oxide or silicon oxynitride is preferably used for the insulating layer 235.

The insulating layer 235 preferably includes a barrier insulating layer against hydrogen. Accordingly, diffusion of hydrogen in the semiconductor layer 230 can be suppressed, and the reliability of the transistor 200 can be improved. For example, aluminum oxide, hafnium oxide, silicon nitride, or silicon nitride oxide is preferably used for the insulating layer 235.

For the insulating layer 235, the above-described material that can have ferroelectricity can also be used.

For example, the insulating layer 235 can have a single-layer structure of a silicon oxide film, a single-layer structure of a silicon nitride film, a two-layer structure of a silicon oxide film and a silicon nitride film, a three-layer structure of a silicon oxide film, a silicon nitride film, and a silicon oxide film, and a three-layer structure of a silicon nitride film, a silicon oxide film, and a silicon nitride film. In the case of a two-layer structure of a silicon oxide film and a silicon nitride film, for example, it is preferable that a silicon oxide film be provided on the semiconductor layer 230 side and a silicon nitride film be provided on the conductive layer 255 side. Accordingly, oxygen can be efficiently supplied to the semiconductor layer 230 and diffusion of impurities such as hydrogen into the semiconductor layer 230 can be inhibited. Alternatively, a silicon nitride film may be provided on the semiconductor layer 230 side, and a silicon oxide film may be provided on the conductive layer 255 side.

### [Conductive Layers]

For each of the conductive layers (the conductive layers 220, 240, 255, 265, and the like) included in the semiconductor device, it is preferable to use a metal element selected from aluminum, chromium, copper, silver, gold, platinum, zinc, tantalum, nickel, titanium, iron, cobalt, molybdenum, tungsten, hafnium, vanadium, niobium, manganese, magnesium, zirconium, beryllium, indium, ruthenium, iridium, strontium, lanthanum, and the like; an alloy containing any of the above metal elements as a component; an alloy containing a combination of the above metal elements; or the like. As an alloy containing any of the above metal elements, a nitride of the alloy or an oxide of the alloy may be used. For example, tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. Alternatively, a semiconductor having high electric conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. Examples of the conductive material containing oxygen include indium oxide containing tungsten oxide, indium oxide containing titanium oxide, indium tin oxide (also referred to as ITO), indium tin oxide containing titanium oxide, indium tin oxide to which silicon is added (also referred to as ITSO), indium zinc oxide (also referred to as IZO (a registered trademark)), and indium zinc oxide containing tungsten oxide. In this specification and the like, a conductive film formed using the conductive material containing oxygen may be referred to as an oxide conductive film.

In addition, a conductive material containing tungsten, copper, or aluminum as its main component is preferable because it has high conductivity.

Conductive layers formed using any of the above materials may be stacked. For example, a stacked-layer structure combining a material containing any of the above metal elements and a conductive material containing oxygen may be employed. Alternatively, a stacked-layer structure combining a material containing any of the above metal elements and a conductive material containing nitrogen may be employed. Further alternatively, a stacked-layer structure combining a material containing any of the above metal elements, a conductive material containing oxygen, and a conductive material containing nitrogen may be employed.

In the case where a metal oxide is used for the channel formation region of the transistor, the conductive layer functioning as the gate electrode such as the conductive layers 255 and 265 preferably employs a stacked-layer structure combining a material containing any of the above metal elements and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

In the case where the oxide semiconductor is used for the semiconductor layer 230, each of the conductive layers 220 and 240 is in contact with the semiconductor layer 230, and thus is preferably formed using a conductive material that is not easily oxidized, a conductive material that maintains its low electric resistance even after being oxidized, a metal oxide that has conductivity (also referred to as an oxide conductor), or a conductive material that has a function of inhibiting diffusion of oxygen. Examples of the conductive material include a conductive material containing nitrogen and a conductive material containing oxygen. Thus, a decrease in conductivity of the conductive layers 220 and 240 can be inhibited.

When a conductive material containing oxygen is used for the conductive layer 220 or the conductive layer 240, the conductive layer 220 or the conductive layer 240 can maintain its conductivity even after absorbing oxygen. It is also preferable that an insulating layer containing oxygen, such as hafnium oxide, be used as the insulating layer 210 in order that the conductive layer 220 can maintain its conductivity. For each of the conductive layers 220 and 240, ITO, ITSO, IZO (registered trademark), or the like is preferably used, for example.

FIG. 5 illustrates an example where the conductive layer 220 has a three-layer structure of a conductive layer 220a1, a conductive layer 220a2 over the conductive layer 220a1, and the conductive layer 220b over the conductive layer 220a2. In this case, for example, a conductive material that is not easily oxidized or a conductive material that has a function of inhibiting diffusion of oxygen is preferably used for the conductive layer 220a1, a material that has high conductivity is preferably used for the conductive layer 220a2, and a conductive material that contains oxygen (preferably an oxide conductor) is preferably used for the conductive layer 220b. Specifically, titanium nitride is preferably used for the conductive layer 220a1, tungsten is preferably used for the conductive layer 220a2, and an oxide conductor (e.g., ITO, ITSO, or IZO (registered trademark)) is preferably used for the conductive layer 220b. In this case, the titanium nitride is in contact with the insulating layer 210, and the oxide conductor is in contact with the semiconductor layer 230 that is the oxide semiconductor. In addition, the oxide conductor is used for the layer closest to the channel formation region of the semiconductor layer 230. Since the oxide conductor has a lower contact resistance with the semiconductor layer 230 than tungsten, the current path between the source and the drain can be shortened and the amount of the on-state current of the transistor can be increased. Such a structure can maintain conductivity even when the conductive layer 220 is in contact with the semiconductor layer 230. In the case of using an oxide insulating layer as the insulating layer 210, the conductive layer 220 can be inhibited from being excessively oxidized by the insulating layer 210. When a metal material (here, tungsten) having higher conductivity than an oxide conductor and titanium nitride is used for the conductive layer 220a2, the conductivity of the conductive layer 220 can be increased.

FIG. 5 illustrates the example where the conductive layer 240 has a two-layer structure of the conductive layer 240a and the conductive layer 240b over the conductive layer 240a. In this case, for example, a conductive material containing oxygen is preferably used for the conductive layer 240b, and a material having higher conductivity than the material for the conductive layer 240b is preferably used for the conductive layer 240a. Specifically, for example, an oxide conductor (e.g., ITO, ITSO, or IZO (registered trademark)) is preferably used for the conductive layer 240b, and tungsten is preferably used for the conductive layer 240a. For the conductive layer 240a, ruthenium, titanium nitride, tantalum nitride, or the like may be used.

In the conductive layer 240, a layer mainly in contact with the semiconductor layer 230 is the conductive layer 240b. In the case where an oxide semiconductor is used for the semiconductor layer 230, the use of an oxide conductor for the conductive layer 240b is preferable, in which case the contact resistance with the semiconductor layer 230 can be reduced. A material having higher conductivity than an oxide conductor is preferably used for a layer included in the conductive layer 240, in which case the conductivity of the conductive layer 240 can be increased.

Note that a conductive material containing oxygen can be used for the conductive layer 240a, and a material having higher conductivity than that for the conductive layer 240a can be used for the conductive layer 240b. In that case, an oxide conductor is used for the layer that is included in the conductive layer 240 and is closest to the channel formation region of the semiconductor layer 230. Thus, the current path between the source and the drain can be shortened, so that the amount of the on-state current of the transistor can be increased.

The conductive layers 255 and 265 are each preferably formed using a material with high conductivity such as tungsten. For each of the conductive layers 255 and 265, a conductive material that is not easily oxidized, a conductive material having a function of inhibiting diffusion of oxygen, or the like is preferably used. As described above, examples of the conductive material include a conductive material containing nitrogen (e.g., titanium nitride or tantalum nitride) and a conductive material containing oxygen (e.g., ruthenium oxide). Thus, a decrease in conductivity of the conductive layers 255 and 265 can be inhibited.

It is preferable to use, for the conductive layer 265, a conductive material containing oxygen and a metal element contained in the metal oxide where a channel is formed. Alternatively, a conductive material containing the above metal element and nitrogen (e.g., titanium nitride or tantalum nitride) may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With the use of such a material, hydrogen contained in the metal oxide where a channel is formed can be captured in some cases. Alternatively, hydrogen entering from an external insulating layer or the like can be captured in some cases.

FIG. 5 illustrates an example where the conductive layer 265 has a two-layer structure of the conductive layer 265a and the conductive layer 265b over the conductive layer 265a. In this case, for example, it is preferable to use titanium nitride for the conductive layer 265a and tungsten for the conductive layer 265b. Alternatively, it is preferable to use tantalum nitride for the conductive layer 265a and copper for the conductive layer 265b. With such a structure, the conductivity of the conductive layer 265 can be increased.

The conductive layer 265 may have a stacked-layer structure of three or more layers. The conductive layer 265 may have a three-layer structure of tantalum nitride, titanium nitride over the tantalum nitride, and tungsten over the titanium nitride, for example.

The conductive layer 265 functions as the gate wiring and thus preferably has high conductivity. The conductive layer 265 is preferably formed using tungsten. For example, a two-layer structure of titanium nitride and tungsten may be employed.

For the conductive layer 255, tungsten or tantalum nitride is preferably used, for example.

### [Substrate]

In the case where a semiconductor device such as a transistor, a memory cell, or a memory device is provided over a substrate, there is no particular limitation on materials used for the substrate. The material can be determined considering whether it has or does not have light-transmitting properties or it has heat resistance that can withstand heat treatment. For example, an insulator substrate, a semiconductor substrate, or a conductor substrate may be used. As the insulator substrate, a glass substrate of barium borosilicate glass, aluminoborosilicate glass, or the like, a ceramic substrate, a quartz substrate, a sapphire substrate, or a stabilized zirconia substrate (e.g., an yttria-stabilized zirconia substrate) can be used, for example. Alternatively, a semiconductor substrate, a flexible substrate, a resin substrate, or the like may be used.

Examples of the semiconductor substrate include a semiconductor substrate containing a material such as silicon or germanium and a compound semiconductor substrate containing a material such as silicon carbide, silicon germanium, gallium arsenide, indium phosphide, zinc oxide, or gallium oxide. Other examples include a semiconductor substrate in which an insulator region is provided in the above semiconductor substrate such as a silicon on insulator (SOI) substrate. The semiconductor substrate may be a single crystal semiconductor or a polycrystalline semiconductor.

Examples of the conductor substrate include a graphite substrate, a metal substrate, an alloy substrate, and a conductive resin substrate. Alternatively, a substrate including a metal nitride, a substrate including a metal oxide, or the like is given. Other examples include an insulator substrate provided with a conductive layer or a semiconductor layer, a semiconductor substrate provided with a conductive layer or an insulating layer, and a conductor substrate provided with a semiconductor layer or an insulating layer.

For the material of the flexible substrate, the resin substrate, or the like, polyester such as polyethylene terephthalate (PET) or polyethylene naphthalate (PEN), polyacrylonitrile, an acrylic resin, polyimide, polymethyl methacrylate, polycarbonate (PC), polyethersulfone (PES), polyamide (e.g., nylon or aramid), polysiloxane, a cycloolefin resin, polystyrene, polyamide-imide, polyurethane, polyvinyl chloride, polyvinylidene chloride, polypropylene, polytetrafluoroethylene (PTFE), an ABS resin, or cellulose nanofiber can be used, for example.

When any of the above-described materials is used for the substrate, a lightweight semiconductor device can be provided. Furthermore, with the use of any of the materials described above for the substrate, a shock-resistant semiconductor device can be provided. Furthermore, with the use of any of the materials described above for the substrate, a semiconductor device that is less likely to be broken can be provided.

Alternatively, any of these substrates provided with an element may be used. Examples of the element provided over the substrate include a capacitor element, a resistor, a switching element, a light-emitting element, and a memory element.

### <Structure Example of Memory Cell>

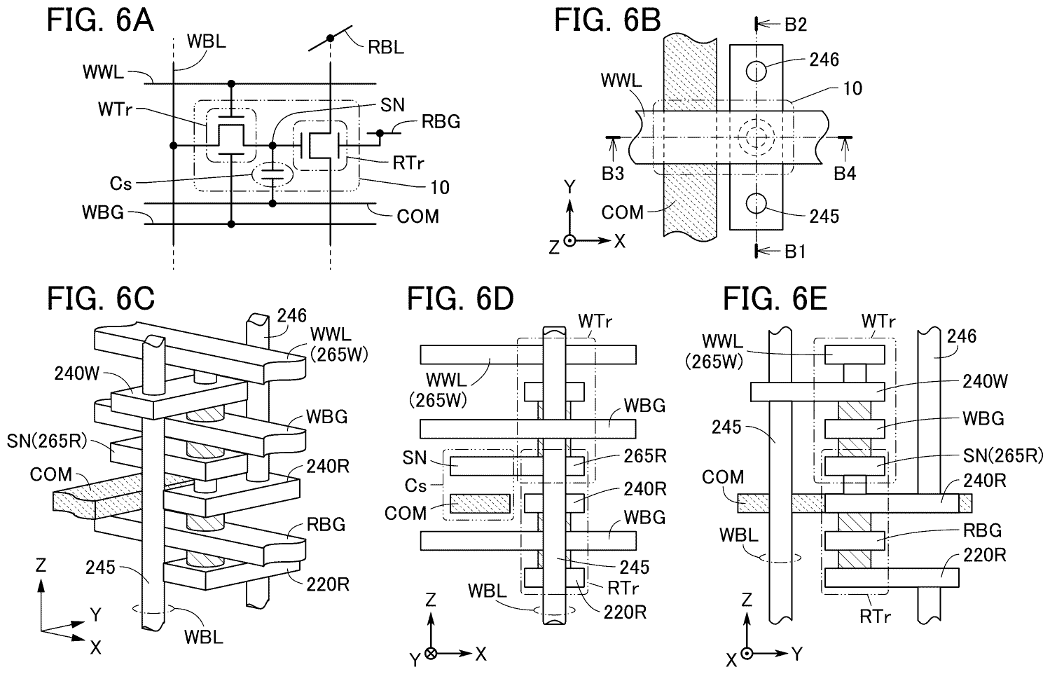

FIG. 6A is a circuit structure example of the memory cell 10 included in the memory string 100. FIG. 6B is a schematic plan view of the memory cell 10 illustrated in FIG. 6A seen from the Z direction. FIG. 6C is a schematic perspective view of the memory cell 10 illustrated in FIG. 6A. FIG. 6D is a schematic view of the memory cell 10 illustrated in FIG. 6A seen in the Y direction. FIG. 6E is a schematic view of the memory cell 10 illustrated in FIG. 6A seen from the X direction. The memory cell 10 illustrated in FIG. 6A is a “2Tr1C” memory cell including two transistors and one capacitor element.

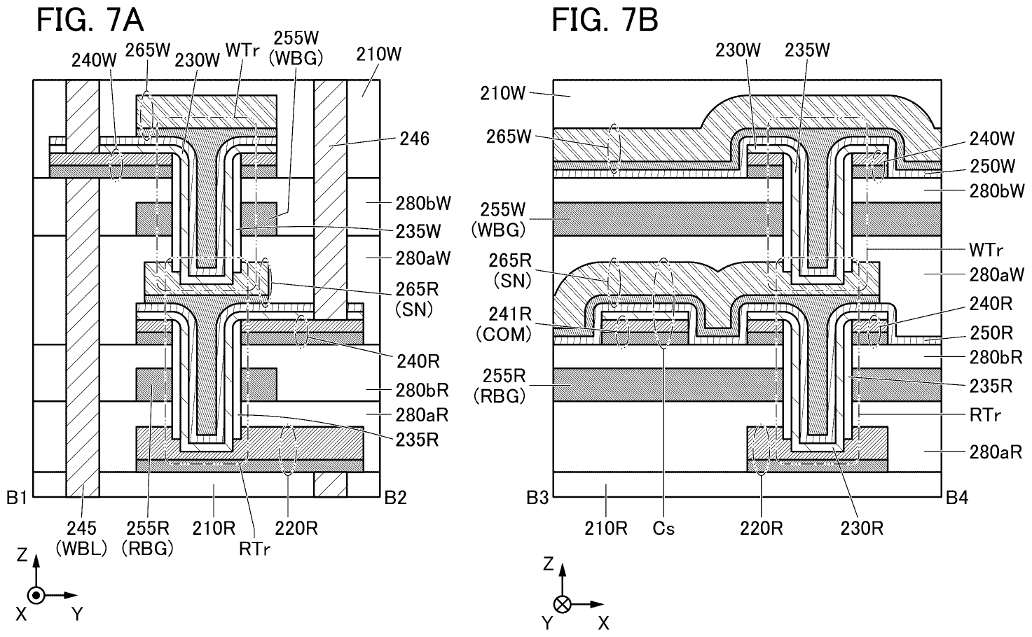

FIG. 7A illustrates a cross-sectional structure example along the dashed-dotted line B1-B2 in FIG. 6B. FIG. 7B illustrates a cross-sectional structure example along the dashed-dotted line B3-B4 in FIG. 4B.

As described above, the transistor 200 can be used as each of the transistor WTr and the transistor RTr that are included in the memory cell 10. The use of the transistor 200, which is a vertical transistor, as the transistor WTr and the transistor RTr can reduce the area occupied by the memory cell 10. Furthermore, when the transistor WTr and the transistor RTr are provided to overlap with each other, the area occupied by the memory cell 10 can be further reduced.

FIGS. 7A and 7B illustrate a structure example of the memory cell 10 in which the transistor 200 is used as each of the transistor WTr and the transistor RTr. In FIGS. 6A to 6E and FIGS. 7A and 7B, “W” and “R” are added to the reference numerals shown in FIGS. 4A to 4E and FIG. 5 to facilitate the comparison with the structure of the transistor 200. Specifically, “W” is added to the reference numerals of the transistor WTr and the portions related to the transistor WTr mainly, and “R” is added to the reference numerals of the transistor RTr and the portions related to the transistor RTr mainly.

The conductive layer 220R functions as one of a source electrode and a drain electrode (a first terminal) of the transistor RTr. The conductive layer 240R functions as the other of the source electrode and the drain electrode (a second terminal) of the transistor RTr. A conductive layer 265R functions as a gate electrode of the transistor RTr, and a conductive layer 255R functions as a back gate electrode of the transistor RTr. The conductive layer 255R functions as the wiring RBG.

A conductive layer 241R is provided over an insulating layer 280bR. The conductive layer 241R has the same structure as the conductive layer 240R. The conductive layer 241R can be formed using the same material in the same step at the same time as the conductive layer 240R. The conductive layer 241R functions as the wiring COM. A region where the conductive layer 241R and the conductive layer 265R overlap with each other with an insulating layer 250R therebetween functions as the capacitor element Cs. The conductive layer 265R functions as the retention node SN. Thus, part of the conductive layer 241R functions as one electrode of the capacitor element Cs, and part of the conductive layer 265R functions as the other electrode of the capacitor element Cs. By providing the capacitor element Cs, the retention node SN is hardly affected by an external electric field, leakage current, and the like, so that data written to the memory cell 10 can be retained stably. Consequently, the memory cell 10 can have higher reliability.

The conductive layer 265R functions as the gate electrode of the transistor RTr and one of a source electrode and a drain electrode (a first terminal) of the transistor WTr. When the conductive layer 265R serves as both the gate electrode of the transistor RTr and one of the source electrode and the drain electrode of the transistor WTr, the number of conductive layers included in the memory cell 10 can be reduced. This can reduce the area occupied by the memory cell 10. In addition, the manufacturing cost of the memory cell 10 can be reduced. Furthermore, the productivity of the memory cell 10 can be improved.

The conductive layer 240W functions as the other of the source electrode and the drain electrode (a second terminal) of the transistor WTr. The conductive layer 265W functions as a gate electrode of the transistor WTr, and a conductive layer 255W functions as the back gate electrode of the transistor WTr. The conductive layer 255W functions as the wiring WBG.

Although the insulating layer 210 is divided into an insulating layer 210R and an insulating layer 210W in FIGS. 7A and 7B, both the layers may be the same layer. For example, the insulating layer 210W provided in the i-th stage and the insulating layer 210R provided in the i+1-th stage may be the same layer.

The conductive layer 240W (the conductive layer 240W[1]) functioning as the second terminal of the transistor WTr[1] included in the memory cell 10[1] in the first stage is connected to the conductive layer 240W (the conductive layer 240W[2]) functioning as the second terminal of the transistor WTr[2] included in the memory cell 10[2] in the second stage through the conductive layer 245.

In FIG. 7A, the conductive layer 245 is provided to penetrate an insulating layer 280bW, an insulating layer 280aW, the insulating layer 280bR, an insulating layer 280aR, the insulating layer 210R (the insulating layer 210W), an insulating layer 250W, and a semiconductor layer 230W in the Z direction. The conductive layer 240W provided in the i-th stage and the conductive layer 240W provided in the i−1-th stage are connected to each other through the conductive layer 245 provided in the i-th stage. Although the conductive layer 245 is illustrated as one conductive layer in this embodiment, the conductive layer 245 may be formed of a plurality of conductive layers.

In FIG. 7A, the conductive layer 246 is provided to penetrate the insulating layer 210W (the insulating layer 210R), the insulating layer 280bW, the insulating layer 280aW, the insulating layer 250R, and the semiconductor layer 230R in the Z direction. The conductive layer 240R provided in the i-th stage and the conductive layer 240R provided in the i+1-th stage are connected to each other through the conductive layer 246 provided in the i-th stage. Although the conductive layer 246 is illustrated as one conductive layer in this embodiment, the conductive layer 246 may be formed of a plurality of conductive layers.

The amount of the off-state current of the transistor WTr is preferably as small as possible so that data written to the retention node SN is retained for a long time. When the channel length of the transistor WTr is increased, the amount of the off-state current of the transistor WTr can be reduced. In order to increase the speed of reading data written to the retention node SN, the amount of the on-state current of the transistor RTr is preferably as large as possible. When the channel length of the transistor RTr is shortened, the amount of the on-state current of the transistor RTr can be increased. Thus, it is preferable that the channel length of the transistor WTr be long and the channel length of the transistor RTr be short. In other words, the channel length of the transistor WTr is preferably longer than the channel length of the transistor RTr. For the same reason, the channel width of the transistor WTr is preferably shorter than the channel width of the transistor RTr.

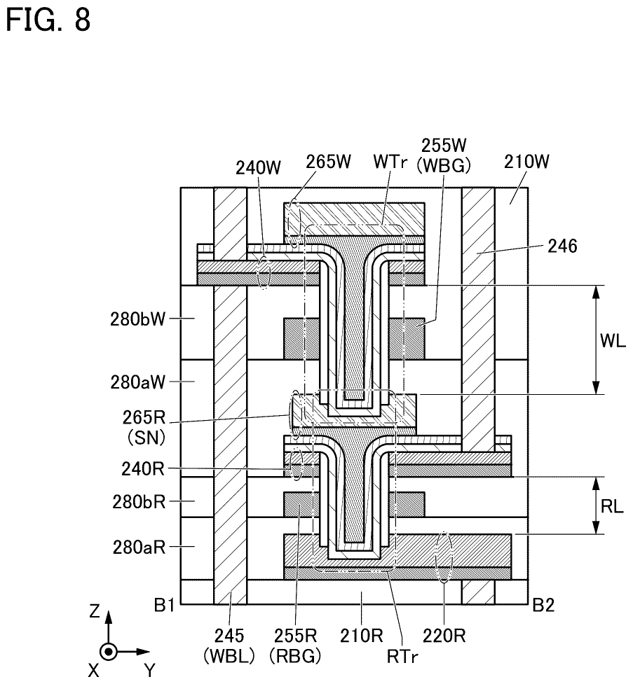

FIG. 8 is a cross-sectional view corresponding to FIG. 7A. In FIG. 8, the channel length of the transistor WTr is denoted as a channel length WL, and the channel length of the transistor RTr is denoted as a channel length RL. In the case where the transistor 200 which is a vertical transistor is used as each of the transistor WTr and the transistor RTr, the length of the channel length WL can be controlled by the thicknesses of the insulating layer 280aW, the insulating layer 280bW, and the conductive layer 255W. The length of the channel length RL can be controlled by the thicknesses of the insulating layer 280aR, the insulating layer 280bR, and the conductive layer 255R. Thus, the total thickness of the insulating layer 280aW, the conductive layer 255W, and the insulating layer 280bW in a region where the conductive layer 240W and the conductive layer 265R overlap with each other when seen from the Z direction is preferably larger than the total thickness of the insulating layer 280aR, the conductive layer 255R, and the insulating layer 280bR in a region where the conductive layer 240R and the conductive layer 220R overlap with each other when seen from the Z direction.

The conductive layers 245 provided in the first to n-th stages and the conductive layers 240W provided in the first to n-th stages function as part of the wiring WBL. Thus, the wiring WBL extends along the Z direction. The wiring WWL, the wiring WBG, and the wiring RBG extend in the X direction.

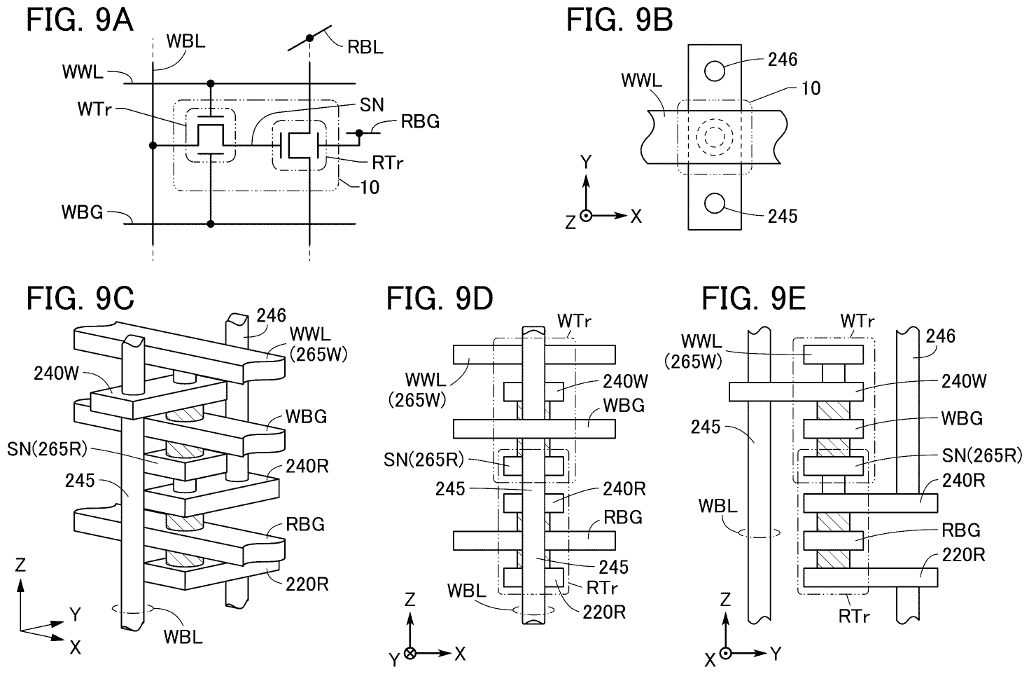

As described above, when the OS transistor is used as the transistor WTr, the data written to the retention node SN can be retained for a long period. Thus, as in a circuit structure example illustrated in FIG. 9A, the capacitor element Cs is not necessarily included. FIG. 9B is a schematic plan view of the memory cell 10 illustrated in FIG. 9A seen from the Z direction. FIG. 9C is a schematic perspective view of the memory cell 10 illustrated in FIG. 9A. FIG. 9D is a schematic view in which the memory cell 10 illustrated in FIG. 9A is seen in the Y direction. FIG. 9E is a schematic view of the memory cell 10 illustrated in FIG. 9A seen from the X direction.

When the capacitor element Cs is not included, the capacitance of the retention node SN is reduced, so that data writing time can be shortened. That is, the writing speed can be increased. Furthermore, formation of the wiring COM is unnecessary when the capacitor element Cs is not included. In addition, the size of the conductive layer 265R seen from the Z direction can be reduced. This can reduce the area occupied by the memory cell 10. Thus, a memory device with high memory density can be provided.

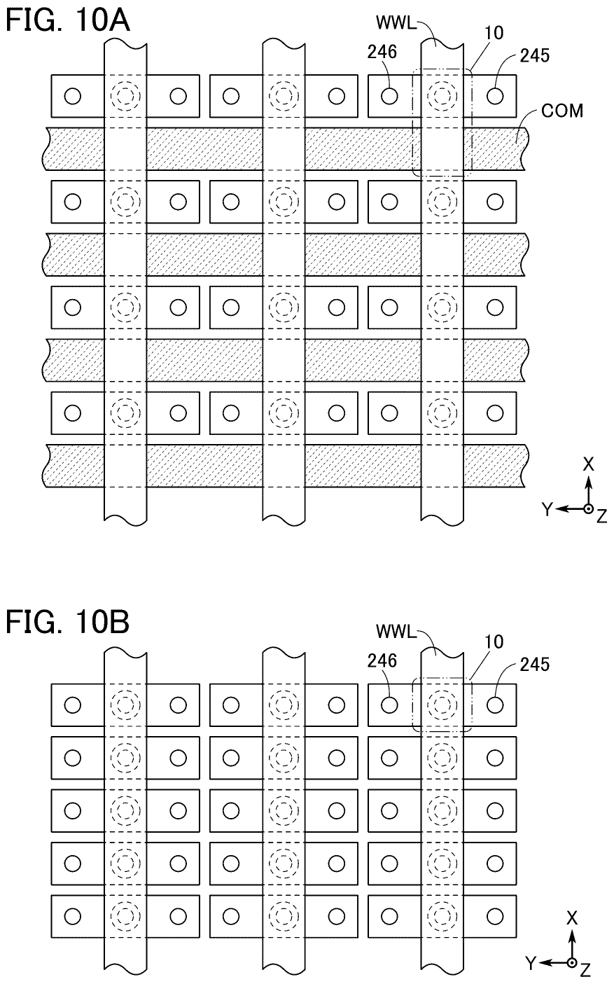

FIGS. 10A and 10B are plan views of the plurality of memory cells 10 of the i-th stage arranged in a matrix. FIG. 10A is a plan view of the case where the memory cell 10 includes the capacitor element Cs. FIG. 10B is a plan view of the case where the memory cell 10 does not include the capacitor element Cs. In the case where the memory cell 10 does not include the capacitor element Cs, the wiring COM is unnecessary; thus, the memory density can be higher than that in the case where the memory cell 10 includes the capacitor element Cs.

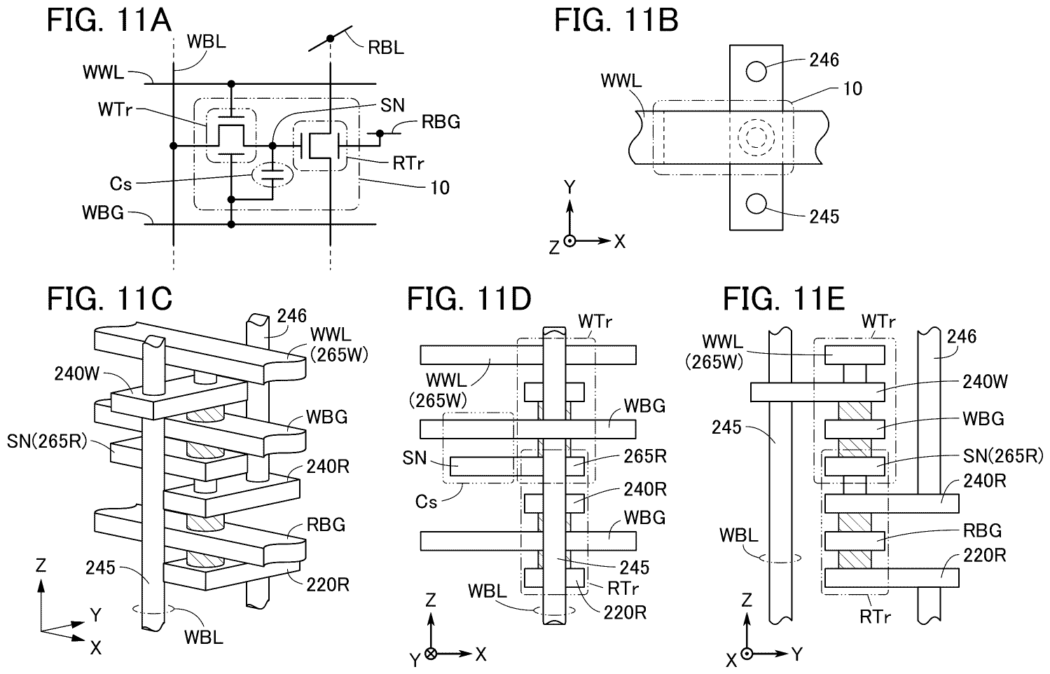

In the case where the potential of the wiring WBG is a fixed potential, the other electrode of the capacitor element Cs can be connected to the wiring WBG as in a circuit structure example illustrated in FIG. 11A. Alternatively, part of the wiring WBG can be used as the other electrode of the capacitor element Cs. FIG. 11B is a schematic plan view of the memory cell 10 illustrated in FIG. 11A seen from the Z direction. FIG. 11C is a schematic perspective view of the memory cell 10 illustrated in FIG. 11A. FIG. 11D is a schematic view in which the memory cell 10 illustrated in FIG. 11A is seen in the Y direction. FIG. 11E is a schematic view of the memory cell 10 illustrated in FIG. 11A seen from the X direction. A region where the wiring WBG and the conductive layer 265R overlap with each other with an insulating layer therebetween functions as the capacitor element Cs.

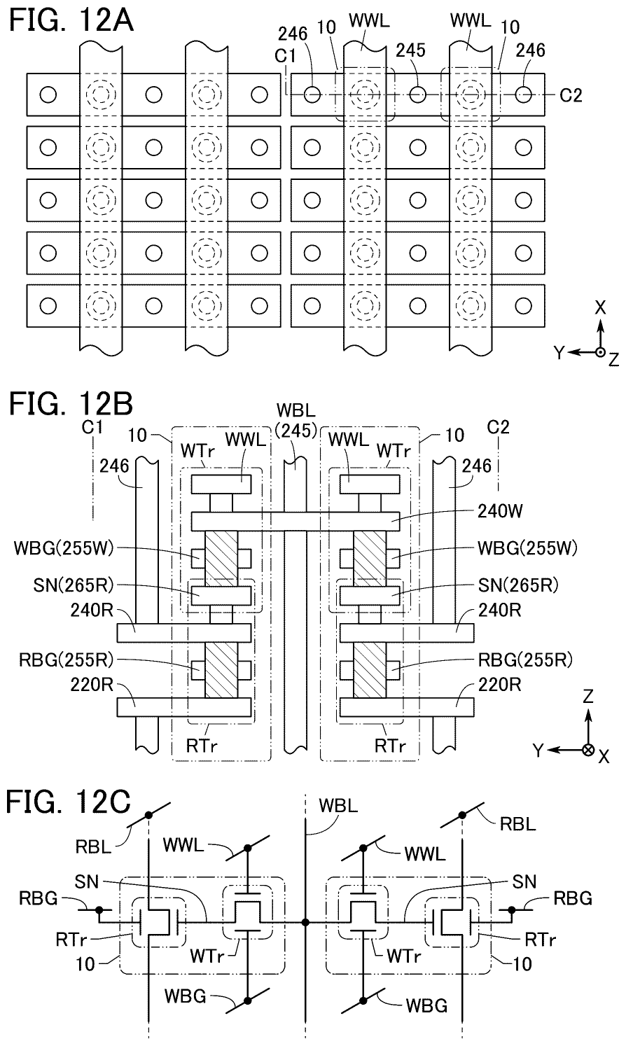

FIG. 12A is a plan view of the plurality of memory cells 10 in the i-th stage arranged in a matrix. FIG. 12B is a cross-sectional view taken along the dashed-dotted line C1-C2 in FIG. 12A. FIG. 12C is an equivalent circuit diagram of FIG. 12B. In the memory cell 10 of one embodiment of the present invention, one wiring WBL can be shared by two adjacent memory cells 10. That is, one wiring WBL can be shared by two adjacent memory strings 100. When one wiring WBL is used in two memory strings 100, the number of wirings WBL to be used can be reduced by half. Thus, the area occupied by the memory device is further reduced, so that a memory device with a higher memory density can be provided.

When an OS transistor is used as the transistor WTr, the memory cell 10 can be a 2Tr1C OS memory. Alternatively, when OS transistors are used as the transistor WTr and the transistor RTr, the memory cell 10 can be a 2Tr1C OS memory.

The memory cell 10 which is an OS memory can retain written data for a period of one year or longer, or even 10 years or longer after electric power supply is stopped. Thus, the memory cell 10 can be regarded as a nonvolatile memory.

In the OS memory, the amount of written charge is less likely to change over a long period of time; hence, the OS memory can retain multilevel (multibit) data as well as binary (1-bit) data.

In the memory cell 10 which is an OS memory, charge is written to a retention node through the OS transistor; hence, a high voltage, which a conventional flash memory requires, is unnecessary and high-speed write operation is possible. The OS memory does not require an erasing operation that is performed in flash memories before data rewriting. Furthermore, the OS memory does not perform charge injection and extraction to and from a floating gate or a charge-trap layer, allowing a substantially no limitation on the number of times of data writing and reading. The OS memory is less likely to degrade than a conventional flash memory and can have high reliability.

Unlike a ferroelectric random access memory (FeRAM), a resistive random access memory (ReRAM), or the like, the structure of the memory cell 10 does not change at the atomic level. Thus, the memory cell 10 has higher write endurance than the ferroelectric memory and the resistive random access memory.

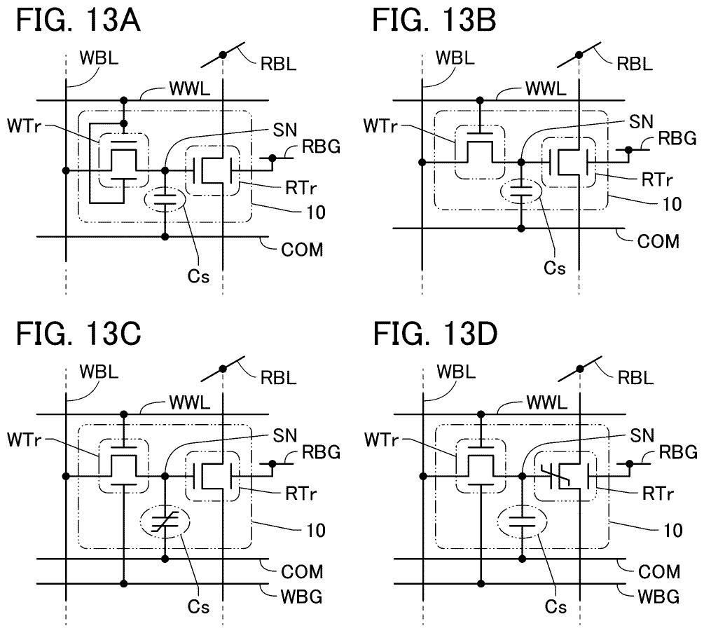

As illustrated in the circuit diagram in FIG. 13A, the gate and the back gate of the transistor WTr may be connected to each other. In this case, the wiring WBG can be omitted. In the case where Vth of the transistor WTr is large in the positive direction, a transistor without a back gate can be used as the transistor WTr as illustrated in the circuit diagram in FIG. 13B. Also in this case, the wiring WBG can be omitted. As illustrated in the circuit diagram in FIG. 13C, a ferroelectric capacitor element in which a ferroelectric material is used as a dielectric may be used as the capacitor element Cs. As illustrated in the circuit diagram in FIG. 13D, a ferroelectric transistor using a ferroelectric material (ferroelectric FET:FeFET) for a gate insulating layer may be used as the transistor RTr.

This embodiment can be implemented in an appropriate combination with any of the structures described in the other embodiments and the like.

### Embodiment 2

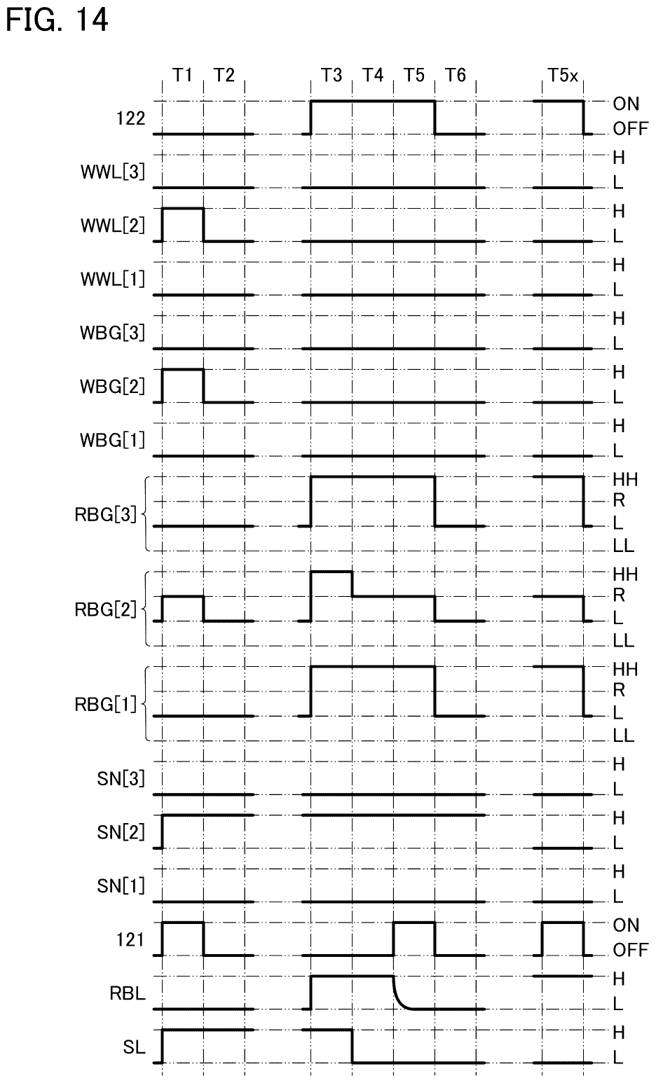

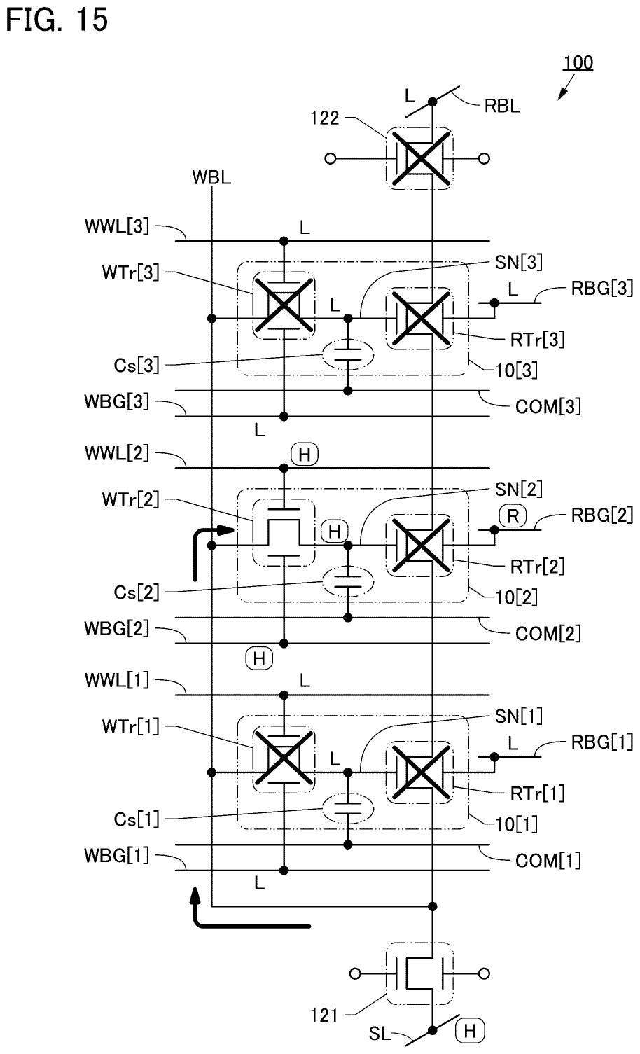

An operation example of the memory string 100 of one embodiment of the present invention will be described. In this embodiment, an operation example of the memory string 100 in the case where n is 3 is described. FIG. 14 is a timing chart illustrating an operation of the memory string 100. FIGS. 15 to 21 are circuit diagrams illustrating the operation of the memory string 100.

### <Writing Operation>

In this embodiment, an operation example in which the potential H out of the potential H and the potential L is written to the memory cell 10[2] is described. Specifically, an operation example in which charge with a charge amount corresponding to the potential H is written to the retention node SN[2] is described. When the potential H corresponds to a logic value “1” and the potential L corresponds to a logic value “0”, one memory cell 10 can store 1-bit data. In the case where one memory string 100 includes n stages of memory cells 10, data of n bits at maximum can be stored in one memory string 100.

It is assumed that in the initial state, the potential L is written to the memory cell 10[1] and the memory cell 10[3]. In addition, the transistor 121 and the transistor 122 are turned off, and the potential L is supplied to the wiring WWL[1] to the wiring WWL[3], the wiring WBG[1] to the wiring WBG[3], the retention node SN[1] to the retention node SN[3], the wiring RBL, and the wiring SL.

The potential L is supplied to the wiring RBG[1] to the wiring RBG[3]. Note that in the case where the potential H is supplied to the gate of the n-type transistor and the potential L is supplied to the back gate, the potential on the gate side and the potential on the back gate side are canceled out and 0 V is applied to the semiconductor layer. Thus, the n-type transistor is turned off.

Note that a potential LL may be supplied to the gate or the back gate to surely turn off the n-type transistor. The potential LL is lower than the potential L. For example, in the case where the Vth variation of the transistor is large, the transistor cannot be brought into an off state even when the potential L is supplied to the back gate in some cases. At that time, for example, by supplying the potential LL to the back gate of the n-type transistor, the n-type transistor can be surely turned off even when the potential H is supplied to the gate of the n-type transistor.

As described above, in this embodiment, in the case where the potential L or the potential LL is supplied to the wiring RBG[1] to the wiring RBG[3], the transistor RTr[1] to the transistor RTr[3] are turned off regardless of the potentials of the retention node SN[1] to the retention node SN[3].

### [Period T1]

In Period T1, the potential H is supplied to the wiring WWL[2] and the wiring WBG[2]. Moreover, a potential R is supplied to the wiring RBG[2]. The potential R is between the potential H and the potential L. In this embodiment, the potential R is 0 V. In addition, the potential H is supplied to the wiring SL. Also, the transistor 121 is turned on. Then, the potential of the retention node SN[2] becomes the potential H (see FIGS. 14 and 15).

Data written to the memory cell 10 is supplied from the wiring SL to the memory cell 10 through a source and a drain of the transistor 121. Furthermore, when the potential H is supplied to both the wiring WWL[2] and the wiring WBG[2], the amount of the on-state current of the transistor WTr[2] can be increased and the data writing speed can be increased as compared with the case where the potential H is supplied to only the wiring WWL[2].

### [Period T2]

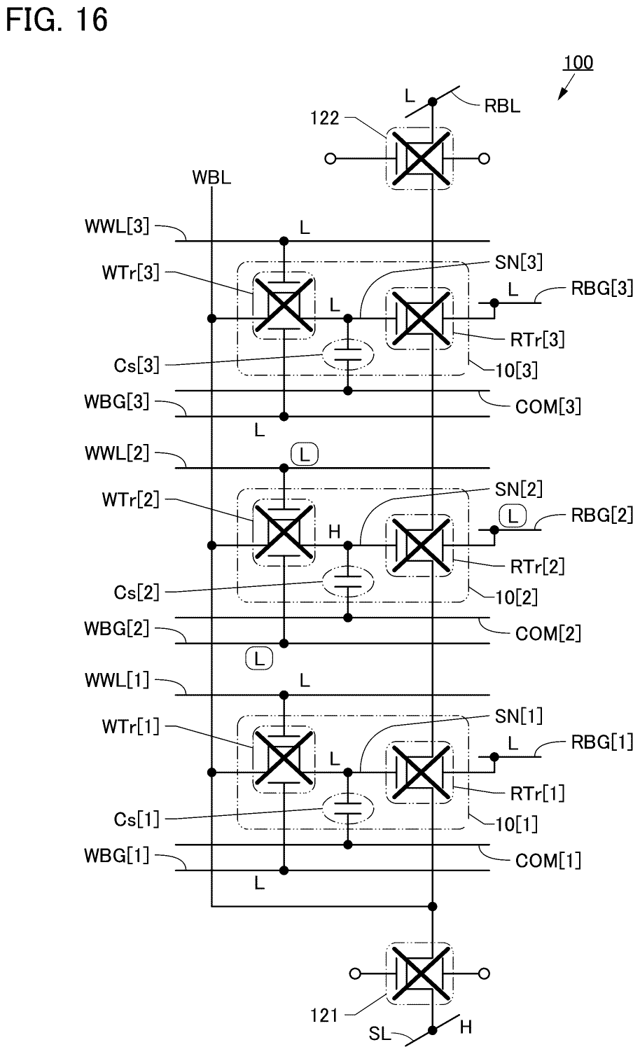

In Period T2, the potential L is supplied to the wiring WWL[2] and the wiring WBG[2]. Then, the transistor WTr[2] is turned off and charge written to the retention node SN[2] is retained. Here, charge with a charge amount corresponding to the potential H is retained (see FIGS. 14 and 16). Furthermore, the potential of the wiring RBG[2] is set to the potential L.

In this manner, data can be stored in the memory cell 10[2]. Data written to the memory cell 10 is supplied from the wiring SL to the memory cell 10 through the source and the drain of the transistor 121. In the case where data is written to the memory cell 10[1], the potential L is supplied to the wiring WWL[2], the wiring WBG[2], the wiring WWL[3], and the wiring WBG[3], and the potential H is supplied to the wiring WWL[1] and the wiring WBG[1]. Similarly, in the case where data is written to the memory cell 10[3], the potential L is supplied to the wiring WWL[1], the wiring WBG[1], the wiring WWL[2], and the wiring WBG[2], and the potential H is supplied to the wiring WWL[3] and the wiring WBG[3].

### <Reading Operation>

An operation example of reading data stored in the memory cell 10[2] will be described. It is assumed that in the initial state, the potential L is retained in the memory cell 10[1] and the memory cell 10[3]. In addition, it is assumed that the transistor 121 and the transistor 122 are turned off, and the potential L is supplied to the wiring WWL[1] to the wiring WWL[3], the wiring WBG[1] to the wiring WBG[3], the retention node SN[1], the retention node SN[3], the wiring RBL, and the wiring SL. Furthermore, it is assumed that the potential L is supplied to the wiring RBG[1] to the wiring RBG[3].

<<Case where Potential H is Retained>>

First, a reading operation in the case where the potential H is retained in the memory cell 10[2] is described.

### [Period T3]

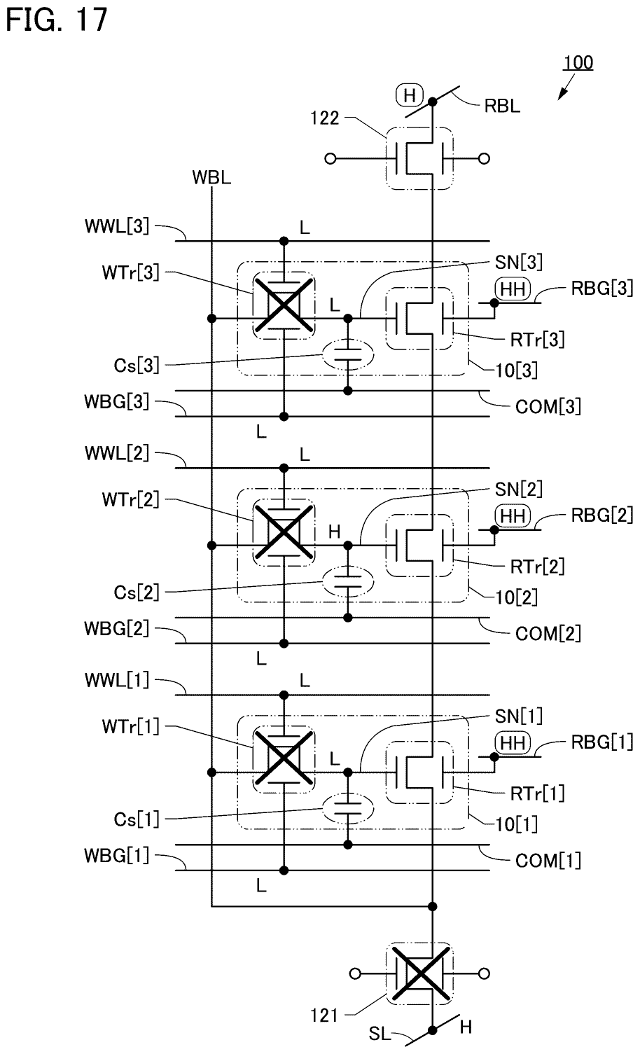

In Period T3, the transistor 122 is turned on, and the potential HH is supplied to the wiring RBG[1] to the wiring RBG[3]. The potential HH is higher than the potential H. When the potential HH is supplied to a back gate of the n-type transistor, the transistor can be surely brought into an on state even when the potential L is supplied to the gate of the transistor. Thus, the transistor RTr[1] to the transistor RTr[3] are turned on regardless of the potentials of the retention node SN[1] to the retention node SN[3] (see FIGS. 14 and 17). The wiring RBL is precharged to the potential H. That is, the wiring RBL is set to the potential H and then is brought into a floating state.

### [Period T4]

In Period T4, the potential R that is a reading potential is supplied to the wiring RBG connected to the memory cell 10 that is to be read. The potential R is between the potential H and the potential L. In this embodiment, the potential R is set to 0 V. Thus, 0 V is supplied as the potential R to the wiring RBG[2].

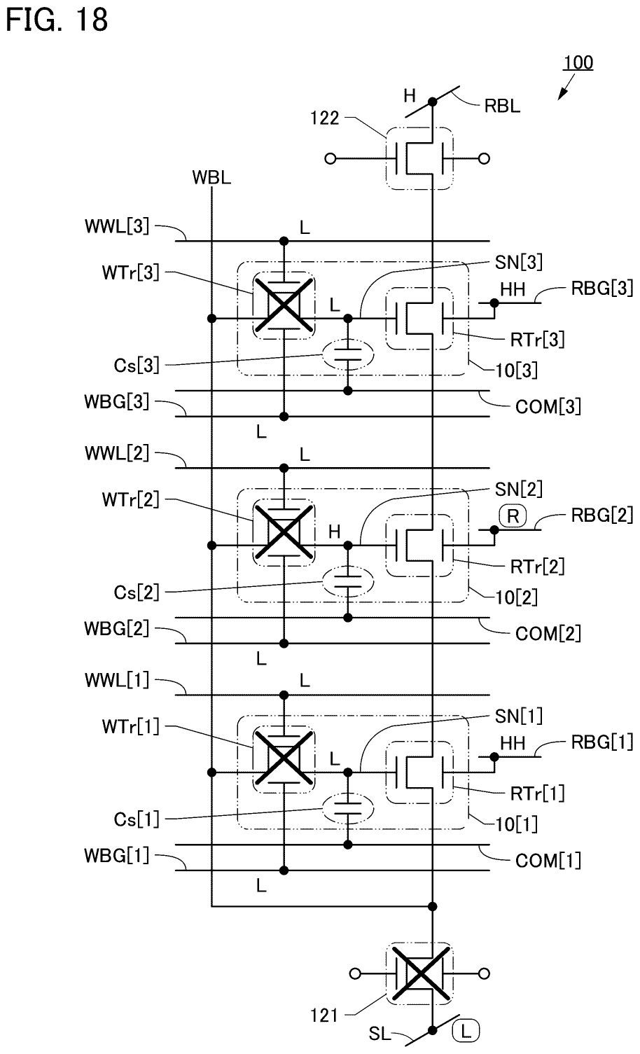

Since the potential of the retention node SN[2] is the potential H and the potential of the wiring RBG[2] is the potential R, the transistor RTr[2] is turned on (see FIGS. 14 and 18). In addition, the potential L is supplied to the wiring SL.

### [Period T5]

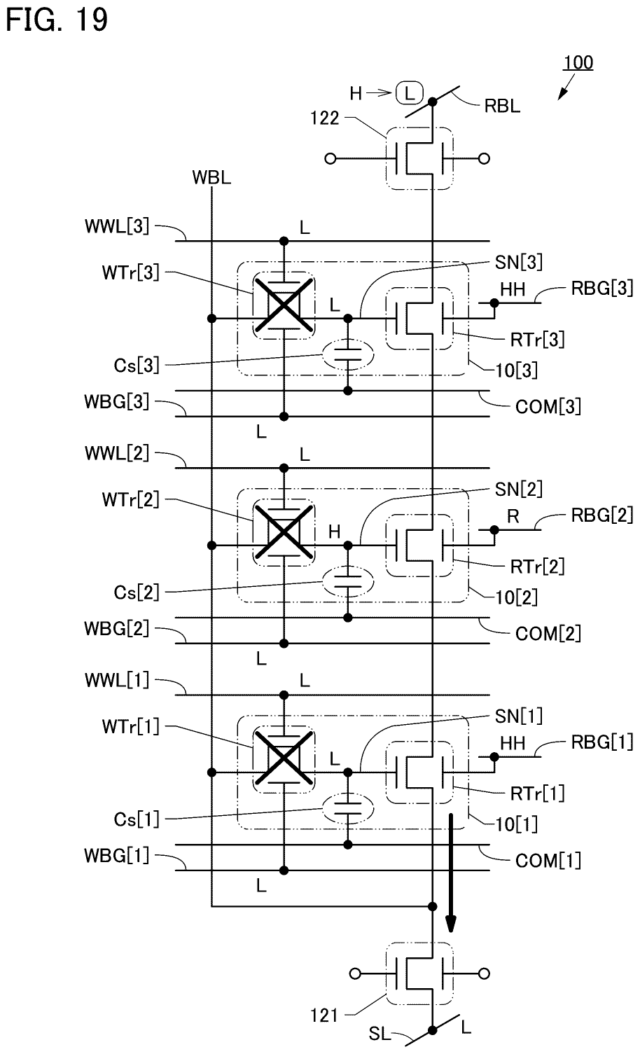

In Period T5, the transistor 121 is turned on. At this time, since the transistor RTr[1] to the transistor RTr[3] and the transistor 122 are turned on, the wiring RBL and the wiring SL are connected through these transistors. Then, the potential of the wiring RBL precharged to the potential H becomes the potential L (see FIGS. 14 and 19).

In Period T5, the potential of the wiring RBL becomes the potential L, which indicates that the potential H is retained in the memory cell 10[2].

### [Period T6]

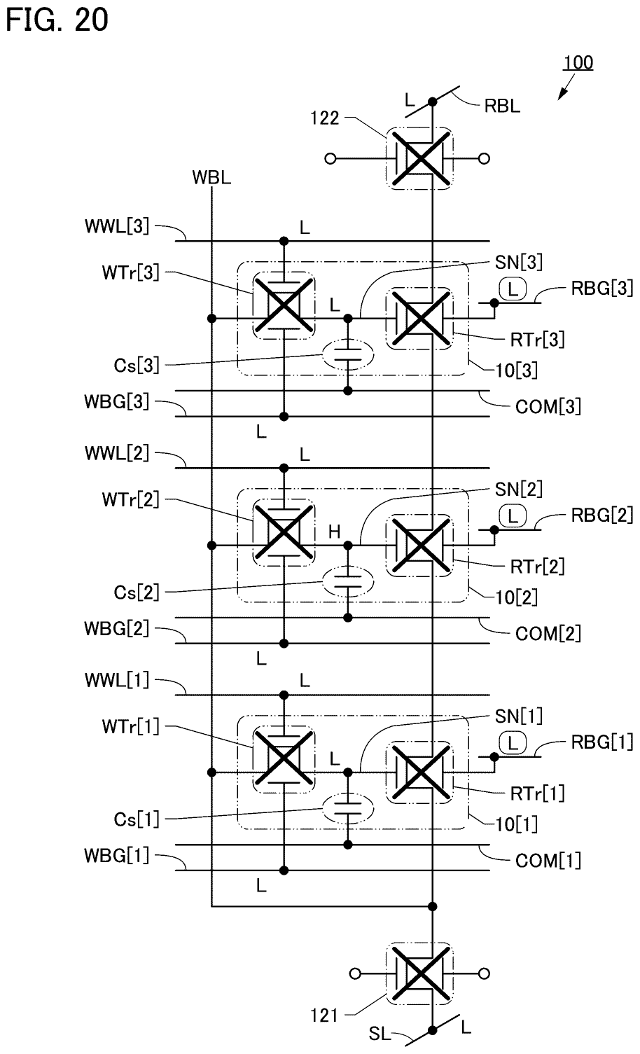

In Period T6, the potentials of the transistor 121, the transistor 122, and the wiring RBG[1] to the wiring RBG[3] are the potential L (see FIGS. 14 and 20). Note that in the reading operation, data written to the retention node SN is retained without being erased. Thus, the memory cell 10 is a memory element capable of non-destructive reading.

<<Case where Potential L is Retained>>

Next, a reading operation in the case where the potential L is retained in the memory cell 10[2] is described. In the case where the potential L is retained in the memory cell 10[2], the potential change in Period T5 is different. In Period T4, even when the potential of the wiring RBG[2] is the potential R, the transistor RTr[2] remains in the off state because the potential of the retention node SN[2] is the potential L.

### [Period T5x]

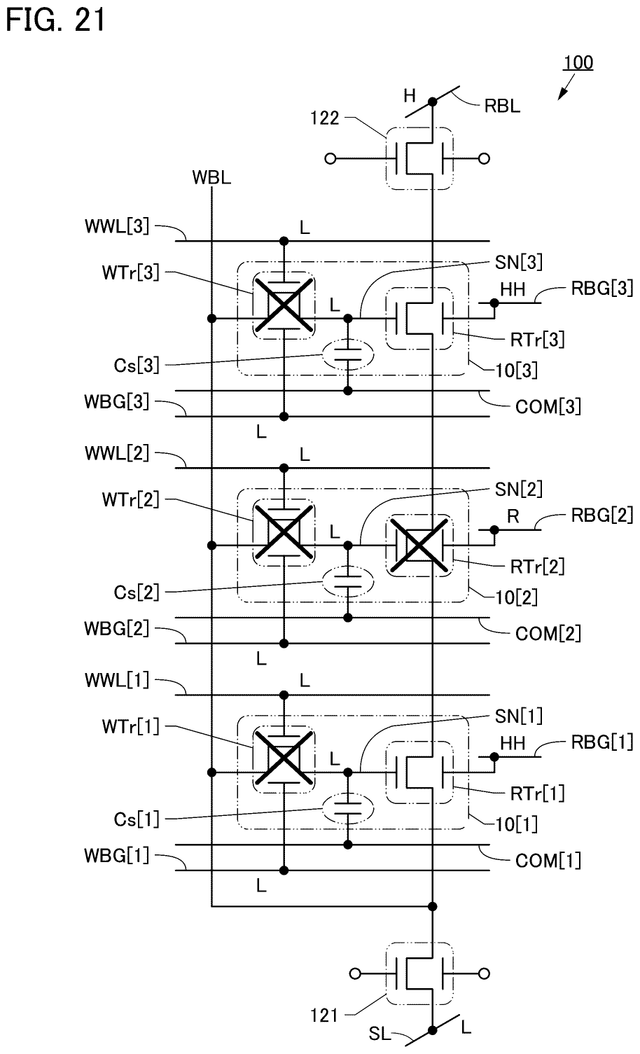

In Period T5x, the transistor 121 is turned on. At this time, the transistor RTr[1], the transistor RTr[3], and the transistor 122 are turned on; however, since the transistor RTr[2] is turned off, the wiring RBL and the wiring SL are not connected to each other. Thus, the potential of the wiring RBL precharged to the potential H remains at the potential H (see FIGS. 14 and 21).

When the potential of the wiring RBL remains at the potential H in Period T5x, it is found that the potential L is retained in the memory cell 10[2].

In this manner, data can be written to and read from the memory cell 10.

This embodiment can be implemented in an appropriate combination with any of the structures described in the other embodiments and the like.

### Embodiment 3

In this embodiment, an oxide semiconductor layer that can be used as the semiconductor layer of the transistor will be described.

### [Oxide Semiconductor Layer]

It is preferable that the oxide semiconductor layer of one embodiment of the present invention contain a metal oxide having crystallinity. Examples of the structure of a metal oxide having crystallinity include a c-axis aligned crystalline (CAAC) structure, a polycrystalline structure, and a nano-crystal (nc) structure. By using a metal oxide having crystallinity for the oxide semiconductor layer, the density of defect states in the oxide semiconductor layer can be reduced. Thus, the reliability of a transistor including the oxide semiconductor layer of one embodiment of the present invention can be increased, and the reliability of a memory device including the transistor can be increased.

It is particularly preferable that the oxide semiconductor layer of one embodiment of the present invention include a metal oxide having a CAAC structure. The CAAC structure is a crystal structure in which a plurality of microcrystals (typically, a plurality of microcrystals each having a hexagonal crystal structure) have c-axis alignment and are connected on the a-b plane without alignment. When a cross section of an oxide semiconductor layer having a CAAC structure is observed using a high-resolution transmission electron microscope (TEM) image, it can confirmed that metal atoms are arranged in a layered manner in a crystal part. Thus, the oxide semiconductor layer having a CAAC structure can also be referred to as a structure including the layered crystal parts.

The crystallinity of the oxide semiconductor layer can be analyzed by X-ray diffraction (XRD), TEM, or electron diffraction (ED), for example. Alternatively, any of these methods may be combined with each other for the analysis.

Note that there is no particular limitation on the crystallinity of a semiconductor material included in the oxide semiconductor layer. For example, the oxide semiconductor layer includes one or more of an amorphous semiconductor (a semiconductor having an amorphous structure), a single crystal semiconductor (a semiconductor having a single crystal structure), and a semiconductor having other crystallinity than single crystal (a microcrystalline semiconductor, a polycrystalline semiconductor, or a semiconductor partly including crystal regions) in some cases. The oxide semiconductor layer having crystallinity can inhibit deterioration of the transistor characteristics in some cases.

Examples of the metal oxide included in the oxide semiconductor layer of one embodiment of the present invention include indium oxide, gallium oxide, and zinc oxide. The metal oxide of one embodiment of the present invention preferably contains at least indium (In) or zinc (Zn). The metal oxide preferably contains two or three selected from indium, an element M, and zinc. The element M is a metal element or metalloid element that has a high bonding energy with oxygen, such as a metal element or metalloid element whose bonding energy with oxygen is higher than that of In. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M included in the metal oxide is preferably one or more of the above elements, further preferably one or more selected from aluminum, gallium, tin, and yttrium, and still further preferably gallium. When the element M included in the metal oxide is gallium, the metal oxide of one embodiment of the present invention preferably includes one or more selected from indium, gallium, and zinc. In this specification and the like, a metal element and a metalloid element may be collectively referred to as a “metal element”, and a “metal element” in this specification and the like may refer to a metalloid element.

As the metal oxide of one embodiment of the present invention, for example, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (also referred to as In—Ga—Sn oxide or IGTO), gallium zinc oxide (also referred to as Ga—Zn oxide or GZO), aluminum zinc oxide (also referred to as Al—Zn oxide or AZO), indium aluminum zinc oxide (also referred to as In—Al—Zn oxide or IAZO), indium tin zinc oxide (In—Sn—Zn oxide), indium titanium zinc oxide (In—Ti—Zn oxide), indium gallium zinc oxide (also referred to as In—Ga—Zn oxide or IGZO), indium gallium tin zinc oxide (also referred to as In—Ga—Sn—Zn oxide or IGZTO), or indium gallium aluminum zinc oxide (also referred to as In—Ga—Al—Zn oxide, IGAZO, or IAGZO) can be used. Alternatively, indium tin oxide containing silicon, gallium tin oxide (Ga—Sn oxide), aluminum tin oxide (Al—Sn oxide), or the like can be used.

By increasing the proportion of the number of indium atoms in the total number of atoms of all the metal elements included in the metal oxide, a high on-state current and high frequency characteristics of the transistor can be achieved.

Instead of indium, the metal oxide may contain one or more kinds of metal elements whose period number in the periodic table is large. Alternatively, in addition to indium, the metal oxide may contain one or more kinds of metal elements whose period number in the periodic table is large. The larger the overlap between orbits of metal elements is, the more likely it is that the metal oxide will have high carrier conductivity. Thus, when a metal element with a large period number in the periodic table is contained in the metal oxide, the field-effect mobility of the transistor can be increased in some cases. Examples of the metal element with a large period number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds selected from nonmetallic elements. A transistor including the metal oxide including a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor is suppressed and the transistor can have high reliability.

By increasing the proportion of the element M atoms in the total number of atoms of all the metal elements contained in the metal oxide, oxygen vacancies can be prevented from being formed in the metal oxide. Accordingly, generation of carriers due to oxygen vacancies is inhibited, which makes the off-state current of the transistor low. Furthermore, changes in the electrical characteristics of the transistor can be reduced to improve the reliability of the transistor.

In the description of this embodiment, In—Ga—Zn oxide is sometimes taken as an example of the metal oxide.

The oxide semiconductor layer of one embodiment of the present invention has crystallinity. The oxide semiconductor layer of one embodiment of the present invention preferably has a CAAC structure.

The oxide semiconductor layer of one embodiment of the present invention can be formed by forming a metal oxide by at least two kinds of deposition methods. For example, the oxide semiconductor layer of one embodiment of the present invention can be formed by forming a metal oxide using a first deposition method and a second deposition method. Note that the oxide semiconductor layer formed by using at least two kinds of deposition methods may be referred to as a hybrid OS.

The oxide semiconductor layer of one embodiment of the present invention can be formed in the following manner: a metal oxide is formed as a first layer by a first deposition method, and then a metal oxide is formed as a second layer over the first layer by a second deposition method. In that case, as the first deposition method, a deposition method that causes less damage to the formation surface than the second deposition method is preferably used. When a deposition method that causes less damage to the formation surface is used as the first deposition method, formation of a mixed layer at an interface between the oxide semiconductor layer and a layer that is the formation surface of the oxide semiconductor layer can be inhibited. Moreover, entry of impurities such as silicon into the second layer can be inhibited, so that the crystallinity of the oxide semiconductor layer can be increased.

Examples of the first deposition method include an atomic layer deposition (ALD) method, a chemical vapor deposition (CVD) method, a molecular beam epitaxy (MBE) method, and a wet process. Examples of the CVD method include a plasma enhanced CVD (PECVD) method, a thermal CVD method, a photo CVD method, and a metal organic CVD (MOCVD) method. Examples of the wet process include a spray coating method. An ALD method and a CVD method are suitable as the first deposition method because damage to the formation surface can be inhibited as compared with a sputtering method described later.

Examples of the ALD method include a thermal ALD method, in which a precursor and a reactant react with each other only by a thermal energy, and a plasma-enhanced ALD (PEALD) method, in which a reactant excited by plasma is used.

An ALD method enables one atomic layer to be deposited at a time, and has various advantages such as deposition of an extremely thin film, deposition on a component with a high aspect ratio or a surface with a large step, deposition of a film with few defects such as pinholes, deposition with excellent coverage, and low-temperature deposition. A PEALD method utilizing plasma is preferable, because deposition at lower temperature is possible in some cases. Note that some precursors used in the ALD method contain an element such as carbon or chlorine. Thus, a film deposited by the ALD method sometimes contains an element such as carbon or chlorine in a larger quantity than a film deposited by another deposition method. Note that these elements can be quantified by X-ray photoelectron spectroscopy (XPS) or secondary ion mass spectrometry (SIMS). The deposition method of the metal oxide of one embodiment of the present invention, which employs an ALD method and one or both of a deposition condition with a high substrate temperature and impurity removal treatment, might form a film with smaller amounts of carbon and chlorine than a method employing an ALD method and neither the condition nor the treatment.

Unlike a deposition method in which particles ejected from a target or the like are deposited, in an ALD method, a film is formed by reaction at a surface of an object to be processed. Thus, a CVD method and an ALD method can provide good step coverage, almost regardless of the shape of an object to be processed. In particular, an ALD method allows excellent step coverage and excellent thickness uniformity and can be suitably used to cover a surface of an opening portion with a high aspect ratio, for example.

A high-quality film can be obtained at a relatively low temperature through a plasma CVD method. A thermal CVD method does not use plasma and thus causes less plasma damage to an object to be processed. A thermal CVD method yields a film with few defects because of no plasma damage during deposition.

Examples of the second deposition method include a sputtering method and a pulsed laser deposition (PLD) method. The metal oxide formed by the second deposition method is likely to have a CAAC structure.

Note that as the first layer, a metal oxide having a microcrystalline structure or an amorphous structure that has lower crystallinity than a CAAC structure is formed in some cases, for example. Formation of the second layer having high crystallinity over the first layer having low crystallinity or the formation of the first and second layers followed by heat treatment can increase the crystallinity of the first layer using the second layer as a nucleus. Accordingly, the crystallinity can be increased in the whole oxide semiconductor layer including the vicinity of the interface with the formation surface.

Furthermore, a third layer can be formed over the second layer. Since the second layer has high crystallinity, the crystal growth of the third layer can be achieved with the use of the crystal of the second layer as a nucleus or a species. Thus, the third layer can be crystallized even when a deposition method that easily has crystallinity is not used as the deposition method of the third layer. Here, when the third layer is formed by a deposition method that provides higher coverage than the second layer, the whole oxide semiconductor layer can have both high crystallinity and high coverage, for example.

For example, the oxide semiconductor layer of one embodiment of the present invention can be formed in the following manner: a metal oxide is formed as a first layer by a first deposition method, a metal oxide is formed as a second layer by a second deposition method, and a metal oxide is formed as a third layer by a first deposition method. Specifically, an ALD method can be used as the first deposition method, and a sputtering method can be used as the second deposition method. An ALD method is a deposition method that achieves higher coverage than a sputtering method, and when an ALD method is used as the deposition method of the first layer and the third layer, the coverage with the oxide semiconductor layer can be improved. Thus, the oxide semiconductor layer can be favorably covered with a step, an opening portion, or the like with a high aspect ratio.

### [Formation Method of Oxide Semiconductor Layer]

The semiconductor layer 230 that is an oxide semiconductor layer can be formed by, for example, forming a semiconductor layer 230a over a layer 229 that is the formation surface by an ALD method, forming a semiconductor layer 230b that is an oxide semiconductor layer over the semiconductor layer 230a that is an oxide semiconductor layer by a sputtering method, and forming a semiconductor layer 230c that is an oxide semiconductor layer over the semiconductor layer 230b by an ALD method. Furthermore, heat treatment is preferably performed after the semiconductor layer 230 which is an oxide semiconductor layer is formed. By performing the heat treatment, the crystallinity of the semiconductor layer 230 can be increased. Here, the heat treatment is not limited to the thermal treatment. For example, the heat treatment may be performed with heat applied in the manufacturing process.

The layer 229 corresponds to the insulating layer 235, the insulating layer 280, or the like described in the above embodiment. The layer 229 does not necessarily have crystallinity. In the case where the layer 229 has crystallinity, a crystal structure with low lattice compatibility with the metal oxide contained in the semiconductor layer 230 may be employed.

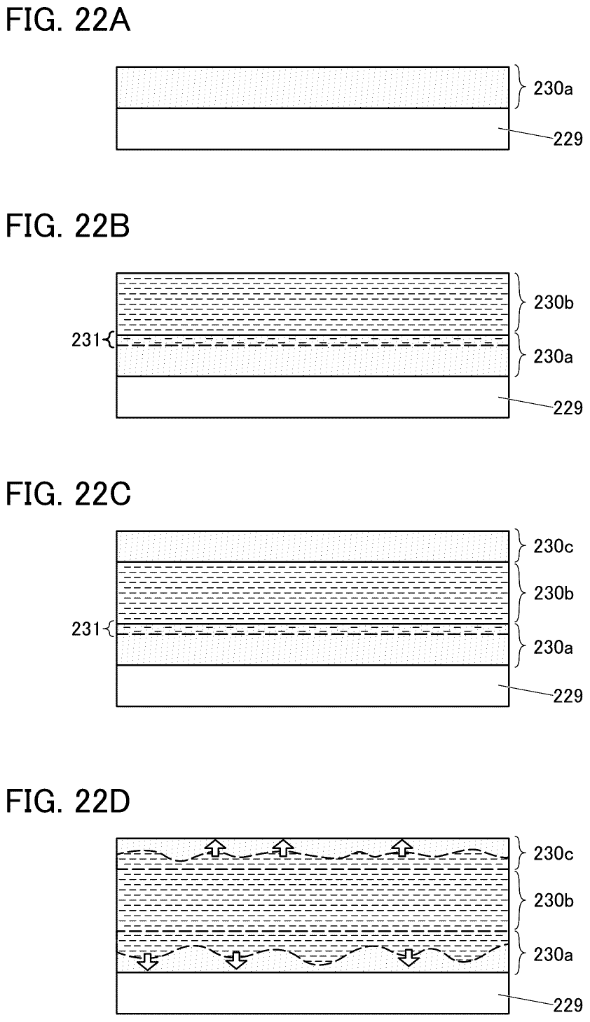

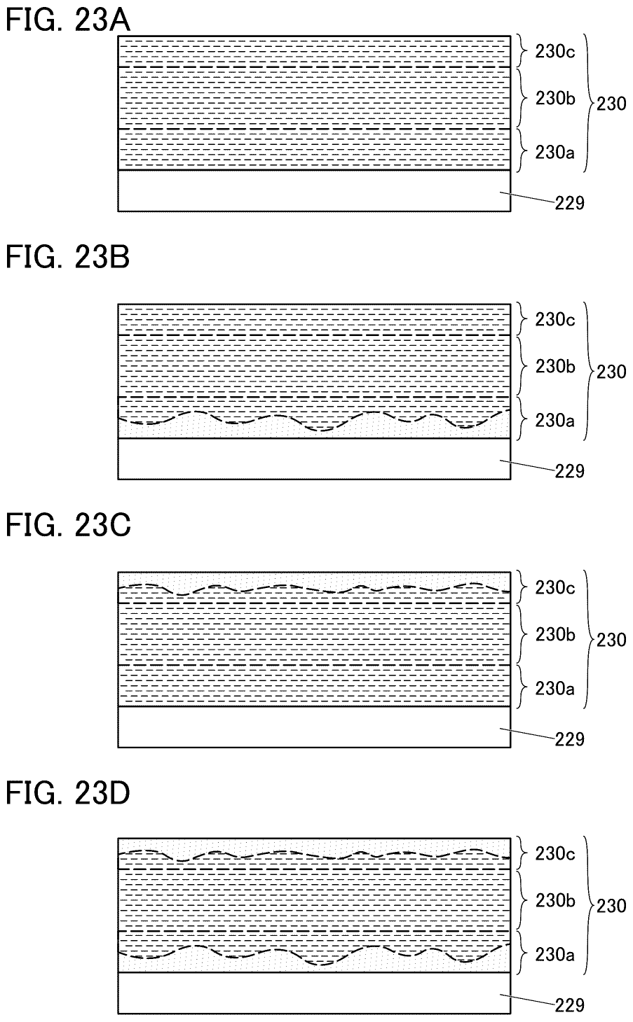

An example of a method for forming the semiconductor layer 230 is described with reference to FIGS. 22A to 22D and FIGS. 23A to 23D.

In the case where a metal oxide film is deposited by a sputtering method, damage to the formation surface due to, for example, a sputtering particle or energy applied to the substrate side by a sputtering particle or the like might cause alloying a component contained in the metal oxide film and a component contained in a layer on which the metal oxide film is formed. In the case where the alloying occurs, it is difficult to increase the crystallinity of the alloyed region even when heat treatment described later is performed. When an oxide semiconductor layer including the alloyed region is used for a transistor, the initial characteristics or reliability of the transistor might be adversely affected. Therefore, it is preferable to inhibit alloying of the component contained in the metal oxide film and the component contained in the layer on which the metal oxide film is formed.

Thus, first, the semiconductor layer 230a is formed over the layer 229 by an ALD method (FIG. 22A). Next, the semiconductor layer 230b is formed over the semiconductor layer 230a by a sputtering method (FIG. 22B).

In the method for forming the oxide semiconductor layer of one embodiment of the present invention, the semiconductor layer 230a is formed between the semiconductor layer 230b and the layer 229 by a deposition method that causes less damage to the formation surface; thus, alloying of a component contained in the semiconductor layer 230 and a component contained in the layer 229 can be inhibited, and the crystallinity of the semiconductor layer 230 can be further increased.

With the above structure, the thickness of the alloyed region can be reduced or reduced to have a thickness that is small enough not to be observed. For example, the thickness of the alloyed region can be greater than or equal to 0 nm and less than or equal to 3 nm, preferably greater than or equal to 0 nm and less than or equal to 2 nm, further preferably greater than or equal to 0 nm and less than or equal to 1 nm, still further preferably greater than or equal to 0 nm and less than 0.3 nm. Note that FIGS. 22A and 22B illustrate an example in which the alloyed region is not formed between the layer 229 and the semiconductor layer 230a.

Note that the thickness of the alloyed region can sometimes be calculated by composition line analysis of the region and its vicinity with SIMS or energy dispersive X-ray spectroscopy (EDX).

For example, EDX line analysis is performed on the region and its vicinity with the direction perpendicular to the formation surface of the semiconductor layer 230a as the depth direction. Next, in the profile of quantitative values of elements in the depth direction, which is obtained from the analysis, the depth at which the quantitative value of a metal that is the main component of the semiconductor layer 230a and is not the main component of a layer (here, the layer 229) serving as a formation surface (the metal is In when the semiconductor layer 230a contains In) becomes half is defined as the depth (position) of the interface between the region and the semiconductor layer 230a. The depth at which the quantitative value of an element (e.g., Si) that is a main component of the layer to be the formation surface and that is not a main component of the semiconductor layer 230a becomes half is defined as the depth (position) of the interface between the region and the layer to be the formation surface. In the above manner, the thickness of the alloyed region can be calculated.

When the thickness of the alloyed region in the oxide semiconductor layer of one embodiment of the present invention is observed by EDX analysis, the thickness is greater than or equal to 0 nm and less than or equal to 3 nm, preferably greater than or equal to 0 nm and less than or equal to 2 nm, further preferably greater than or equal to 0 nm and less than or equal to 1 nm, still further preferably greater than or equal to 0 nm and less than 0.3 nm, for example.

For example, in the case where a silicon oxide layer is used as the layer 229 and SIMS analysis of the semiconductor layer 230 formed over the layer 229 is performed, the depth at which the silicon concentration is the intensity of 50% of the maximum concentration value of the layer 229 is defined as the interface, and the distance between the interface and the depth at which the silicon concentration decreases to 1.0×10²¹ atoms/cm³, preferably 5.0×10²′ atoms/cm³, further preferably 1.0×10²′ atoms/cm³ is set to a thickness t_s2. The thickness t_s2 is preferably less than or equal to 3 nm, further preferably less than or equal to 2 nm.

When the thickness of the alloyed region is reduced, the thickness t_s2 can be a value within the above range.

Note that when the alloyed region is reduced, a CAAC structure can be formed in the vicinity of the formation surface. Here, the vicinity of the formation surface refers to, for example, a region ranging from the formation surface of the semiconductor layer 230 to greater than 0 nm and less than or equal to 3 nm, preferably greater than 0 nm and less than or equal to 2 nm, further preferably greater than or equal to 1 nm and less than or equal to 2 nm in a direction substantially perpendicular to the formation surface of the semiconductor layer 230.

Note that the CAAC structure in the vicinity of the formation surface can be confirmed in observation using TEM in some cases. For example, in a cross-sectional observation of the semiconductor layer 230 using a high-resolution TEM, bright spots arranged in a layered manner in a direction parallel to the formation surface are observed in the vicinity of the formation surface.

Note that in the case where the semiconductor layer 230a is formed by an ALD method, an oxide semiconductor layer having a microcrystalline structure or an amorphous structure that has lower crystallinity than the CAAC structure is formed in some cases. That is, in the formation stage illustrated in FIG. 22A, the semiconductor layer 230a sometimes includes a region having lower crystallinity than the semiconductor layer 230b.

The semiconductor layer 230b preferably has a composition suitable for forming the CAAC structure.

When the semiconductor layer 230b is formed by a sputtering method, a mixed layer 231 is formed on the surface or its vicinity of the semiconductor layer 230a. A fine crystal region is sometimes formed in the mixed layer 231 by, for example, a sputtering particle or energy applied to the substrate side by a sputtering particle or the like when the semiconductor layer 230b is formed. In the following heat treatment step, the mixed layer 231 or a fine crystal region formed in the mixed layer 231 serves as a nucleus, and at least part of the semiconductor layer 230a is crystallized in some cases.

In the deposition of the semiconductor layer 230b by a sputtering method, substrate heating is preferably performed. In formation of the metal oxide, the substrate temperature (stage temperature) at the time of forming the metal oxide is increased, whereby a metal oxide with high crystallinity can be formed in some cases.

Next, the semiconductor layer 230c is formed over the semiconductor layer 230b by an ALD method (FIG. 22C). For the formation of the semiconductor layer 230c by an ALD method, the method for forming the semiconductor layer 230a can be referred to.

When the semiconductor layer 230c is formed over the semiconductor layer 230b having a CAAC structure by an ALD method, the semiconductor layer 230c sometimes epitaxially grows with the semiconductor layer 230b as a nucleus. Thus, the semiconductor layer 230c may include a region having a CAAC structure at the time of forming the semiconductor layer 230c. The region having a CAAC structure is preferably formed over the whole semiconductor layer 230c.

Next, heat treatment step may be performed. By the heat treatment step, the crystallinity of the region having a CAAC structure in the semiconductor layer 230c is increased in some cases. In the case where the region is formed only below the semiconductor layer 230c after the deposition by an ALD method, the region may be extended upward by the heat treatment step (FIG. 22D). That is, by the heat treatment, the region having a CAAC structure is sometimes formed over the whole semiconductor layer 230c.

At least part of the semiconductor layer 230a preferably has a CAAC structure by the heat treatment step (FIG. 22D). The CAAC structure is expected to be easily generated when the mixed layer 231 formed in the semiconductor layer 230a becomes a nucleus or a species in the deposition of the semiconductor layer 230b. The region of the semiconductor layer 230a having a CAAC structure is preferably wide, and the CAAC structure preferably reaches the vicinity of the layer 229.

Since the CAAC region extends from the upper portion to the lower portion of the semiconductor layer 230a, the CAAC region can extend to the vicinity of the layer 229, regardless of the material and crystallinity of the layer 229. For example, the semiconductor layer 230a with high crystallinity can be formed even when the layer 229 has an amorphous structure. Thus, the method for forming the oxide semiconductor layer of one embodiment of the present invention is particularly suitable in the case where the layer that is the formation surface has an amorphous structure.

FIGS. 22A to 22D are cross-sectional views illustrating a method for depositing the metal oxide of one embodiment of the present invention. FIGS. 22A to 22D can be regarded as conceptual diagrams illustrating a deposition model of the metal oxide of one embodiment of the present invention. As illustrated in FIGS. 22A to 22D, the semiconductor layers 230a and 230c have high crystallinity with the use of the semiconductor layer 230b having high crystallinity as a nucleus or a species. Specifically, the crystallinity of the semiconductor layer 230a may be increased by heat treatment at the time of depositing the semiconductor layer 230b or after depositing the semiconductor layer 230c. The crystallinity of the semiconductor layer 230c may be increased by heat treatment at the time of depositing the semiconductor layer 230c or after depositing the semiconductor layer 230c. Note that the heat treatment has an assisting function for increasing crystallinity.

As described above, in the method for depositing the metal oxide of one embodiment of the present invention, the crystallinity of the upper and lower oxide semiconductors (here, the semiconductor layer 230a and the semiconductor layer 230c) can be increased with use of the semiconductor layer 230b with high crystallinity (i.e., CAAC) as a nucleus or a species. Thus, the crystallinity of the whole oxide semiconductor can be increased. In other words, the semiconductor layer 230b is used as a nucleus or a species to form a solid-phase growth of the upper and lower oxide semiconductor, so that an oxide semiconductor with high crystallinity can be formed. An oxide semiconductor formed by such a deposition method, here, a CAAC film, can be referred to as an axial growth CAAC (AG CAAC). Although FIGS. 23A to 23D illustrate a structure example including the semiconductor layers 230a, 230b, and 230c, one embodiment of the present invention is not limited thereto. For example, a structure including the semiconductor layers 230a and 230b can also be referred to as an AG CAAC.

A region having a CAAC structure preferably exists widely over the whole semiconductor layer 230. FIG. 23A illustrates a state where the semiconductor layers 230a, 230b, and 230c are crystallized. In that case, a boundary between the semiconductor layer 230b and the semiconductor layer 230a or 230c is not observed in some cases. In some cases, the semiconductor layer 230 can be expressed as one layer in which interfaces are not clearly observed. That is, the semiconductor layer 230 can be expressed by a single layer in some cases.

In addition, part of the semiconductor layer 230a or 230c is not crystallized in some cases. An example in FIG. 23B illustrates a state where the vicinity of the interface between the layer 229 and the semiconductor layer 230a is not crystallized. FIG. 23C illustrates a state where the vicinity of the surface of the semiconductor layer 230c is not crystallized. FIG. 23D illustrates a state where the vicinity of the interface between the layer 229 and the semiconductor layer 230a and the vicinity of the surface of the semiconductor layer 230c are not crystallized.

Increasing the crystallinity of the oxide semiconductor layer inhibits an increase in the electric resistance of the semiconductor layer of the transistor including the oxide semiconductor layer or improves the initial characteristics (in particular, the on-state current) of the transistor, so that a transistor suitable for high-speed driving can be expected to be manufactured. In addition, the reliability of the transistor can be improved and the amount of the on-state current can be increased.

The whole oxide semiconductor layer of one embodiment of the present invention has high crystallinity. Thus, in the semiconductor layer 230 where the semiconductor layers 230a, 230b, and 230c are stacked, a boundary between the stacked films is not observed in some cases. In particular, after thermal treatment, a boundary between the stacked films is difficult to be observed in some cases. The presence or absence of a boundary between the stacked films can be confirmed with TEM, for example.

As described above, when a metal oxide with a high In content is used for a transistor, the field-effect mobility of the transistor can be increased. Meanwhile, an oxide semiconductor with a high In content tends to be polycrystallized. The use of a metal oxide having a polycrystalline structure for a transistor adversely affects the initial characteristics or reliability of the transistor. Thus, when an oxide semiconductor with a high In content is used for one or both of the semiconductor layer 230a and the semiconductor layer 230c, crystals in which orientations of crystals included in the semiconductor layer 230b are reflected are formed, so that polycrystallization can be inhibited.

It is preferable that crystals included in the semiconductor layer 230b and crystals included in the semiconductor layer 230a or 230c have a small lattice mismatch degree. Thus, the semiconductor layer 230a or the semiconductor layer 230c can form crystals reflecting the orientation of crystals included in the semiconductor layer 230b. At this time, in cross-sectional observation of the semiconductor layer 230 using a high-resolution TEM, for example, bright spots arranged in a layered manner in a direction parallel to the formation surface are observed in the semiconductor layer 230a or 230c.

When the crystals included in the semiconductor layer 230b and the crystals included in the semiconductor layer 230a or 230c have a small lattice mismatch degree, there is no particular limitation on the crystal structure of the semiconductor layer 230a or 230c. The crystal structure of the semiconductor layer 230a or 230c may be any of a cubic crystal structure, a tetragonal crystal structure, an orthorhombic crystal structure, a hexagonal crystal structure, a monoclinic crystal structure, and a trigonal crystal structure.

### [Composition of Oxide Semiconductor Layer]

As described above, the composition of the semiconductor layer 230b is preferably set to a composition suitable for forming a CAAC structure. The semiconductor layer 230b can be formed by a sputtering method, for example. The semiconductor layer 230b preferably contains zinc, for example. The semiconductor layer 230b containing zinc can be a metal oxide with high crystallinity. The semiconductor layer 230b preferably contains the element M in addition to zinc. When the semiconductor layer 230b contains the element M, formation of oxygen vacancies in the metal oxide can be inhibited, for example. Thus, the reliability of the transistor including the oxide semiconductor layer can be improved. For the semiconductor layer 230b, a metal oxide with a composition of In:M:Zn=1:1:1 [atomic ratio] or in the neighborhood thereof, a metal oxide with a composition of In:M:Zn=1:1:1.2 [atomic ratio] or in the neighborhood thereof, a metal oxide with a composition of In:M:Zn=1:1:0.5 [atomic ratio] or in the neighborhood thereof, a metal oxide with a composition of In:M:Zn=1:1:2 [atomic ratio] or in the neighborhood thereof, a metal oxide with a composition of In:M:Zn=4:2:3 [atomic ratio] or in the neighborhood thereof, a metal oxide with a composition of In:M:Zn=1:3:2 [atomic ratio] or in the neighborhood thereof, or a metal oxide with a composition of In:M:Zn=1:3:4 [atomic ratio] or in the neighborhood thereof may be specifically used. Note that the neighborhood of the atomic ratio includes ±30% of an intended atomic ratio. It is preferable to use one or more of gallium, aluminum, and tin as the element M.

The semiconductor layer 230b does not necessarily contain the element M. For example, In—Zn oxide may be used. Specifically, a composition of In:Zn=1:1 [atomic ratio] or in the neighborhood thereof, a composition of In:Zn=2:1 [atomic ratio] or in the neighborhood thereof, or a composition of In:Zn=4:1 [atomic ratio] or in the neighborhood thereof can be used. Alternatively, indium oxide may be used. A structure containing a slight amount of the element M may be employed. Examples of the composition include a composition of In:Ga:Zn=4:0.1:1 [atomic ratio] or in the neighborhood thereof and a composition of In:Ga:Zn=2:0.1:1 [atomic ratio] or in the neighborhood thereof. Other examples include a composition of In:Sn:Zn=4:0.1:1 [atomic ratio] or in the neighborhood thereof and a composition of In:Sn:Zn=2:0.1:1 [atomic ratio] or in the neighborhood thereof.

Each of the semiconductor layers 230a and 230c can be a metal oxide with a high proportion of In. The semiconductor layers 230a and 230c can be formed by an ALD method, for example. It is particularly preferable to use a metal oxide in which the proportion of In is higher than that of the element M. With the use of a metal oxide with a high proportion of In, the amount of the on-state current can be increased and the frequency characteristics can be increased in the case where an oxide semiconductor layer is used for a transistor.

Alternatively, the semiconductor layer 230a and the semiconductor layer 230c do not necessarily contain the element M. For example, In—Zn oxide may be used. Specifically, a composition of In:Zn=1:1 [atomic ratio] or in the neighborhood thereof, a composition of In:Zn=2:1 [atomic ratio] or in the neighborhood thereof, or a composition of In:Zn=4:1 [atomic ratio] or in the neighborhood thereof can be used. Alternatively, indium oxide may be used. Each of the semiconductor layer 230a and the semiconductor layer 230c may contain a slight amount of the element M. Specifically, a composition of In:Ga:Zn=4:0.1:1 [atomic ratio] or in the neighborhood thereof, a composition of In:Ga:Zn=2:0.1:1 [atomic ratio] or in the neighborhood thereof, a composition of In:Sn:Zn=4:0.1:1 [atomic ratio] or in the neighborhood thereof, or a composition of In:Sn:Zn=2:0.1:1[atomic ratio] or in the neighborhood thereof can be used.

Note that when the composition of zinc in the oxide semiconductor is increased, the crystallinity of the oxide semiconductor can be increased. In particular, the semiconductor layer 230a preferably contains zinc. For example, in the case where the semiconductor layer 230a is formed by an ALD method and the semiconductor layer 230b is formed by a sputtering method, zinc contained in the semiconductor layer 230a is diffused into the semiconductor layer 230b in some cases. Note that the diffusion can be generated at the time of sputtering or later heat treatment. The diffusion of zinc from the semiconductor layer 230a to the semiconductor layer 230b is expected to improve the crystallinity. Alternatively, diffusion of zinc from the semiconductor layer 230a into the semiconductor layer 230b is expected to promote the CAAC structure by lateral growth of a crystal part having c-axis alignment.

The semiconductor layer 230a and the semiconductor layer 230c can each be a metal oxide having a higher proportion of In than the semiconductor layer 230b.

For example, a metal oxide having a higher proportion of Ga than the semiconductor layer 230b can also be used for the semiconductor layer 230a and the semiconductor layer 230c. For example, for each of the semiconductor layer 230a and the semiconductor layer 230c, a metal oxide with a composition of In:Ga:Zn=1:1:1 [atomic ratio] or in the neighborhood thereof, a metal oxide with a composition of In:Ga:Zn=1:3:2 [atomic ratio] or in the neighborhood thereof, or a metal oxide with a composition of In:Ga:Zn=1:3:4 [atomic ratio] or in the neighborhood thereof is preferably used. When the proportion of Ga is increased, the band gap of each of the semiconductor layers 230a and 230c can be larger than that of the semiconductor layer 230b in some cases, for example. Thus, the semiconductor layer 230b is sandwiched between the semiconductor layers 230a and 230c each having a wide band gap, and the semiconductor layer 230b mainly functions as a current path (channel). When the semiconductor layer 230b is sandwiched between the semiconductor layers 230a and 230c, the trap states at the interface of the semiconductor layer 230b and its vicinity can be reduced. Accordingly, a buried-channel transistor where a channel is away from the interface with an insulating layer can be achieved, whereby the field-effect mobility can be increased.

In the oxide semiconductor layer of one embodiment of the present invention, even in the case where a composition in which the CAAC structure is less likely to be formed in the formation of a single layer is used for the semiconductor layers 230a and 230c, crystal growth occurs with the semiconductor layer 230b as a nucleus, so that the whole oxide semiconductor layer including the semiconductor layers 230a and 230c can have a CAAC structure. Alternatively, a CAAC structure can be formed in a region including the whole semiconductor layer 230b and a region including at least part of each of the semiconductor layers 230a and 230c.

In particular, even in the composition where the proportion of In in the semiconductor layers 230a and 230c is high, crystallinity suitable for a semiconductor layer of a transistor can be obtained. The oxide semiconductor layer of one embodiment of the present invention enables both high on-state characteristics and high reliability of a transistor, respectively by having a high proportion of In and by having a CAAC structure with high crystallinity.

Note that the semiconductor layer 230a and the semiconductor layer 230c may have different compositions.

The semiconductor layers 230a and 230c may be formed using a metal oxide having the same composition as the semiconductor layer 230b.

With the use of the oxide semiconductor layer having the CAAC structure formed by the above-described two kinds of deposition methods for a channel formation region of a transistor, the transistor can have excellent characteristics (e.g., a high on-state current, high field-effect mobility, a low S value, high frequency characteristics (also referred to as f characteristics), or high reliability).

Analysis of the composition of the metal oxide used for the semiconductor layer 230 can be performed by EDX, XPS, inductively coupled plasma-mass spectrometry (ICP-MS), or inductively coupled plasma-atomic emission spectrometry (ICP-AES), for example. Alternatively, any of these methods may be combined with each other for the analysis. As for an element whose content is low, the actual content may be different from the content obtained by analysis because of the influence of the analysis accuracy. In the case where the content of the element M is low, for example, the content of the element M obtained by analysis may be lower than the actual content.

[c-Axis Alignment Proportion]

The oxide semiconductor layer of one embodiment of the present invention has a CAAC structure. The degree of the crystallinity of the oxide semiconductor layer of one embodiment of the present invention can be evaluated with the use of crystal orientation, for example.

The crystal orientation can be obtained from an fast fourier transform (FFT) pattern obtained by performing FFT processing on a TEM image. Specifically, the directions of the crystal axes can be obtained using an FFT pattern. The FFT pattern obtained by the FFT processing reflects reciprocal lattice space information like an electron diffraction pattern.

When FFT processing is performed on each region in the TEM image of the oxide semiconductor layer, crystal orientation of each region can be obtained. For example, crystal orientation is obtained by each region in a certain area range, so that a map indicating crystal orientation can be formed. Specifically, two spots with high intensity are observed in the FFT pattern of the region including a layered crystal part. The direction of the crystal axis of the region can be obtained from the angle of the line segment connecting the two spots.

In the map showing crystal orientation, the c-axis alignment proportion can be calculated by calculating the proportion of the region having c-axis alignment. Here, the c-axis alignment region is a region where the difference between the region aligned with the c-axis and the c-axis is less than or equal to 20°.

In the oxide semiconductor layer of one embodiment of the present invention, the c-axis alignment proportion can be calculated by, for example, a cross-section or a plan-view TEM observation of the oxide semiconductor layer. The region where the FFT is performed (also referred to as an FFT window) can be a circle with a diameter of 1.0 nm, for example. Note that the region where the FFT is performed is not limited to a circle.

In the oxide semiconductor layer of one embodiment of the present invention, the c-axis alignment proportion is higher than or equal to 60%, preferably higher than or equal to 70%, further preferably higher than or equal to 80%, still further preferably higher than or equal to 90%, yet still further preferably higher than or equal to 95%.

Furthermore, the c-axis alignment proportions of the region where the semiconductor layer 230a is deposited, the region where the semiconductor layer 230b is deposited, and the region where the semiconductor layer 230c is deposited are Rc1, Rc2, and Rc3, respectively. Each of Rc2 and Rc3 is higher than or equal to 60%, preferably higher than or equal to 70%, further preferably higher than or equal to 80%, still further preferably higher than or equal to 90%, yet still further preferably higher than or equal to 95%. Rc3/Rc1 is preferably higher than 1. Furthermore, Rc2/Rc1 is preferably higher than 1.

Note that the boundaries between the semiconductor layers 230a, 230b, and 230c are not clearly observed after the formation of the semiconductor layer 230 in some cases.

The semiconductor layer 230 of one embodiment of the present invention can be divided into three regions: a first region, a second region, and a third region in this order from the top of the layer 229. Each of the regions is a layered region.

The first, second, and third regions each have a CAAC structure. In addition, the c-axis alignment proportion in the third region is preferably higher than the c-axis alignment proportion in the first region. The c-axis alignment proportion in the second region is preferably higher than the c-axis alignment proportion in the first region. The c-axis alignment proportions in the second region and the third region are higher than or equal to 80%, preferably higher than or equal to 90%, further preferably higher than or equal to 95%.

The first region is positioned in a range of 0 nm to 3 nm, both inclusive, from the top surface of the layer 229, and the third region is positioned in a range of 0 nm to 3 nm, both inclusive, from the top surface of the semiconductor layer 230.

The thicknesses of the layers in the regions are substantially the same, for example.

This embodiment can be implemented in an appropriate combination with any of the structures described in the other embodiments and the like.

### Embodiment 4

In this embodiment, a structure example of a memory device 300 including the memory string 100 of one embodiment of the present invention will be described.

### <Memory Device 300>

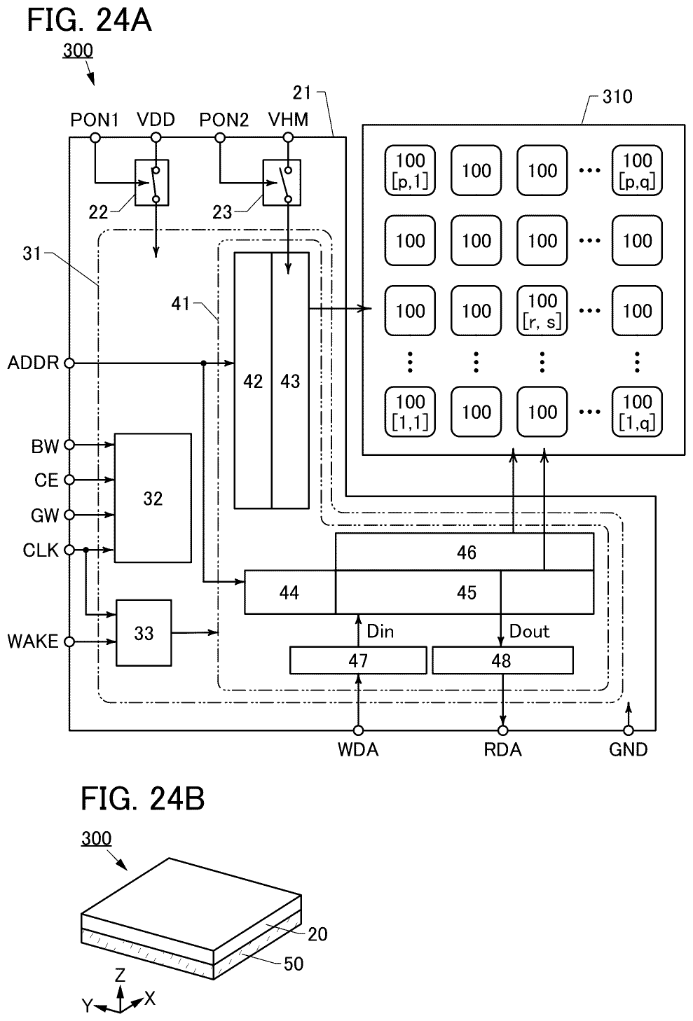

FIG. 24A is a block diagram illustrating a structure example of the memory device 300 including the memory string 100 of one embodiment of the present invention. The memory device 300 illustrated in FIG. 24A includes a driver circuit 21 and a memory cell array 310.

The memory cell array 310 includes a plurality of memory strings 100 arranged in a matrix of p rows and q columns (p and q are each an integer greater than or equal to 1). When the plurality of memory strings 100 are arranged in a matrix, a memory device with high storage capacity can be achieved.

In FIG. 24A, the memory string 100 in the first row and the first column is denoted by the memory string 100[1,1], the memory string 100 in the p-th row and the q-th column is denoted by the memory string 100[p,q], the memory string 100 in the p-th row and the first column is denoted by the memory string 100[p,1], the memory string 100 in the first row and the q-th column is denoted by the memory string 100[1,q], and the memory string 100 in the r-th row and the s-th column (r represents a given row and is an integer greater than or equal to 1 and less than or equal to p, and s represents a given column and is an integer greater than or equal to 1 and less than or equal to q) is denoted by the memory string 100[r,s].

Note that the rows and the columns extend in directions orthogonal to each other. In this embodiment, the X direction (the direction along the X axis) is referred to as a “row” and the Y direction (the direction along the Y axis) is referred to as a “column”, but the X direction may be referred to as a “column” and the Y direction may be referred to as a “row”.

The driver circuit 21 includes a power switch 22, a power switch 23, and a peripheral circuit 31. The peripheral circuit 31 includes a peripheral circuit 41, a control circuit 32, and a voltage generation circuit 33.

In the memory device 300, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the memory device 300. For example, the control circuit performs a logical operation on the signal CE, the signal GW, and the signal BW to determine an operation mode (e.g., a writing operation or a reading operation) of the device 300. Alternatively, the control circuit 32 generates a control signal for the peripheral circuit 41 so that the operation mode is executed.

The voltage generation circuit 33 has a function of generating a voltage. The signal WAKE has a function of controlling the input of the signal CLK to the voltage generation circuit 33. For example, when a signal of the potential H is supplied as the signal WAKE, the signal CLK is input to the voltage generation circuit 33, and the voltage generation circuit 33 generates a voltage.

The peripheral circuit 41 is a circuit for writing and reading data to/from the memory strings 100. The peripheral circuit 41 includes a row decoder 42, a column decoder 44, a row driver 43, a column driver 45, an input circuit 47, a sense amplifier 46, and an output circuit 48.

The row decoder 42 and the column decoder 44 have a function of decoding the signal ADDR. The row decoder 42 is a circuit for specifying a row to be accessed, and the column decoder 44 is a circuit for specifying a column to be accessed. The row driver 43 has a function of selecting wirings (the wiring WWL, the wiring WBG, and the wiring RBG) specified by the row decoder 42. The column driver 45 has a function of supplying data stored in the memory string 100 to the wiring WBL specified by the column decoder 44. The column driver 45 has a function of supplying the potential H to the wiring RBL specified by the column decoder 44. The sense amplifier 46 has a function of detecting a change in the potential of the wiring RBL specified by the column decoder 44 and reading out data stored in the memory string 100.

The input circuit 47 has a function of retaining the signal WDA. Data retained by the input circuit 47 is output to the column driver 45. Data output from the input circuit 47 is data (Din) to be written to the memory string 100. Data (Dout) read from the memory string 100 by the sense amplifier 46 is output to the output circuit 48. The output circuit 48 has a function of retaining Dout. In addition, the output circuit 48 has a function of outputting Dout to the outside of the memory device 300. Data output from the output circuit 48 is the signal RDA.

The power switch 22 has a function of controlling supply of the potential VDD to the peripheral circuit 31. The power switch 23 has a function of controlling supply of the potential VHM to the row driver 43. Here, in the memory device 300, a high power supply potential is the potential VDD and a low power supply potential is the potential GND (a ground potential). In addition, the potential VHM is a power supply potential used to set a word line (e.g., the wiring WWL) at the potential H and is higher than the potential VDD. The on/off state of the power switch 22 is controlled by the signal PON1, and the on/off state of the power switch 23 is controlled by the signal PON2. The number of power domains to which the potential VDD is supplied is one in the peripheral circuit 31 in FIG. 24A but can be more than one. In that case, a power switch is provided for each power domain.

As illustrated in FIG. 24B, the driver circuit 21 may be provided in the layer 50, and the layer 20 including the memory cell array 310 may be provided to overlap with the layer 50. For the layer 50, a single crystal semiconductor substrate, an SOI substrate, or the like can be used. When the layer 50 including the driver circuit 21 and the layer 20 including the memory cell array 310 are separately formed, the operation of the driver circuit 21 included in the layer 50 can be confirmed before the layer 20 is formed over the layer 50. Consequently, the manufacturing yield of the memory device 300 can be improved because only the non-defective layer 50 can be used.

When the layer 50 including the driver circuit 21 and the layer 20 including the memory cell array 310 are provided to overlap with each other, the signal propagation distance between the driver circuit 21 and the memory array 310 can be shortened. Accordingly, parasitic resistance and parasitic capacitance between the driver circuit 21 and the memory array 310 are reduced, so that power consumption and signal delays can be reduced. In addition, the memory device 300 can be downsized. Furthermore, the storage capacity per unit area can be increased.

### <Stacked-Layer Structure Example of Memory Device>

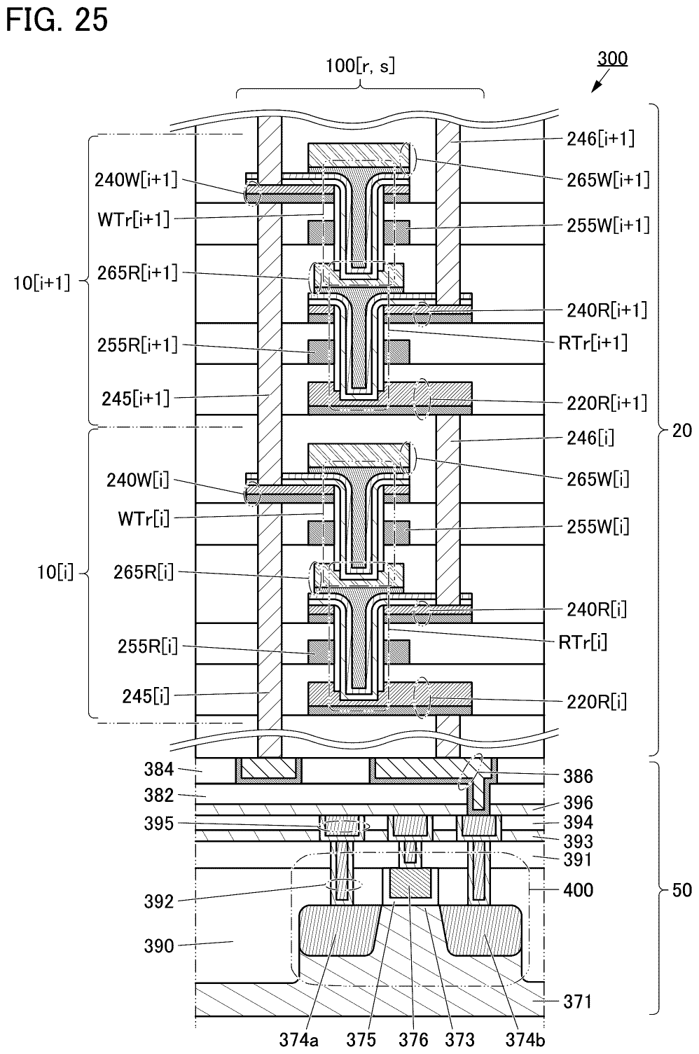

FIG. 25 illustrates a stacked-layer structure example of the memory device 300 that is a kind of a semiconductor device. The memory device 300 illustrated in FIG. 25 includes the layer 20 including the memory cell array 310 above the layer 50 including the driver circuit 21. FIG. 25 illustrates the memory cell 10[i] and the memory cell 10[i+1] in the memory string 100[r,s] as an example. In FIG. 25, some layers in the memory cell 10[i] are denoted by “[i]”. Part of some layers in the memory cell 10[i+1] are denoted by “[i+1]”.

Note that the description of the memory cells 10 is omitted here in order to reduce repeated description.

In FIG. 25, a transistor 400 is illustrated as an example of a transistor included in the driver circuit 21. The transistor 400 is provided on a substrate 371 and includes a conductive layer 376 functioning as a gate, an insulating layer 375 functioning as a gate insulating layer, a semiconductor region 373 that is a part of the substrate 371, and a low-resistance region 374a and a low-resistance region 374b functioning as a source region and a drain region. As the transistor 400, either a p-channel transistor or an n-channel transistor can be used. As the substrate 371, a single crystal silicon substrate can be used, for example.

In the transistor 400 illustrated in FIG. 25, the semiconductor region 373 (part of the substrate 371) in which a channel is formed has a protruding shape. Furthermore, the conductive layer 376 is provided to cover the side and top surfaces of the semiconductor region 373 with the insulating layer 375 therebetween. Note that the conductive layer 376 may be formed using a material for adjusting the work function. The transistor 400 is also referred to as a FIN-type transistor because it utilizes a protruding portion of the semiconductor substrate. Note that an insulating layer serving as a mask for forming the projecting portion may be provided in contact with the top of the projecting portion. Although the case where the protruding portion is formed by processing part of the semiconductor substrate is described here, a semiconductor film having a protruding shape may be formed by processing an SOI substrate.

Note that the transistor 400 illustrated in FIG. 25 is just an example and is not limited to the structure illustrated therein; an appropriate transistor is used in accordance with a circuit structure or a driving method.

Wiring layers including an interlayer film, a wiring, a plug, and the like may be provided in the layer 50. A plurality of wiring layers can be provided in accordance with the design. Furthermore, in this specification and the like, a wiring and a plug electrically connected to the wiring may be a single component. That is, in some cases, part of a conductive layer functions as a wiring or part of a conductive layer functions as a plug.

For example, an insulating layer 390, an insulating layer 391, an insulating layer 393, and an insulating layer 394 are stacked over the transistor 400 in this order as interlayer insulating films. A conductive layer 392 or the like is embedded in the insulating layer 390 and the insulating layer 391. A conductive layer 395 or the like are embedded in the insulating layer 393 and the insulating layer 394. Note that the conductive layer 392 and the conductive layer 395 function as contact plugs or wirings.

The insulating layer functioning as an interlayer film may function as a planarization film that covers a roughness thereunder. For example, CMP treatment or the like may be performed on the top surface of the insulating layer 391 to improve planarity.

A wiring layer may be provided over the insulating layer 394 and the conductive layer 395. For example, in FIG. 25, an insulating layer 396, an insulating layer 382, and an insulating layer 384 are stacked in this order over the insulating layer 394 and the conductive layer 395. Furthermore, a conductive layer 386 is formed in the insulating layers 396, 382, and 384. The conductive layer 386 functions as a contact plug or a wiring. The memory string 100[r,s] is connected to the transistor 400 through the conductive layer 386.

This embodiment can be implemented in an appropriate combination with any of the structures described in the other embodiments and the like.

### Embodiment 5

In this embodiment, an application example of a memory device including a memory element of one embodiment of the present invention (hereinafter, also referred to as “a memory device of one embodiment of the present invention”) will be described.

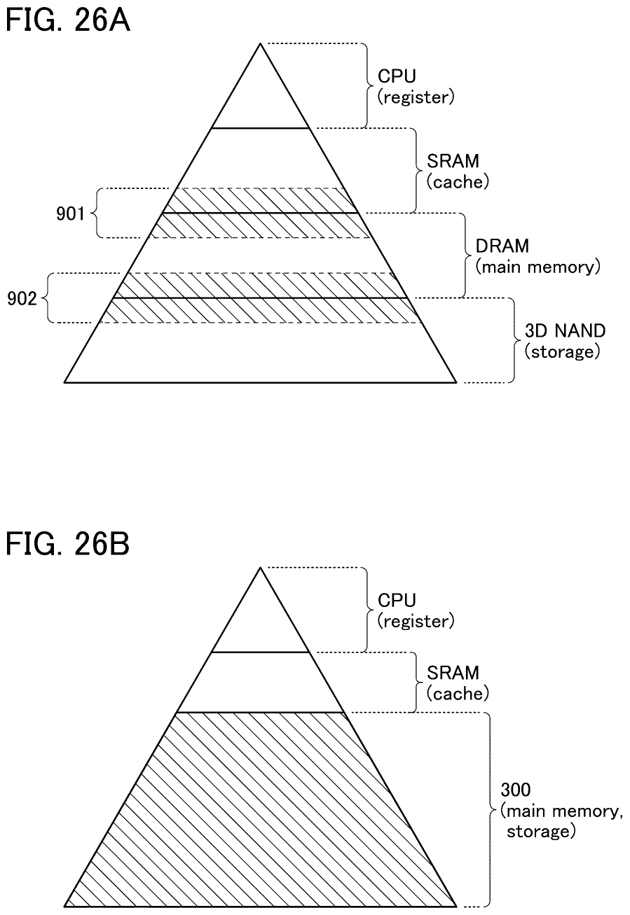

In general, a variety of memory devices are used in semiconductor devices such as computers in accordance with the intended use. FIG. 26A illustrates the hierarchy of various memory devices used in a semiconductor device. The memory devices at the upper levels require a higher operating speed, whereas the memory devices at the lower levels require a larger storage capacity and a higher memory density. FIG. 26A illustrates, sequentially from the top level, a memory included as a register in an arithmetic processing device such as a CPU, a static random access memory (SRAM), a dynamic random access memory (DRAM), and a 3D NAND memory.

A memory included as a register in an arithmetic processing device such as a CPU is used for temporary storage of arithmetic operation results, for example, and thus is very frequently accessed by the arithmetic processing device. Accordingly, high operating speed is required rather than storage capacity. The register also has a function of retaining settings of the arithmetic processing device, for example.

An SRAM is used for a cache, for example. The cache has a function of duplicating and retaining part of data retained in the main memory. Duplicating frequently used data and retaining the duplicated data in the cache facilitates rapid data access. The cache requires a smaller storage capacity than the main memory but a higher operating speed than the main memory. Data that is rewritten in the cache is duplicated, and the duplicated data is supplied to the main memory.

A DRAM is used for the main memory, for example. The main memory has a function of retaining a program and data that are read from the storage. The memory density of a DRAM is approximately 0.1 to 0.3 Gbit/mm².

A 3D NAND memory is used for the storage, for example. The storage has a function of retaining data that needs to be stored for a long time and programs used in an arithmetic processing device, for example. Therefore, the storage needs to have a high storage capacity and a high memory density rather than operating speed. The memory density of the memory device used for a storage is approximately 0.6 to 6.0 Gbit/mm².

The memory device of one embodiment of the present invention operates fast and can retain data for a long time. The memory device of one embodiment of the present invention is favorably used as a memory device in a boundary region 901 that includes both the level including the cache and the level including the main memory. The memory device of one embodiment of the present invention is favorably used as a memory device in a boundary region 902 that includes both the level including the main memory and the level including the storage.

The memory device of one embodiment of the present invention is favorably used at both the level including the main memory and the level including the storage. The memory device of one embodiment of the present invention is favorably used at the level including the cache. FIG. 26B illustrates the hierarchy of various memory devices different from that in FIG. 26A.

FIG. 26B illustrates, sequentially from the top level, a memory included as a register in an arithmetic processing device such as a CPU, an SRAM used as a cache, and the memory device 300 of one embodiment of the present invention. The memory device 300 of one embodiment of the present invention can be used for the cache, main memory, and storage. When a high-speed memory of 1 GHz or higher is required as the cache, the cache is included in an arithmetic processing device such as a CPU.

The memory device of one embodiment of the present invention can be used for an electronic component, a large computer, a device for space, a data center (DC), and a variety of electronic devices, for example. With the use of the memory device of one embodiment of the present invention, the electronic component, the large computer, the device for space, the DC, and a variety of electronic devices can have reduced power consumption and higher performance.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and laptop personal computers, a monitor of a computer and the like, digital signage, and a large game machine such as a pachinko machine.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device in this embodiment can have a function of displaying a variety of data (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

### [Electronic Component]

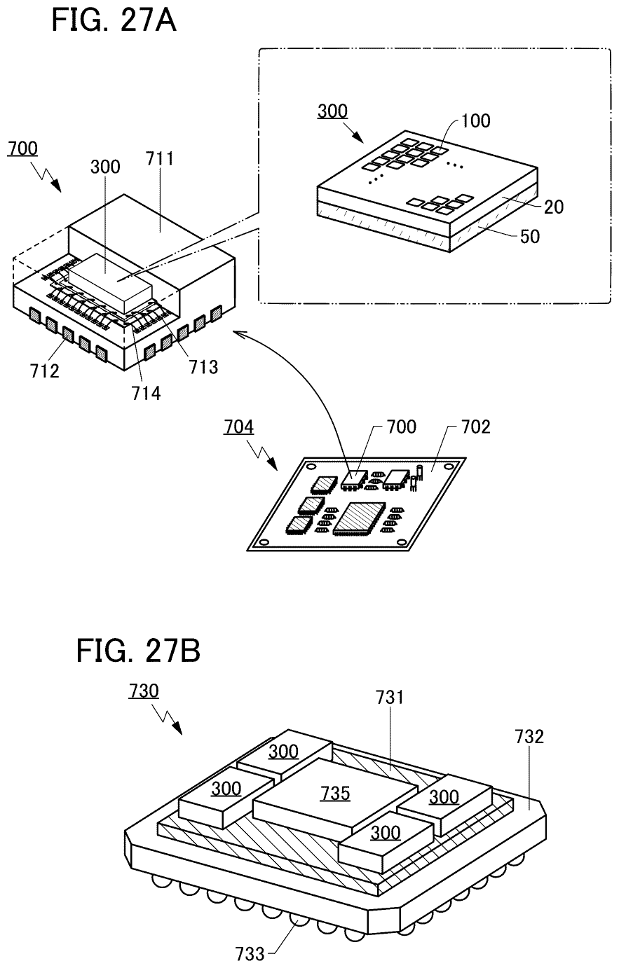

FIG. 27A is a perspective view of a substrate (a circuit board 704) provided with an electronic component 700. The electronic component 700 illustrated in FIG. 27A includes the memory device 300 in a mold 711. Some components are omitted in FIG. 27A to show the inside of the electronic component 700. The electronic component 700 includes a land 712 outside the mold 711. The land 712 is electrically connected to an electrode pad 713, and the electrode pad 713 is electrically connected to the memory device 300 through a wire 714. The electronic component 700 is mounted on a printed circuit board 702, for example. A plurality of such electronic components are combined and electrically connected to each other on the printed circuit board 702, which forms the circuit board 704.

The memory device 300 includes the layer 50 and the layer 20. Note that the layer 50 includes the driver circuit 21, and the layer 20 includes the memory cell array 310. The memory cell array 310 includes the plurality of memory strings 100. Each of the memory strings 100 includes the plurality of memory cells 10. The memory device 300 can have a monolithic stacked-layer structure of the layer 50 and the layer 20. In the monolithic stacked-layer structure, layers can be connected to each other without using a through electrode technique such as a through silicon via (TSV) technique and a bonding technique such as Cu-to-Cu direct bonding. The monolithic stacked-layer structure of the layer 50 and the layer 20 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is used, which means that the number of connection pins can be increased. The increase in the number of connection pins enables parallel operations, which can improve the bandwidth of the memory (also referred to as a memory bandwidth).

It is preferable that the memory cell array 310 included in the layer 20 be formed with OS transistors and be monolithically stacked. The monolithic stacked-layer structure of memory cell arrays can improve the bandwidth of the memory and/or the access latency of the memory. Note that the bandwidth refers to the data transfer volume per unit time, and the access latency refers to a period of time from data access to the start of data transmission. Note that in the case where the layer 20 is formed with Si transistors, the monolithic stacked-layer structure is difficult to form compared with the case where the layer 20 is formed with OS transistors. Therefore, an OS transistor is superior to a Si transistor in the monolithic stacked-layer structure.

The memory device 300 may be called a die. Note that in this specification and the like, a die refers to a chip obtained by, for example, forming a circuit pattern on a disc-like substrate (also referred to as a wafer) or the like and cutting the substrate with the pattern into dices in a process of manufacturing a semiconductor chip. Examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

Next, FIG. 27B is a perspective view of an electronic component 730. The electronic component 730 is an example of a system in package (SiP) or a multi-chip module (MCM). In the electronic component 730, an interposer 731 is provided over a package substrate 732 (printed circuit board), and a semiconductor device 735 and a plurality of memory devices 300 are provided over the interposer 731.

The electronic component 730 using the memory device 300 as a high bandwidth memory (HBM) is illustrated as an example. The semiconductor device 735 can be used for an integrated circuit such as a CPU, a GPU, or an field programmable gate array (FPGA).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected with use of a silicon interposer, TSV, and the like, a space for a width of the terminal pitch and the like is needed. Accordingly, in the case where the size of the electronic component 730 is reduced, the width of the terminal pitch becomes an issue, which sometimes makes it difficult to provide a large number of wirings for obtaining a wide memory bandwidth. For this reason, the above-described monolithic stacked-layer structure with use of OS transistors is suitable. A composite structure obtained by combining a stacked-layer of memory cell arrays formed by TSV and a monolithic stacked-layer of memory cell arrays may be employed.

In addition, a heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the memory devices 300 and the semiconductor device 735 are preferably equal to each other.

To mount the electronic component 730 on another substrate, an electrode 733 may be provided on a bottom portion of the package substrate 732. FIG. 27B illustrates an example in which the electrode 733 is formed of a solder ball. Solder balls are provided in a matrix on the bottom portion of the package substrate 732, so that BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by various mounting methods other than BGA and PGA. Examples of a mounting method include SPGA (Staggered Pin Grid Array), LGA (Land Grid Array), QFP (Quad Flat Package), QFJ (Quad Flat J-leaded package), and QFN (Quad Flat Non-leaded package).

### [Large Computer]

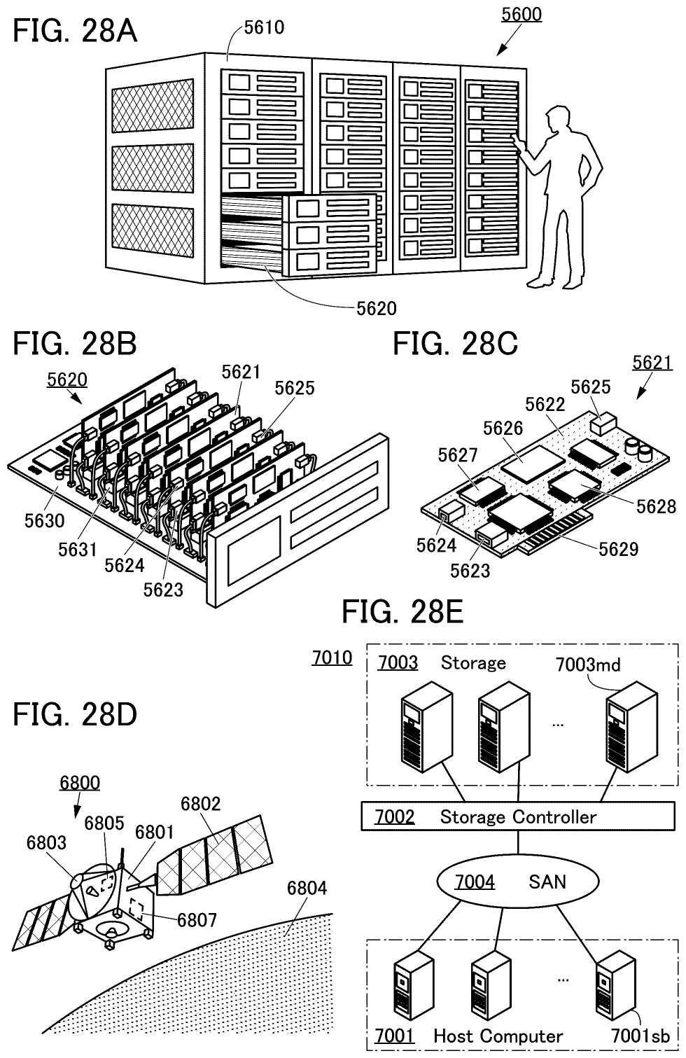

Next, FIG. 28A is a perspective view of a large computer 5600. In the large computer 5600 illustrated in FIG. 28A, a plurality of rack mount computers 5620 are stored in a rack 5610. Note that the large computer 5600 may be referred to as a supercomputer.

The computer 5620 can have a structure in a perspective view illustrated in FIG. 28B, for example. In FIG. 28B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 28C is an example of a processing board provided with a CPU, a GPU, a memory device, and the like. The PC card 5621 includes a board 5622. The board 5622 includes a connection terminal 5623, a connection terminal 5624, a connection terminal 5625, a semiconductor device 5626, a semiconductor device 5627, a semiconductor device 5628, and a connection terminal 5629. Note that FIG. 28C also illustrates semiconductor devices other than the semiconductor device 5626, the semiconductor device 5627, and the semiconductor device 5628, the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing electric power supply, signal input, or the like to the PC card 5621. As another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device or the like. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Device for Space]

The semiconductor device of one embodiment of the present invention is suitably used as a device for space.

The semiconductor device of one embodiment of the present invention includes an OS transistor. A change in electrical characteristics of the OS transistor due to radiation irradiation is small. That is, the OS transistor is highly resistant to radiation, and thus is suitably used even in an environment where radiation can enter. For example, the OS transistor is suitably used in outer space. Specifically, the OS transistor can be used as a transistor in a semiconductor device provided in a space shuttle, an artificial satellite, or a space probe. Examples of radiation include X-rays and a neutron beam. Note that outer space refers to, for example, space at an altitude greater than or equal to 100 km, and outer space described in this specification includes one or more of thermosphere, mesosphere, and stratosphere.

FIG. 28D illustrates an artificial satellite 6800 as an example of a device for space. The artificial satellite 6800 includes a body 6801, a solar panel 6802, an antenna 6803, a secondary battery 6805, and a control device 6807. In FIG. 28D, a planet 6804 in outer space is illustrated.

Although not illustrated in FIG. 28D, a battery management system (also referred to as BMS) or a battery control circuit may be provided in the secondary battery 6805. The battery management system or the battery control circuit preferably uses the OS transistor, in which case it has low power consumption and high reliability even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor of one embodiment of the present invention is suitably used for the control device 6807. A change in electrical characteristics of the OS transistor due to radiation irradiation is smaller than a change in electrical characteristics of a Si transistor. Accordingly, the OS transistor has high reliability and thus is suitably used even in an environment where radiation can enter.

The artificial satellite 6800 can include a sensor. For example, with a structure including a visible light sensor, the artificial satellite 6800 can have a function of detecting sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can function as an earth observing satellite, for example.

Although the artificial satellite is described as an example of a device for space in this embodiment, one embodiment of the present invention is not limited to this example. The semiconductor device of one embodiment of the present invention is suitably used for a device for space such as a spacecraft, a space capsule, or a space probe, for example.

As described above, an OS transistor has excellent effects of achieving a wide memory bandwidth and being highly resistant to radiation as compared with a Si transistor.

### [Data Center]

The semiconductor device of one embodiment of the present invention is suitably used for, for example, a storage system in a data center or the like. Long-term management of data, such as guarantee of data immutability, is required for the data center. The long-term management of data needs setting a storage or a server for retaining a huge amount of data, stable power supply for retaining data, cooling equipment for retaining data, an increase in building size, and the like.

With use of the semiconductor device of one embodiment of the present invention for a storage system in a data center, electric power used for retaining data can be reduced and a semiconductor device for retaining data can be reduced in size. Accordingly, reductions in sizes of the storage system and the power supply for retaining data, downscaling of the cooling equipment, and the like can be achieved. Therefore, a space of the data center can be reduced.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention can achieve a data center that operates stably even in a high temperature environment. Thus, the reliability of the data center can be increased.

FIG. 28E illustrates a storage system that can be used in a data center. A storage system 7010 illustrated in FIG. 28E includes a plurality of servers 7001sb as host 7001 (indicated as “Host Computer” in the diagram). The storage system 7010 includes a plurality of memory devices 7003md as a storage 7003 (indicated as “Storage” in the diagram). In the illustrated example, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer which accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM that can be used as a cache memory in the storage. In the storage system, in order to solve the problem of low access speed of the storage 7003, a cache memory is normally provided in the storage to shorten the time for data storage and output.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

With a structure in which an OS transistor is used as a transistor for storing data in the cache memory to retain a potential based on data, the frequency of refreshing can be decreased, so that power consumption can be reduced. Furthermore, downscaling is possible by stacking memory cell arrays.

The use of the semiconductor device of one embodiment of the present invention for one or more selected from an electronic component, a large computer, a device for space, a data center, and an electronic device can reduce power consumption. While the demand for energy is expected to increase with higher performance or higher integration of semiconductor devices, the emission amount of greenhouse effect gases typified by carbon dioxide (CO₂) can be reduced with use of the semiconductor device of one embodiment of the present invention. Furthermore, the semiconductor device of one embodiment of the present invention has low power consumption and thus is effective as a global warming countermeasure.

This embodiment can be implemented in an appropriate combination with any of the structures described in the other embodiments and the like.

This application is based on Japanese Patent Application Serial No. 2023-123290 filed with Japan Patent Office on Jul. 28, 2023, the entire contents of which are hereby incorporated by reference.

What is claimed is:

1. A memory device comprising:
n memory cells, n being an integer greater than or equal to 3;
a first wiring;
n second wirings;
n third wirings; and
n fourth wirings,
each of the n memory cells comprising:
a first transistor; and
a second transistor,
each of the first transistor and the second transistor comprising:
a first conductive layer;
a first insulating layer over the first conductive layer;
a fourth conductive layer over the first insulating layer;
a second insulating layer over the fourth conductive layer;
a second conductive layer over the second insulating layer;
semiconductor layer comprising a region along a side surface of the fourth conductive layer; and
a third conductive layer comprising the region along the side surface of the fourth conductive layer with the semiconductor layer therebetween,
wherein the second conductive layer of the first transistor[i] in the i-th memory cell is electrically connected to the first wiring, where i is an integer greater than or equal to 2 and less than or equal to n−1,
wherein the first conductive layer of the first transistor[i] is electrically connected to the third conductive layer of the second transistor[i] in the i-th memory cell,
wherein the third conductive layer of the first transistor[i] is electrically connected to the i-th second wiring,
wherein the fourth conductive layer of the first transistor[i] is electrically connected to the i-th third wiring,
wherein the fourth conductive layer of the second transistor[i] is electrically connected to the i-th fourth wiring,
wherein the first conductive layer of the second transistor[i] is electrically connected to the second conductive layer of the second transistor[i−1] in the i−1-th memory cell, and
wherein the second conductive layer of the second transistor[i] is electrically connected to the first conductive layer of the second transistor[i+1] in the i+1-th memory cell.

2. The memory device according to claim 1,
wherein the first transistor[i] and the second transistor[i] comprise a region where the first transistor[i] and the second transistor[i] overlap with each other in a plan view.

3. The memory device according to claim 1,
wherein the first conductive layer of the first transistor[i] is configured to serve as the third conductive layer of the second transistor[i].

4. The memory device according to claim 1,
wherein the semiconductor layer comprises an oxide semiconductor.

5. The memory device according to claim 1,
wherein each of the n memory cells comprises a capacitor element, and
wherein the capacitor element in the i-th memory cell is electrically connected to the third conductive layer of the second transistor[i].

6. The memory device according to claim 2,
wherein the first conductive layer of the first transistor[i] is configured to serve as the third conductive layer of the second transistor[i].

7. The memory device according to claim 2,
wherein the semiconductor layer comprises an oxide semiconductor.

8. The memory device according to claim 2,
wherein each of the n memory cells comprises a capacitor element, and
wherein the capacitor element in the i-th memory cell is electrically connected to the third conductive layer of the second transistor[i].
